(19) United States
(12) Patent Application Publication
(10) Pub. No.: US 2016/0163982 A1
(43) Pub. Date: Jun. 9, 2016

(54) ORGANIC ELECTROLUMINESCENT DEVICE

(71) Applicant: SAMSUNG DISPLAY CO., LTD., Yongin-si (KR)

(72) Inventors: Jun Ishihara, Yokohama (JP); Ichinori Takada, Yokohama (JP)

(21) Appl. No.: 14/957,456

(22) Filed: Dec. 2, 2015

(30) Foreign Application Priority Data
Dec. 3, 2014 (JP) 2014-245305
Dec. 3, 2014 (JP) 2014-245307

(51) Int. Cl. H01L 51/00

(52) U.S. Cl. CPC H01L 51/006; H01L 51/0061; H01L 51/0072; H01L 51/5004

(57) ABSTRACT

An organic electroluminescent device includes an anode, an emission layer, an anode-side hole transport layer between the anode and the emission layer, the anode-side hole transport layer including an anode-side hole transport material doped with an electron accepting material, a middle hole transport layer between the anode-side hole transport layer and the emission layer, the middle hole transport layer including a middle hole transport material, and an emission layer-side hole transport layer between the middle hole transport layer and the emission layer, the emission layer-side hole transport layer being adjacent to the emission layer. The emission layer-side hole transport layer includes an emission layer-side hole transport material represented by Formula 1. The organic electroluminescent device may have improved emission efficiency and emission life.

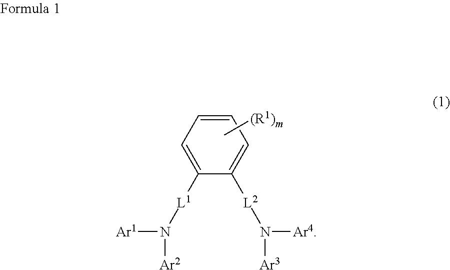

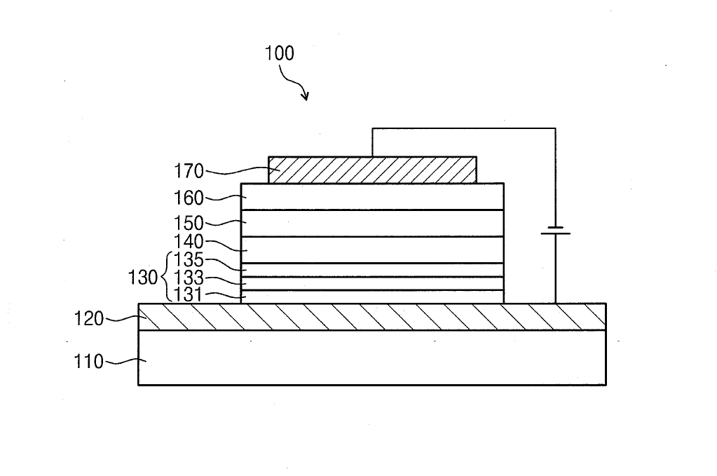

### CROSS-REFERENCE TO RELATED APPLICATIONS

This U.S. non-provisional patent application claims priority to and the benefit of Japanese Patent Applications Nos. 2014-245305, filed on Dec. 3, 2014, and 2014-245307, filed on Dec. 3, 2014, the entire contents of both of which are hereby incorporated by reference.

### BACKGROUND

1. Field

One or more aspects of embodiments of the present disclosure herein relate to an organic electroluminescent device.

2. Description of the Related Art

Recently, the developments of organic electroluminescent displays have been actively conducted. Also, the developments of organic electroluminescent devices, which are self-luminescent devices used in the organic electroluminescent displays, have been actively conducted.

An example structure of an organic electroluminescent device is a laminated structure including an anode, a hole transport layer, an emission layer, an electron transport layer, and a cathode. In such organic electroluminescent device, excitons are generated by recombining holes and electrons respectively injected from the anode and the cathode into the emission layer. The emission of light may be then realized by the transition of the generated excitons to a ground state.

Various techniques for forming a hole transport material and/or a hole transport layer in an organic electroluminescent device have been disclosed. For example, a hole transport material including a carbazolyl group used in a hole transport layer has been disclosed. Also, a technique of adding an electron accepting material to a hole transport layer, etc. has been disclosed. In addition, a technique of forming a hole transport layer having a structure including a plurality of laminated layers has been disclosed.

However, in organic electroluminescent devices prepared according to the aforementioned disclosed techniques, the emission efficiency and emission life values of the organic electroluminescent devices prepared according to the aforementioned disclosed techniques, the emission efficiency are not satisfactory, and further improvement thereof is desired.

### SUMMARY

One or more aspects of embodiments of the present disclosure, in consideration of the above-mentioned defects of the disclosed techniques, are directed toward a novel and improved organic electroluminescent device having improved emission efficiency and emission life.

An embodiment of the present inventive concept provides an organic electroluminescent device including an anode, an emission layer, an anode-side hole transport layer between the anode and the emission layer, anode-side hole transport layer including an anode-side hole transport material doped with an electron accepting material, a middle hole transport layer between the anode-side hole transport layer and the emission layer, the middle hole transport layer including a middle hole transport material, and an emission layer-side hole transport layer between the middle hole transport layer and the emission layer, the emission layer-side hole transport layer being adjacent to the emission layer. The emission layer-side hole transport layer includes an emission layer-side hole transport material represented by the following Formula 1:

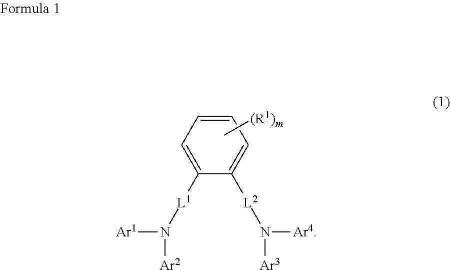

In Formula 1, Ar¹-Ar⁴ may be each independently selected from a substituted or unsubstituted aryl group having 6 to 50 carbon atoms for forming a ring, and a substituted or unsubstituted heteroaryl group having 5 to 50 carbon atoms for forming a ring, and m may be an integer selected from 0 to 4.

R¹ may be selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R¹(s), and L¹ and L² may be each independently selected from a direct linkage, a substituted or unsubstituted arylene group having 6 to 18 carbon atoms for forming a ring, and a substituted or unsubstituted heteroarylene group having 5 to 15 carbon atoms for forming a ring.

According to one or more embodiments of the present disclosure, the emission efficiency and emission life of an organic electroluminescent device may be improved.

In an embodiment, Ar¹-Ar⁴ in Formula 1 may be each independently a compound represented by one of Formulae (1a)-(1c) collectively denoted as Formula 2.

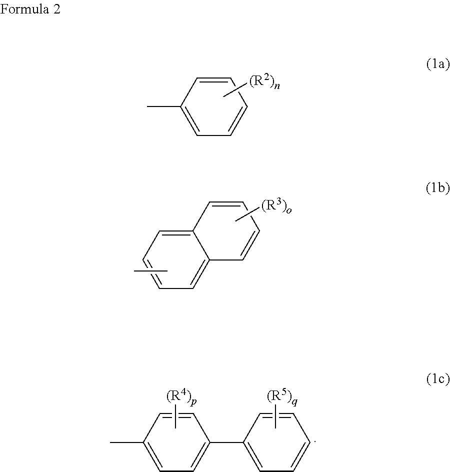

In Formulae (1a)-(1c), p may be an integer from 0 to 4, n and q may each independently be an integer from 0 to 5, o may be an integer from 0 to 7, and R², R³, R⁴ and R⁵ may be each independently selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R²(s), R³(s), R⁴(s), and R⁵(s), respectively.

According to one or more embodiments of the present disclosure, the emission efficiency and emission life of an organic electroluminescent device may be improved.

In an embodiment, the middle hole transport material may be a compound represented by the following Formula 3.

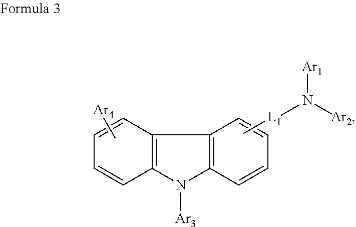

In Formula 3, Ar₁, Ar₂, and Ar₃ may be each independently selected from a substituted or unsubstituted aryl group having 6 to 50 carbon atoms for forming a ring, and a substituted or unsubstituted heteroaryl group having 5 to 50 carbon atoms for forming a ring, Ar₄ may be selected from hydrogen, deuterium, a halogen atom, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms, and L¹ may be selected from a direct linkage, a substituted or unsubstituted arylene group having 6 to 18 carbon atoms for forming a ring, and a substituted or unsubstituted heteroarylene group having 5 to 15 carbon atoms for forming a ring.

According to one or more embodiments of the present disclosure, the emission efficiency and emission life of an organic electroluminescent device may be improved.

In an embodiment, the electron accepting material may have a lowest unoccupied molecular orbital (LUMO) level from about −9.0 eV to about −4.0 eV.

According to one or more embodiments of the present disclosure, the emission efficiency and emission life of an organic electroluminescent device may be improved.

In an embodiment, the anode-side hole transport layer may be adjacent to the anode.

According to one or more embodiments of the present disclosure, the emission efficiency and emission life of an organic electroluminescent device may be improved.

In an embodiment, the anode-side hole transport material may be a compound represented by Formula 3.

According to one or more embodiments of the present disclosure, the emission efficiency and emission life of an organic electroluminescent device may be improved.

In an embodiment, the emission layer may include a compound represented by the following Formula 4.

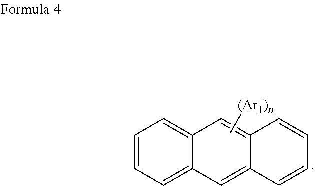

In Formula 4, Ar₁ may be selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group, and a hydroxyl group, and n may be an integer from 1 to 10.

According to one or more embodiments of the present disclosure, the emission efficiency and emission life of an organic electroluminescent device may be improved.

In an embodiment of the inventive concept, an organic electroluminescent device includes an anode, an emission layer, an anode-side hole transport layer between the anode and the emission layer, the anode-side hole transport layer including mainly an electron accepting material, a middle hole transport layer between the anode-side hole transport layer and the emission layer, the middle hole transport layer including a middle hole transport material, and an emission layer-side hole transport layer between the middle hole transport layer and the emission layer, the emission layer-side hole transport layer being adjacent to the emission layer. The emission layer-side hole transport layer includes an emission layer-side hole transport material represented by the following Formula 1.

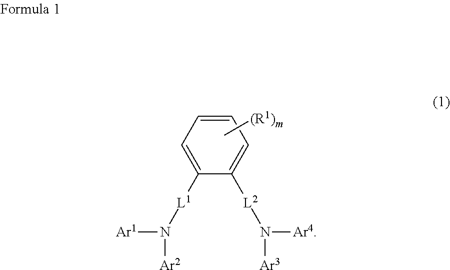

In Formula 1, Ar¹ to Ar⁴ may each independently be selected from a substituted or unsubstituted aryl group having 6 to 50 carbon atoms for forming a ring, and a substituted or unsubstituted heteroaryl group having 5 to 50 carbon atoms for forming a ring, m may be an integer from 0 to 4, R¹ may be selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R¹(s), and L¹ and L² may be selected from a direct linkage, a substituted or unsubstituted arylene group having 6 to 18 carbon atoms for forming a ring, and a substituted or unsubstituted heteroarylene group having 5 to 15 carbon atoms for forming a ring.

According to one or more embodiments of the present disclosure, the emission efficiency and emission life of an organic electroluminescent device may be improved.

In an embodiment, Ar¹ to Ar⁴ in Formula 1 may be each independently a compound represented by one of Formulae (1a)-(1c) collectively denoted as Formula 2.

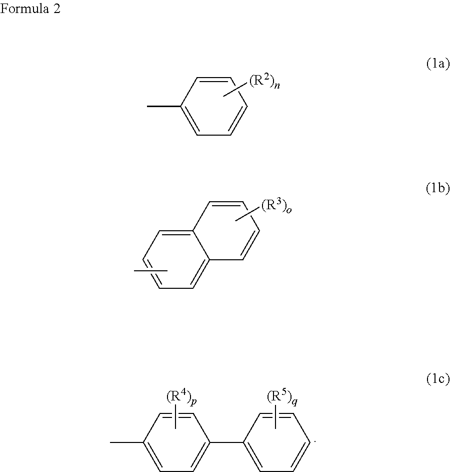

In Formulae (1a)-(1c), p may be an integer from 0 to 4, n and q may be each independently an integer from 0 to 5, o may be an integer from 0 to 7, and R² to R⁵ may be each independently selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R²(s) to R⁵(s), respectively.

According to one or more embodiments of the present disclosure, the emission efficiency and emission life of an organic electroluminescent device may be improved.

In an embodiment, the middle hole transport material may be a compound represented by the following Formula 3.

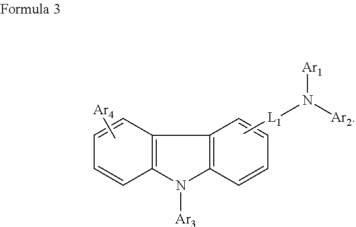

In Formula 3, Ar₁ to Ar₃ may be each independently selected from a substituted or unsubstituted aryl group having 6 to 50 carbon atoms for forming a ring, or a substituted or unsubstituted heteroaryl group having 5 to 50 carbon atoms for forming a ring, Ar₄ may be selected from hydrogen, deuterium, a halogen atom, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms, and L₁ may be selected from a direct linkage, a substituted or unsubstituted arylene group having 6 to 18 carbon atoms for forming a ring, and a substituted or unsubstituted heteroarylene group having 5 to 15 carbon atoms for forming a ring.

According to one or more embodiments of the present disclosure, the emission efficiency and emission life of an organic electroluminescent device may be improved.

In an embodiment, the electron accepting material may have a LUMO level from about −9.0 eV to about −4.0 eV.

According to one or more embodiments of the present disclosure, the emission efficiency and emission life of an organic electroluminescent device may be improved.

In an embodiment, the anode-side hole transport layer may be adjacent to the anode.

According to one or more embodiments of the present disclosure, the emission efficiency and emission life of an organic electroluminescent device may be improved.

In an embodiment, the emission layer may include a compound represented by the following Formula 4.

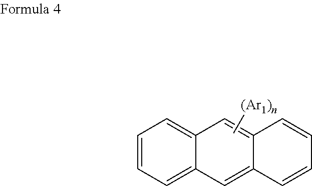

In Formula 4, Ar₁ may be selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group, and a hydroxyl group, and n may be an integer from 1 to 10.

### BRIEF DESCRIPTION OF THE DRAWINGS

The accompanying drawing is included to provide a further understanding of the present inventive concept, and is incorporated in and constitutes a part of this specification. The drawing illustrates example embodiments of the inventive concept and, together with the description, serves to explain principles of the inventive concept. The drawing is a schematic structure of an organic electroluminescent device according to an embodiment of the present inventive concept.

### DETAILED DESCRIPTION

Example embodiments of the present inventive concept will be described below in more detail with reference to the accompanying drawing. In the specification and drawing, elements having substantially the same function will be designated by the same reference numerals, and repeated explanation thereof will not be provided.

### 1-1. Configuration of Organic Electroluminescent Device Including an Anode-Side Hole Transport Layer Including Anode-Side Hole Transport Material and Doped with an Electron Accepting Material

### 1-1-1. Configuration of the Whole Organic Electroluminescent Device

First, the overall configuration of an organic electroluminescent device 100 according to an embodiment of the inventive concept will be described with reference to the drawing.

As shown in the drawing, an organic electroluminescent device 100 according to an embodiment may include a substrate 110, a first electrode 120 disposed on the substrate 110, a hole transport layer 130 disposed on the first electrode 120, an emission layer 140 disposed on the hole transport layer 130, an electron transport layer 150 disposed on the emission layer 140, an electron injection layer 160 disposed on the electron transport layer 150, and a second electrode 170 disposed on the electron injection layer 160. In some embodiment, the hole transport layer 130 may be formed to have a multi-layer structure composed of a plurality of layers 131, 133 and 135.

### 1-1-2. Configuration of Substrate

The substrate 110 may be any substrate suitable for use in an organic electroluminescent device. For example, the substrate 110 may be a glass substrate, a semiconductor substrate, or a transparent plastic substrate.

### 1-1-3. Configuration of First Electrode

The first electrode 120 may be, for example, an anode, and may be formed on the substrate 110 using an evaporation method, a sputtering method, etc. For example, the first electrode 120 may be formed as a transmission type electrode (e.g., transmission electrode) using a metal, an alloy, a conductive compound, etc., having large work function. In some embodiments, the first electrode 120 may be formed using, for example, indium tin oxide (ITO), indium zinc oxide (IZO), tin oxide (SnO₂), zinc oxide (ZnO), etc., having good transparency and conductivity. In some embodiments, the first electrode 120 may be formed as a reflection type electrode (e.g., reflection electrode) using, for example, magnesium (Mg), aluminum (Al), etc.

### 1-1-4. Configuration of Hole Transport Layer

The hole transport layer 130 may include a hole transport material having hole transporting function. The hole transport layer 130 may be formed, for example, on the first electrode 120 to a layer thickness (total layer thickness of a laminated structure of the hole transport layer) of about 10 nm to about 150 nm.

For example, the hole transport layer 130 of the organic electroluminescent device 100 according to an embodiment may be formed as a multi-layer by sequentially laminating, on the first electrode 120, an anode-side hole transport layer 131, a middle hole transport layer 133, and an emission layer-side hole transport layer 135. Here, the ratio of the thicknesses of the hole transport layers is not specifically limited.

### 1-1-4-1. Configuration of Anode-Side Hole Transport Layer

The anode-side hole transport layer 131 may be a layer including an anode-side hole transport material doped with an electron accepting material. For example, the anode-side hole transport layer 131 may be formed on the first electrode 120.

The anode-side hole transport layer 131 may be doped with the electron accepting material and may improve hole injection property from the first electrode 120. Thus, in one embodiment, the anode-side hole transport layer 131 may preferably be around (or near) the first electrode 120, for example, may be provided adjacent to (e.g., directly on) the first electrode 120.

The anode-side hole transport material included in the anode-side hole transport layer 131 may be any suitable hole transport material. Non-limiting examples of the anode-side hole transport material included in the anode-side hole transport layer 131 may be 1,1-bis[(di-4-tolylamino)phenyl]cyclohexane (TAPC), a carbazole derivative (such as N-phenyl carbazole and/or polyvinyl carbazole), N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), etc.

The electron accepting material included in the anode-side hole transport layer 131 may be any suitable electron accepting material. In some embodiments, the electron accepting material included in the anode-side hole transport layer 131 may have a lowest unoccupied molecular orbital (LUMO) level from about −9.0 eV to about −4.0 eV, for example, the LUMO level from about −6.0 eV to about −4.0 eV.

Non-limiting examples of the electron accepting material having the LUMO level from about −9.0 eV to about −4.0 eV may include Compounds 4-1 to 4-14 collectively denoted as Formula 5.

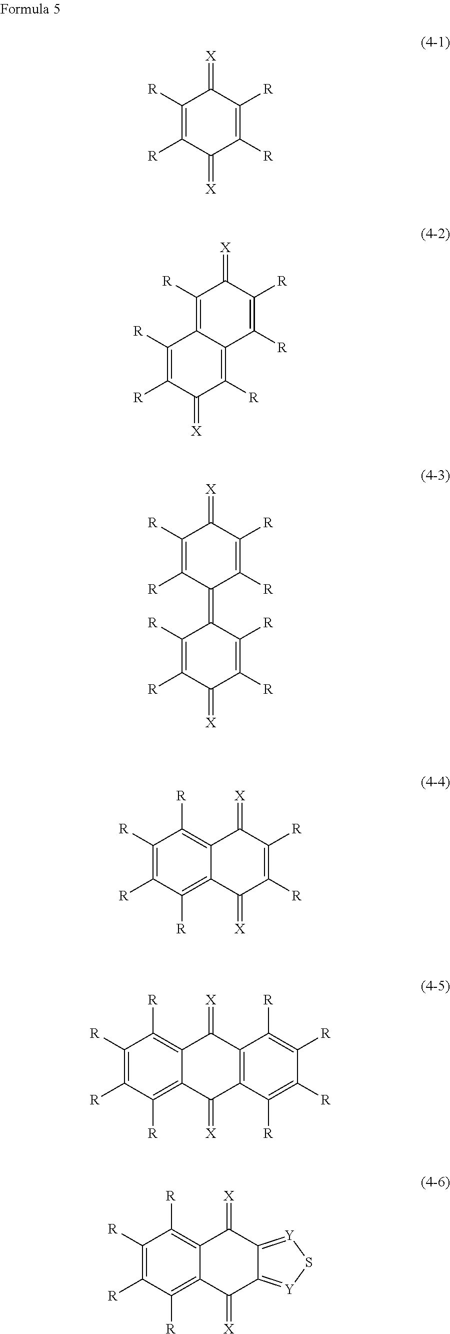

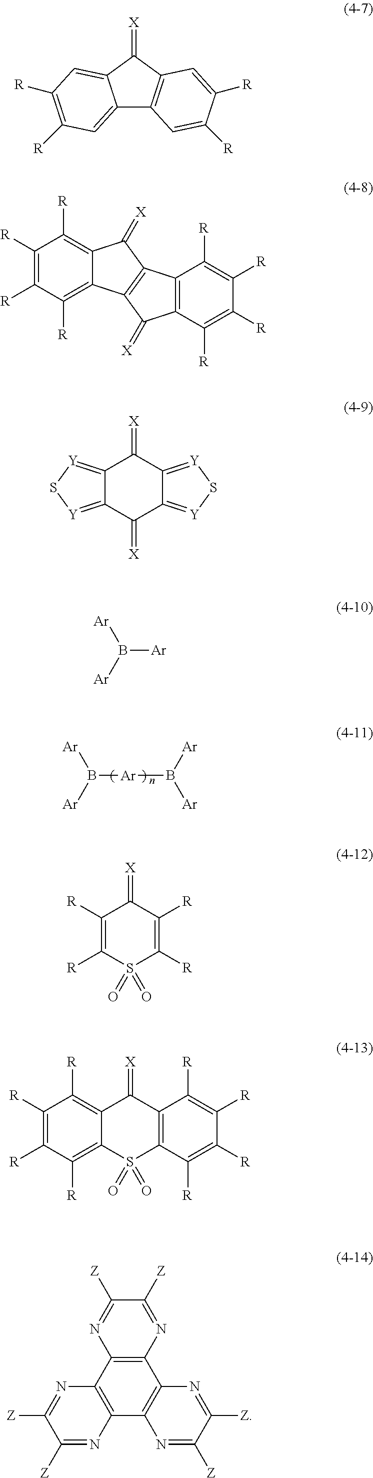

In the above Compounds 4-1 to 4-14, R may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms, and a heteroaryl group having 5 to 50 carbon atoms for forming a ring. As used herein, “atoms for forming a ring” may refer to “ring-forming atoms.”

Ar may be selected from a substituted aryl group with an electron withdrawing group, an unsubstituted aryl group having 6 to 50 carbon atoms for forming a ring, and a substituted or unsubstituted heteroaryl group having 5 to 50 carbon atoms for forming a ring, Y may be a methine group (—CH═) or a nitrogen atom (—N═), Z may be a pseudohalogen (e.g., a pseudohalogen group) or may include sulfur (S) (e.g., Z may be a sulfur-containing group), n may be an integer of 10 or less, and X may be one of the substituent groups represented by Compounds X1 to X7 and collectively denoted as Formula 6.

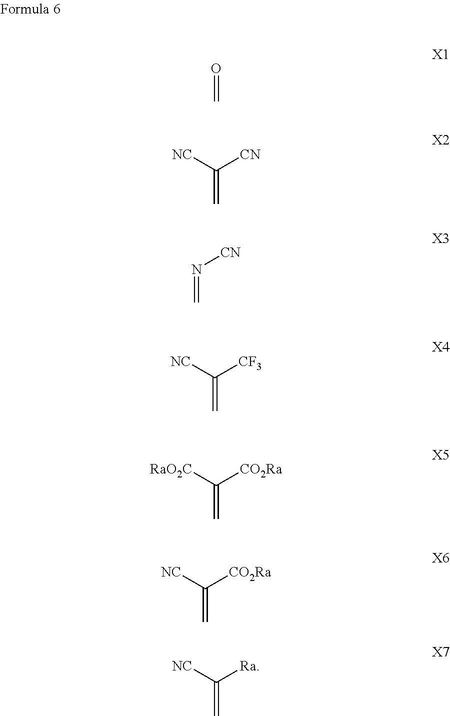

In Compounds X1 to X7 of Formula 6, Ra may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 carbon atoms for forming a ring, and a substituted or unsubstituted heteroaryl group having 5 to 50 carbon atoms for forming a ring.

Non-limiting examples of the substituted or unsubstituted aryl group having 6 to 50 carbon atoms for forming a ring represented by, for example, R, Ar and/or Ra may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, an m-terphenyl-4-yl group, an m-terphenyl-3-yl group, an m-terphenyl-2-yl group, an o-tolyl group, an m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, etc.

Non-limiting examples of the substituted or unsubstituted heteroaryl group having 5 to 50 carbon atoms for forming a ring represented by, for example, R, Ar and/or Ra may include an 1-pyrrolyl group, a 2-pyrrolyl group, a 3-pyrrolyl group, a pyridinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, etc.

Non-limiting examples the substituted or unsubstituted fluoroalkyl group having 1 to 50 carbon atoms represented by, for example, R and/or Ra may include a perfluoroalkyl group (such as a trifluoromethyl group, a pentafluoroethyl group, a heptafluoropropyl group and/or a heptadecafluorooctane group), a monofluoromethyl group, a difluoromethyl group, a trifluoroethyl group, a tetrafluoropropyl group, an octafluoropentyl group, etc.

Non-limiting examples of the substituted or unsubstituted alkyl group having 1 to 50 carbon atoms represented by, for example, R and/or Ra may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-am inoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The substituted or unsubstituted alkoxy group having 1 to 50 carbon atoms represented by, for example, R and/or Ra may be a group represented by —OY. Non-limiting examples of Y may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc.

Non-limiting examples of the halogen atom represented by, for example, R and/or Ra may include fluorine (F), chlorine (CI), bromine (Br), iodine (I), etc.

In some embodiments, the electron accepting material may include Compounds 4-15 and 4-16 collectively denoted as Formula 7. For example, the LUMO level of Compound 4-15 may be about −4.40 eV, and the LUMO level of Compound 4-16 may be about −5.20 eV. However, the electron accepting material is not limited to the following Compounds 4-15 and 4-16.

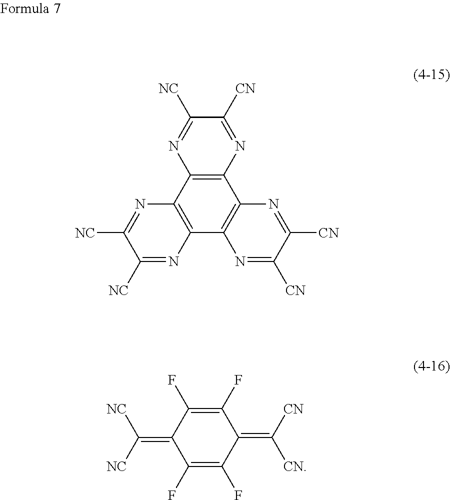 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

The amount doped (e.g., the doping amount) of the electron accepting material may be any suitable amount capable of being doped into the anode-side hole transport layer 131, without limitation. For example, the amount doped of the electron accepting material may be from about 0.1 wt % to about 50 wt % on the basis of the total amount of the anode-side hole transport material included in the anode-side hole transport layer 131, and may be, for example, from about 0.5 wt % to about 5 wt %.

### 1-1-4-2. Configuration of Middle Hole Transport Layer

The middle hole transport layer 133 may include a middle hole transport material. The middle hole transport layer 133 may be formed, for example, on the anode-side hole transport layer 131.

The middle hole transport material included in the middle hole transport layer 133 may be any suitable hole transport material. For example, the middle hole transport material may use any of the hole transport materials mentioned above in connection with the anode-side hole transport materials.

In some embodiments, the middle hole transport material may be a compound represented by the following Formula 3.

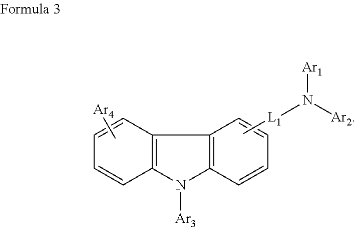

In the above Formula 3, Ar₁, Ar₂, and Ar₃ may be each independently selected from a substituted or unsubstituted aryl group having 6 to 50 carbon atoms for forming a ring, and a substituted or unsubstituted heteroaryl group having 5 to 50 carbon atoms for forming a ring. Ar₄ may be selected from hydrogen, deuterium, a halogen atom, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms. L₁ may be selected from a direct linkage (e.g., a bond such as a single bond), a substituted or unsubstituted arylene group having 6 to 18 carbon atoms for forming a ring, and a substituted or unsubstituted heteroarylene group having 5 to 15 carbon atoms for forming a ring.

Non-limiting examples of Ar₁, Ar₂ and Ar₃ may include a phenyl group, a biphenyl group, a terphenyl group, a naphthyl group, an anthryl group, a phenanthryl group, a fluorenyl group, an indenyl group, a pyrenyl group, an acenaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. For example, Ar₁, Ar₂ and Ar₃ may each independently include the phenyl group, the biphenyl group, the terphenyl group, the fluorenyl group, the carbazolyl group, the dibenzofuranyl group, etc.

Non-limiting examples of Ar₄ may include a phenyl group, a biphenyl group, a terphenyl group, a naphthyl group, an anthryl group, a phenanthryl group, a fluorenyl group, an indenyl group, a pyrenyl group, an acenaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, a methyl group, an ethyl group, a propyl group, an isopropyl group, an n-butyl group, etc. For example, Ar₄ may include the phenyl group, the biphenyl group, the terphenyl group, the fluorenyl group, the carbazolyl group, the dibenzofuranyl group, the methyl group, the ethyl group, etc.

Non-limiting examples of L₁, other than the direct linkage, may include a phenylene group, a biphenylene group, a terphenylene group, a naphthylene group, an anthrylene group, a phenanthrylene group, a fluorenylene group, an indenylene group, a pyrenylene group, an acenaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienylene group, etc. For example, L₁ may include the direct linkage, the phenylene group, the biphenylene group, the terphenylene group, the fluorenylene group, the carbazolylene group, and/or the dibenzofuranylene group.

Non-limiting examples of the compound represented by Formula 3 may include Compounds 2-1 to 2-17 collectively denoted as Formula 8. However, the compound represented by Formula 3 is not limited to the following Compounds 2-1 to 2-17. The middle hole transport material may include at least one of the compounds in the following Formula 8.

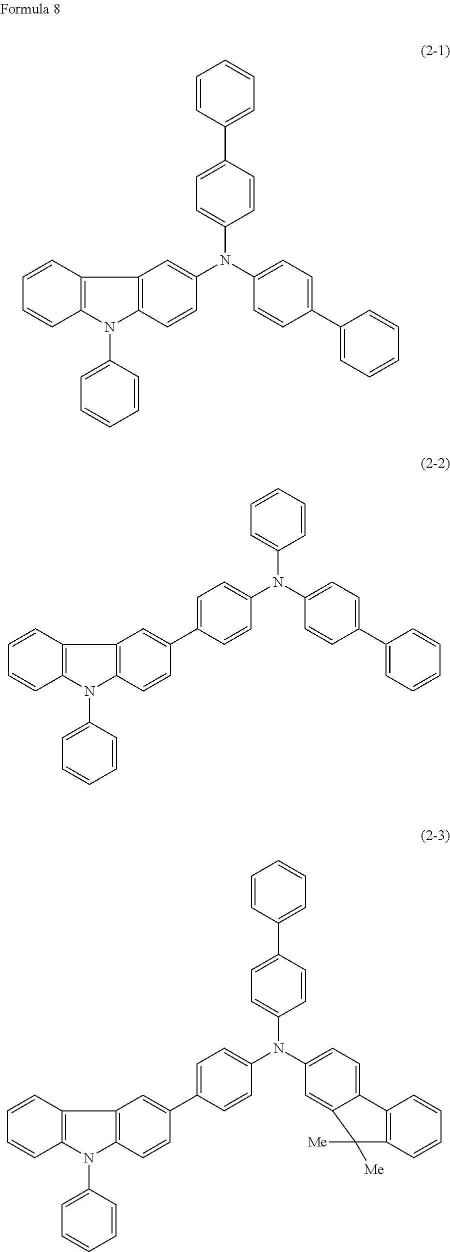 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

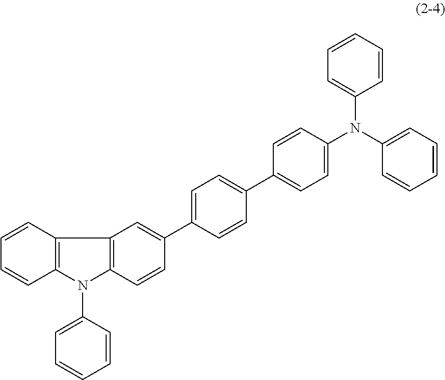 [SMILES: c1ccc(N(c2ccccc2)c2ccc(-c3ccc(-c4ccc5c(c4)c4ccccc4n5-c4ccccc4)cc3)cc2)cc1]

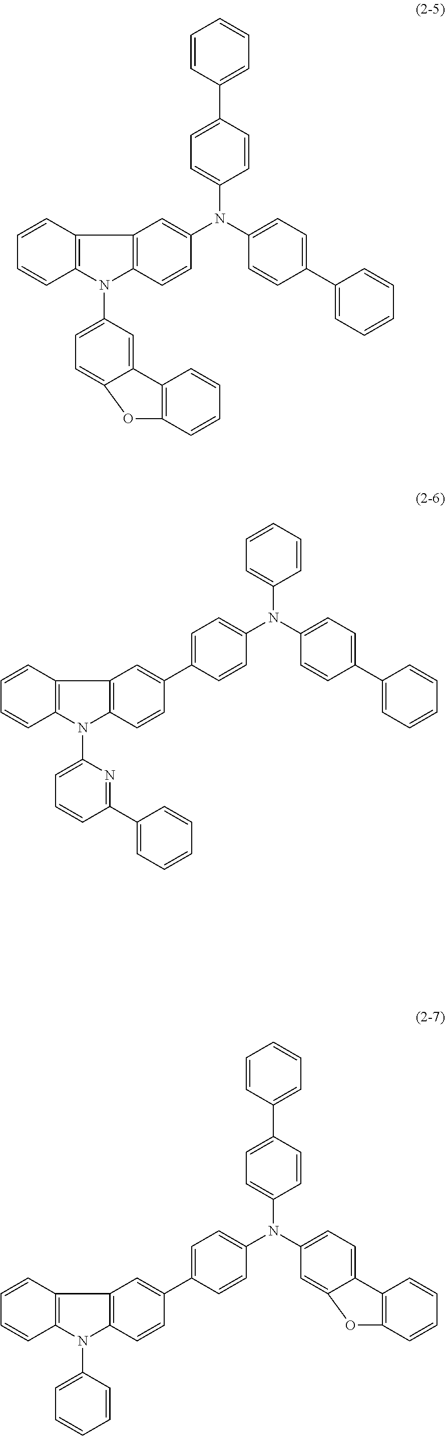 [SMILES: c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1 ; c1ccc(-c2ccc(N(c3ccc(-c4ccc5c(c4)c4ccccc4n5-c4ccccc4)cc3)c3ccc4c(c3)oc3ccccc34)cc2)cc1]

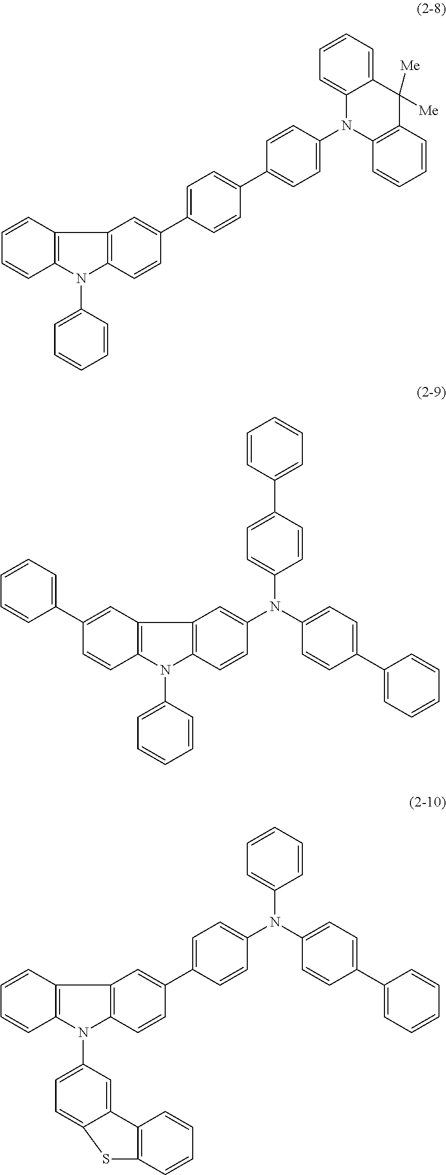 [SMILES: CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1 ; c1ccc(-c2ccc(N(c3ccccc3)c3ccc(-c4ccc5c(c4)c4ccccc4n5-c4ccc5sc6ccccc6c5c4)cc3)cc2)cc1]

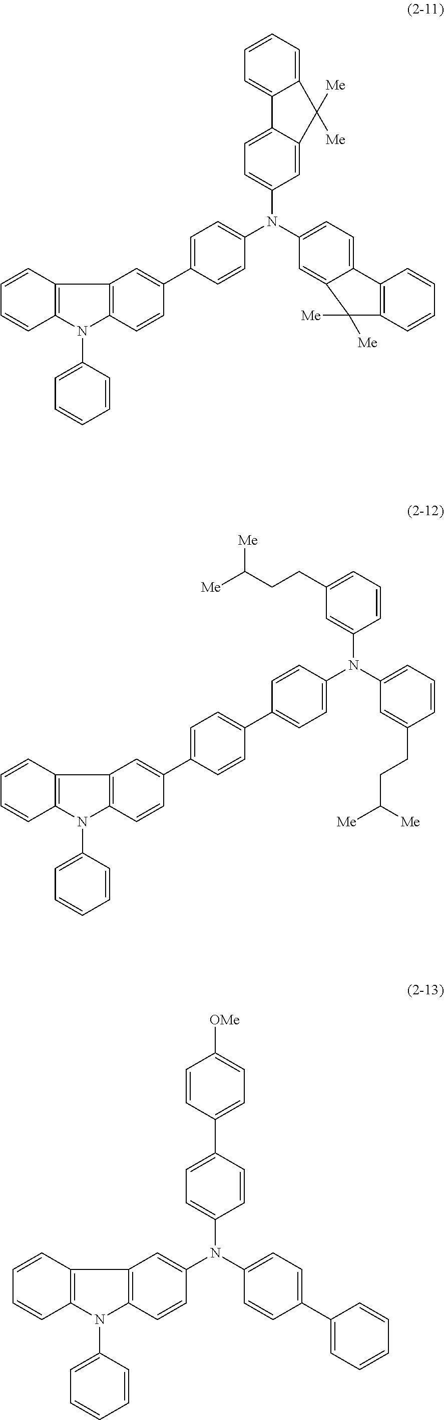 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1 ; COc1ccc(-c2ccc(N(c3ccc(-c4ccccc4)cc3)c3ccc4c(c3)c3ccccc3n4-c3ccccc3)cc2)cc1]

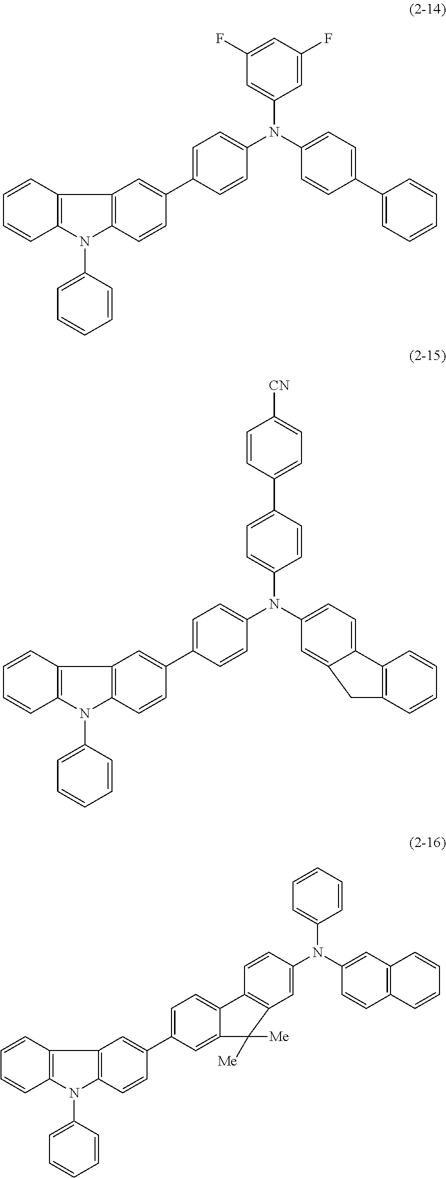 [SMILES: Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1 ; CC1(C)c2cc(-c3ccc4c(c3)c3ccccc3n4-c3ccccc3)ccc2-c2ccc(N(c3ccccc3)c3ccc4ccccc4c3)cc21]

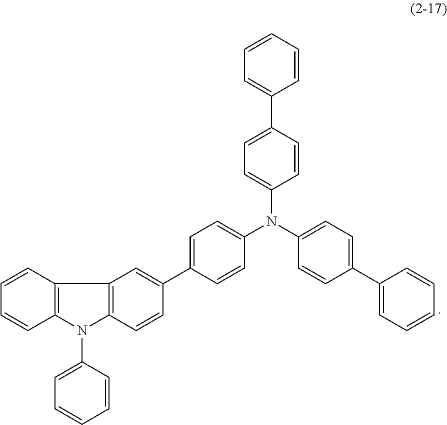 [SMILES: c1ccc(-c2ccc(N(c3ccc(-c4ccccc4)cc3)c3ccc(-c4ccc5c(c4)c4ccccc4n5-c4ccccc4)cc3)cc2)cc1]

The middle hole transport layer 133 including the compound represented by the above Formula 3 as the middle hole transport material may improve the hole transporting property of the hole transport layer 130, and thus may improve the emission efficiency of the organic electroluminescent device 100.

In some embodiments, the compound represented by Formula 3 may be also included in the anode-side hole transport layer 131 as the anode-side hole transport material. In embodiments where the anode-side hole transport layer 131 includes the compound represented by Formula 3 as the anode-side hole transport material, the hole transporting property of the hole transport layer 130 may be further improved, and the emission efficiency of the organic electroluminescent device 100 may be further improved.

In the case where the ratio of a carbazole derivative such as the compound represented by Formula 3 in the hole transport layer 130 is high, the emission life of the organic electroluminescent device 100 may be further increased.

In some embodiments, the anode-side hole transport layer 131 may further include other hole transport materials as the anode-side hole transport material, in addition to the compound represented by Formula 3.

### 1-1-4-3. Configuration of Emission Layer-Side Hole Transport Layer

The emission layer-side hole transport layer 135 may include a compound represented by the following Formula 1. The emission layer-side hole transport layer 135 may be formed, for example, on the middle hole transport layer 133, adjacent to the emission layer 140.

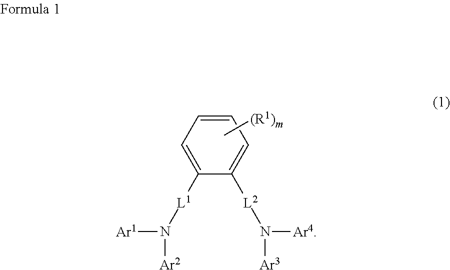

In Formula 1, Ar¹ to Ar⁴ may be each independently selected from a substituted or unsubstituted aryl group having 6 to 50 carbon atoms for forming a ring, and a substituted or unsubstituted heteroaryl group having 5 to 50 carbon atoms for forming a ring.

In addition, m may be an integer from 0 to 4. R¹ may be selected from hydrogen, deuterium, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms. A plurality of adjacent R₁ may form a ring.

Non-limiting examples of R¹, other than hydrogen and deuterium, may include a phenyl group, a biphenyl group, a terphenyl group, a naphthyl group, an anthryl group, a phenanthryl group, a fluorenyl group, an indenyl group, a pyrenyl group, an acenaphthenyl group, a fluoranthenyl group, a triphenylenyl group, a pyridyl group, a pyranyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a dibenzofuranyl group, a dibenzothienyl group, etc. For example, R¹ may include the phenyl group, the biphenyl group, the terphenyl group, the fluorenyl group, the carbazolyl group, the dibenzofuranyl group, etc.

L¹ and L² may each independently be selected from a direct linkage (e.g., a bond such as a single bond), a substituted or unsubstituted arylene group having 6 to 18 carbon atoms for forming a ring, and a substituted or unsubstituted heteroarylene group having 5 to 15 carbon atoms for forming a ring.

Non-limiting examples of L₁ and L₂ may include a phenylene group, a biphenylene group, a terphenylene group, a naphthylene group, an anthrylene group, a phenanthrylene group, a fluorenediyl group, an indanediyl group, a pyrenediyl group, an acenaphthenediyl group, a fluoranthenediyl group, a triphenylenediyl group, a pyridinediyl group, a pyran-diyl group, a quinolinediyl group, an isoquinolinediyl group, a benzofuran-diyl group, a benzothiophenediyl group, an indolediyl group, a carbazolediyl group, a benzooxazolediyl group, a benzothiazolediyl group, a quinoxalinediyl group, a benzoimidazolediyl group, and a dibenzofuran-diyl group. In some embodiments, L₁ and L₂ may each independently include a substituent other than the anthrylene group, for example, L₁ and L₂ may each independently include the phenylene group, the biphenylene group, the terphenylene group, the fluorenediyl group, the carbazolediyl group and/or the dibenzofuranediyl group.

In Formula 1, Ar¹ to Ar⁴ may each independently include a compound represented by one of the following Formulae (1a)-(1c) collectively denoted as Formula 2.

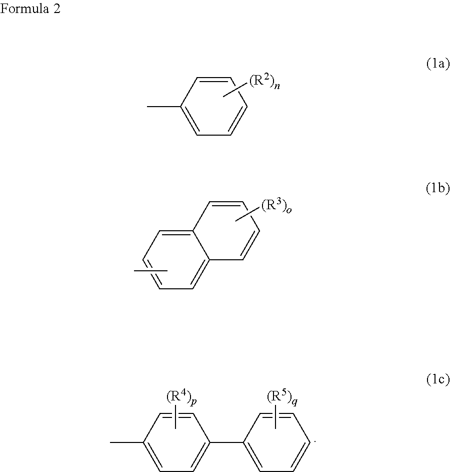

In Formulae (1a)-(1c) in Formula 2, p may be an integer from 0 to 4, n and q may each independently be an integer from 0 to 5, and o may be an integer from 0 to 7. R², R³, R⁴ and R⁵ may be each independently selected from hydrogen, deuterium, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms. R², R³, R⁴ and R⁵ may each independently form a ring with adjacent groups of R², R³, R⁴ and R⁵, respectively. Non-limiting examples of R², R³, R⁴ and R⁵ may be the same as those described herein in connection with R₁.

Non-limiting examples of the compound represented by Formula 1 may include the following Compounds 1 to 49 collectively denoted as Formula 9. However, the compound represented by Formula 1 is not limited to the following Compounds 1 to 49. The emission layer-side hole transport material may include at least one of the compounds in the following Formula 9.

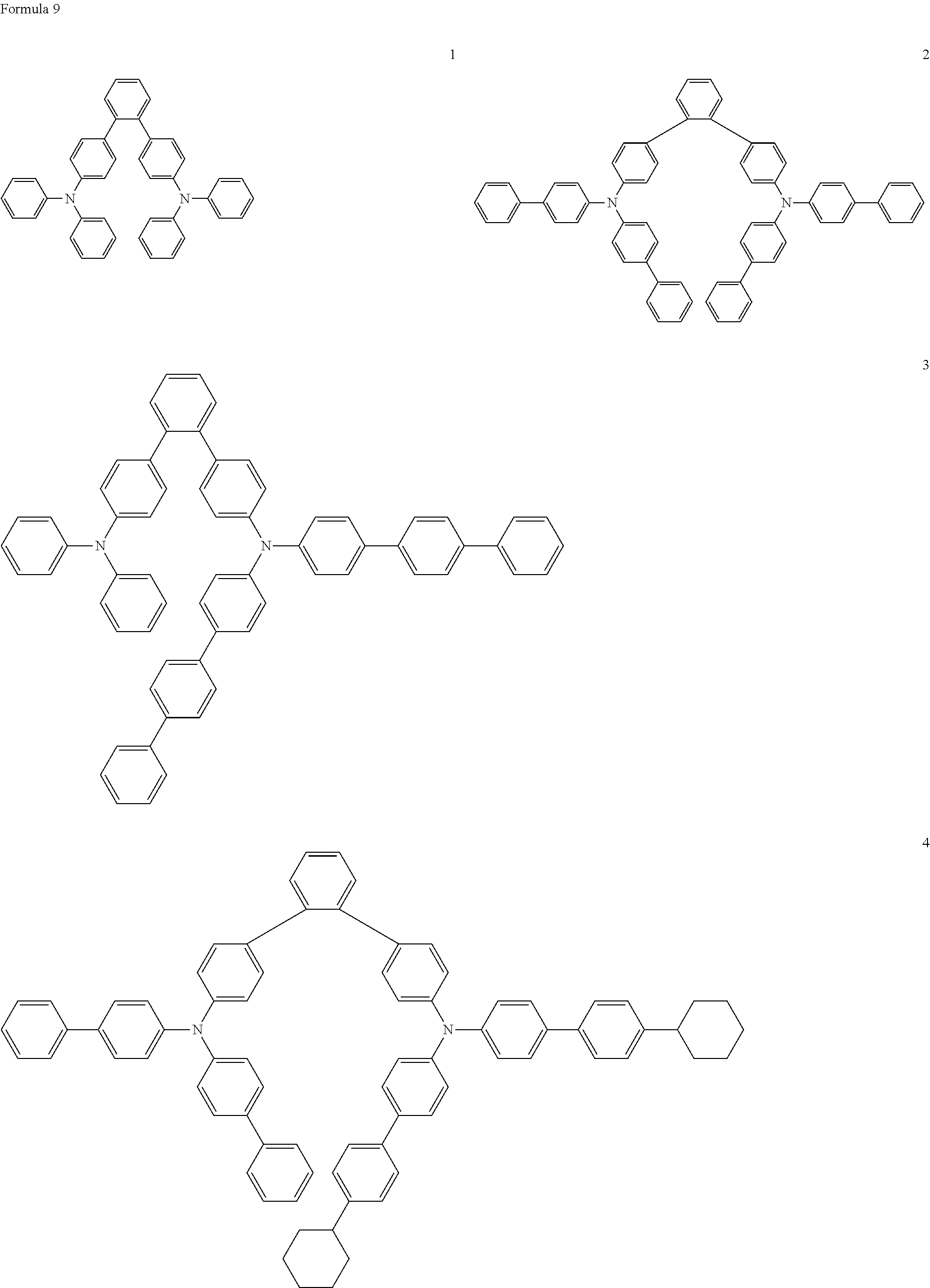 [SMILES: c1ccc(N(c2ccccc2)c2ccc(-c3ccccc3-c3ccc(N(c4ccccc4)c4ccccc4)cc3)cc2)cc1 ; c1ccc(-c2ccc(N(c3ccc(-c4ccccc4)cc3)c3ccc(-c4ccccc4-c4ccc(N(c5ccc(-c6ccccc6)cc5)c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccccc5-c5ccc(N(c6ccccc6)c6ccccc6)cc5)cc4)cc3)cc2)cc1 ; c1ccc(-c2ccc(N(c3ccc(-c4ccccc4)cc3)c3ccc(-c4ccccc4-c4ccc(N(c5ccc(-c6ccc(C7CCCCC7)cc6)cc5)c5ccc(-c6ccc(C7CCCCC7)cc6)cc5)cc4)cc3)cc2)cc1]

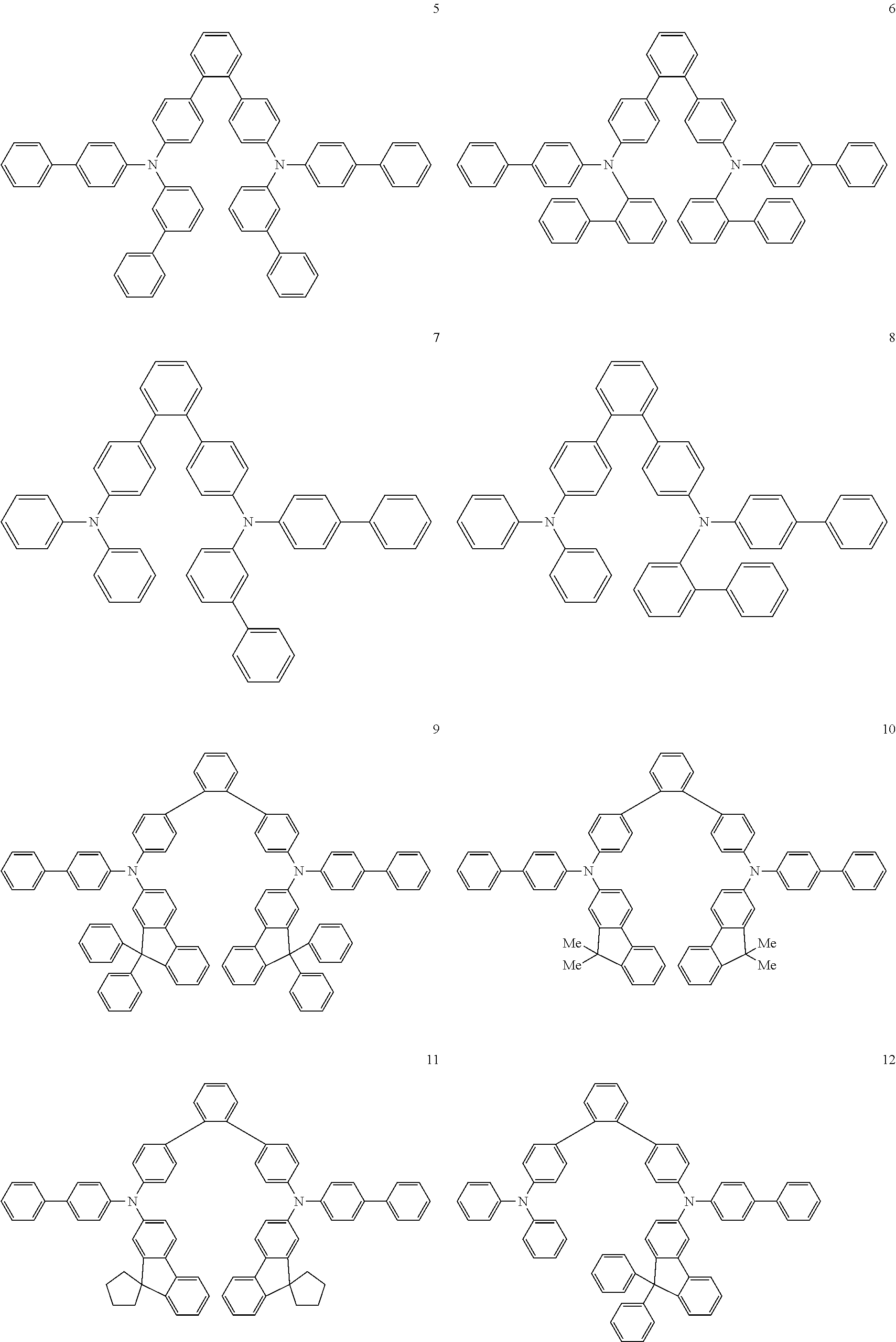

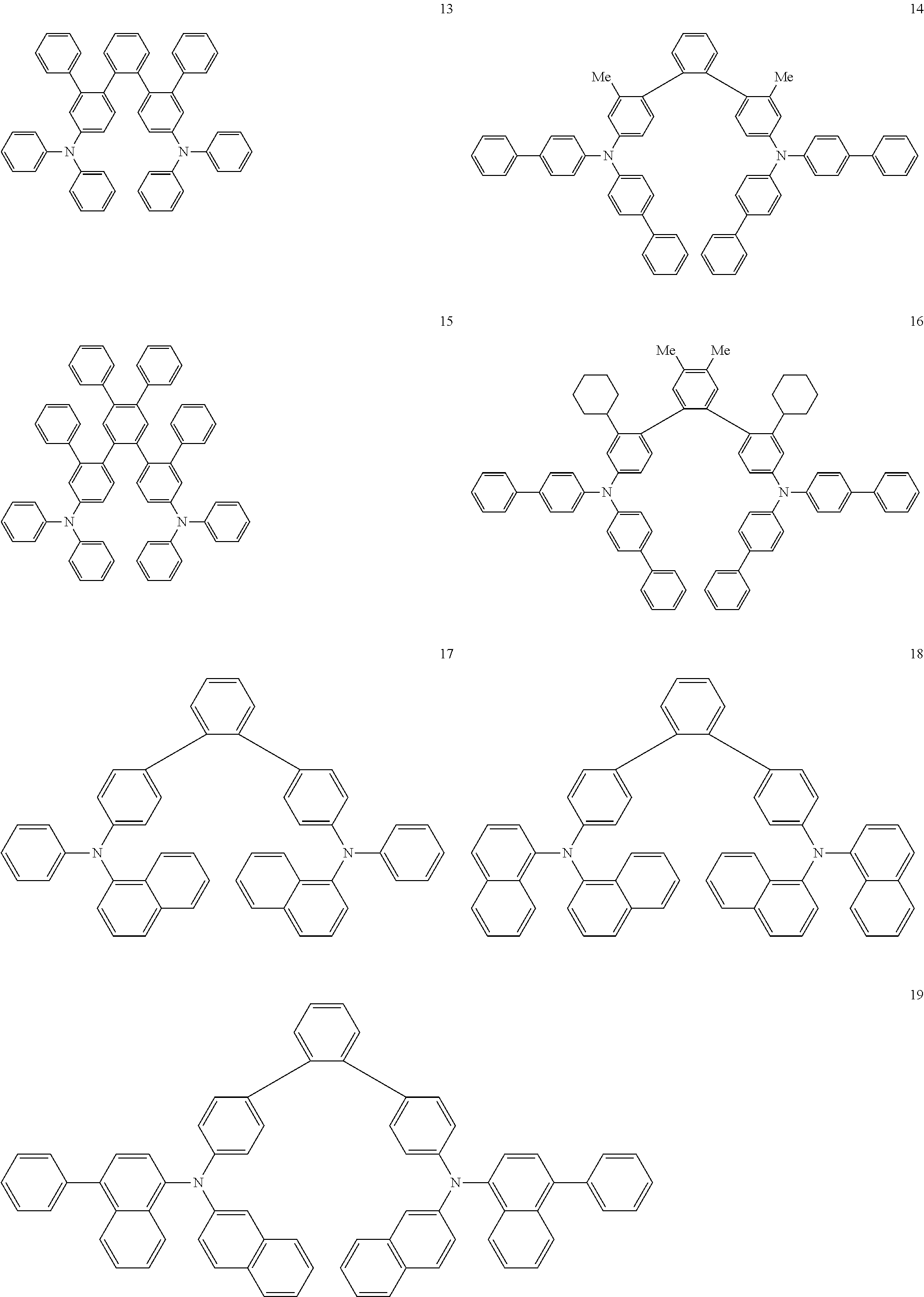

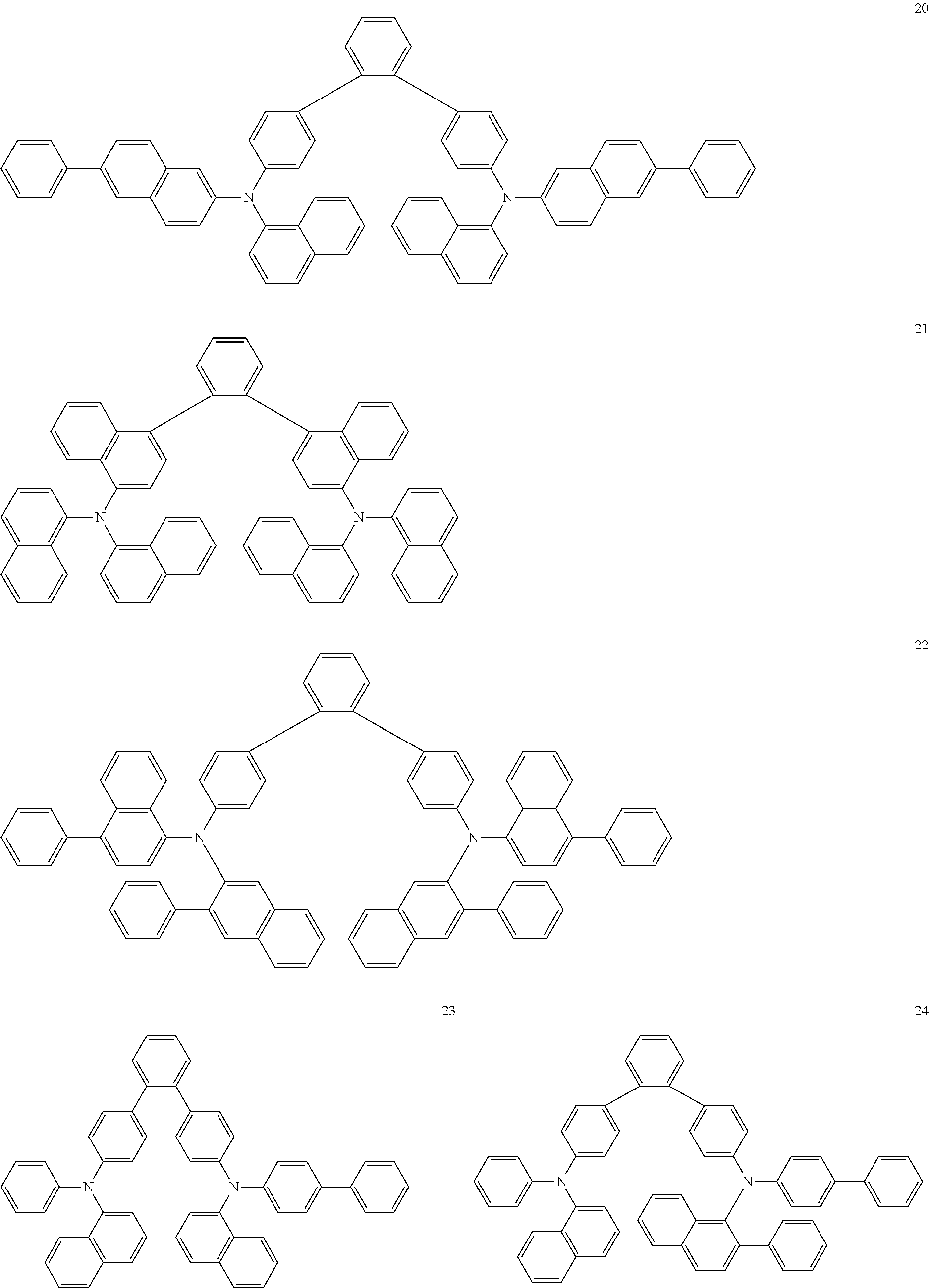

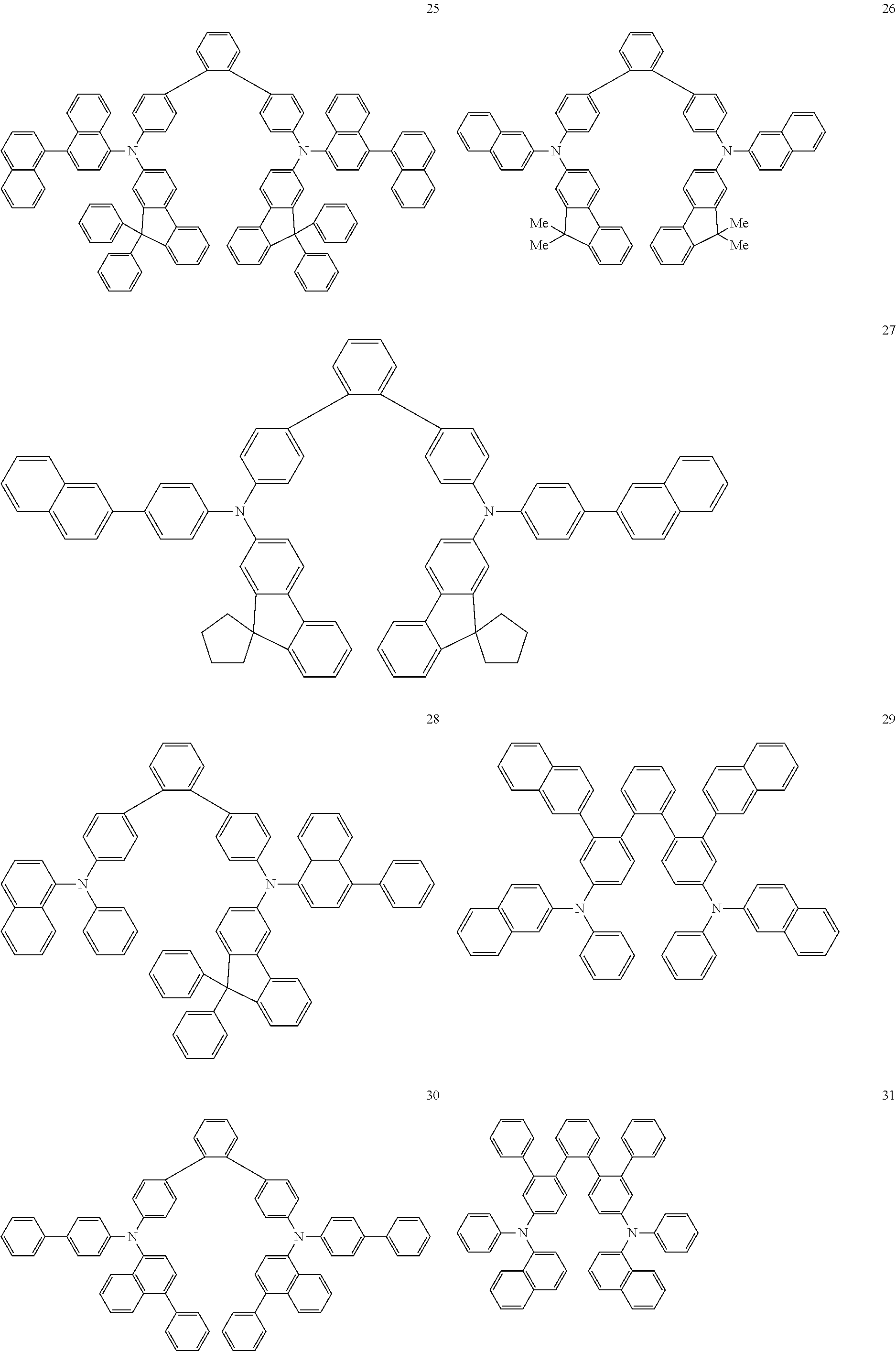

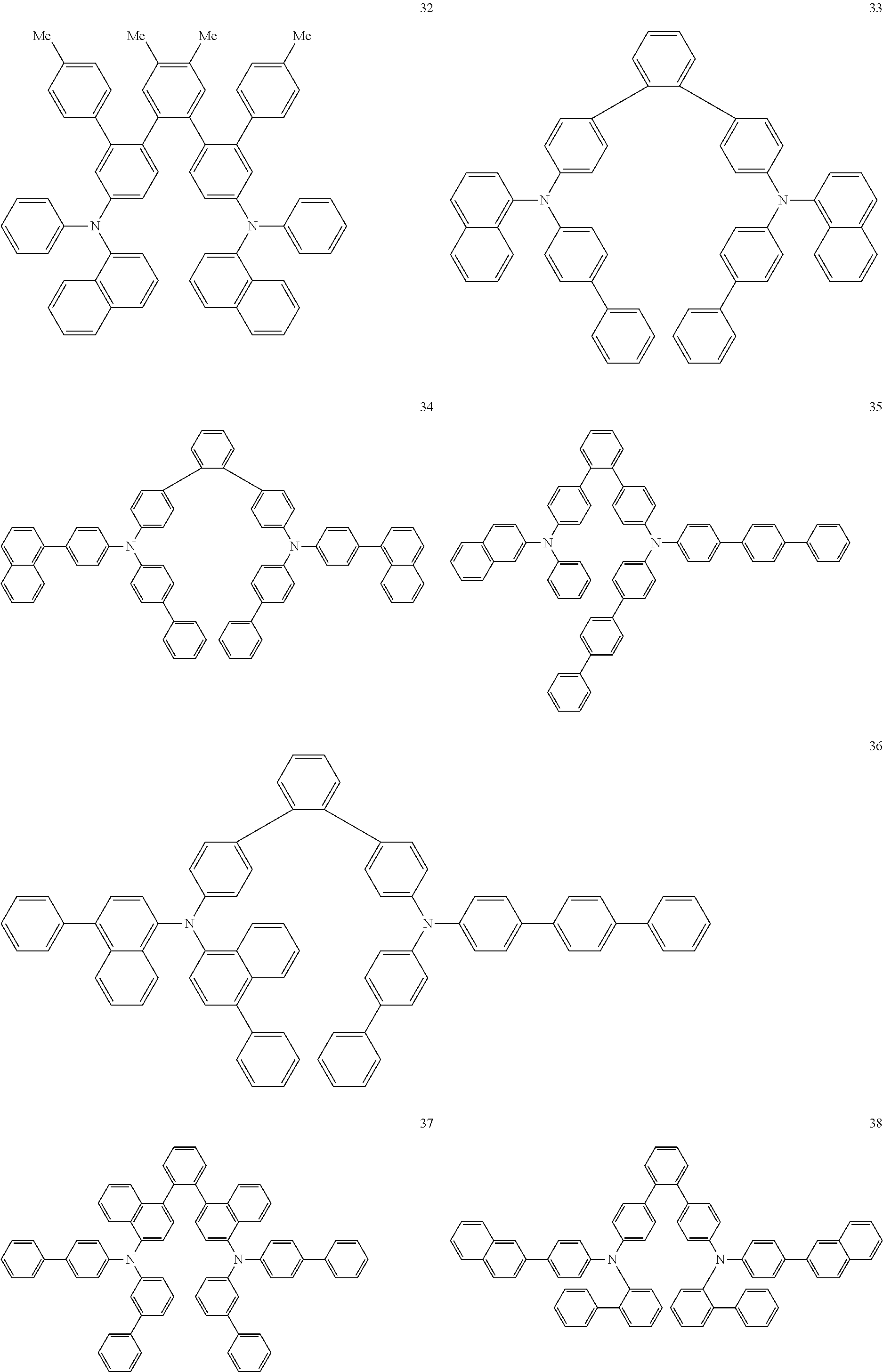

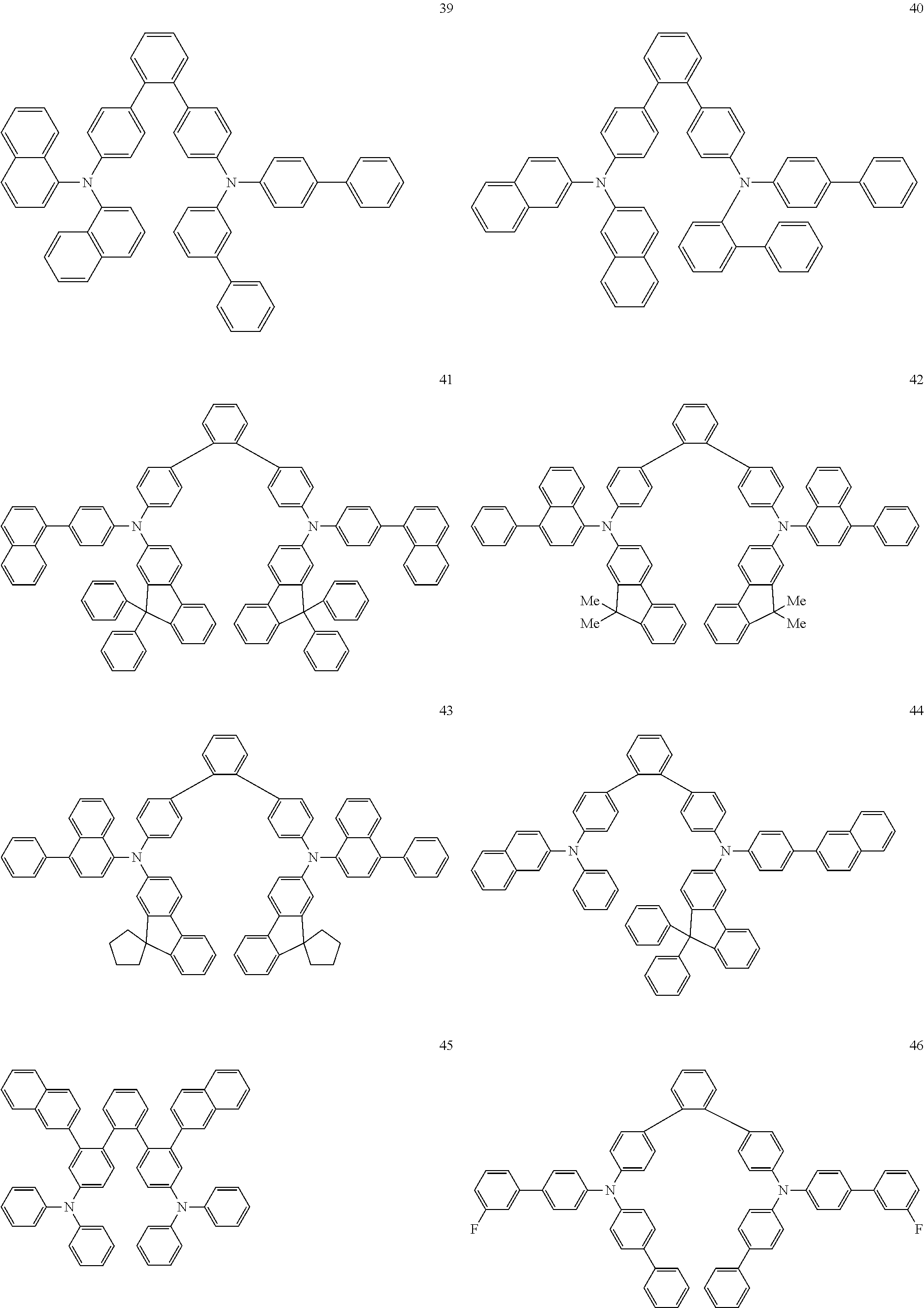

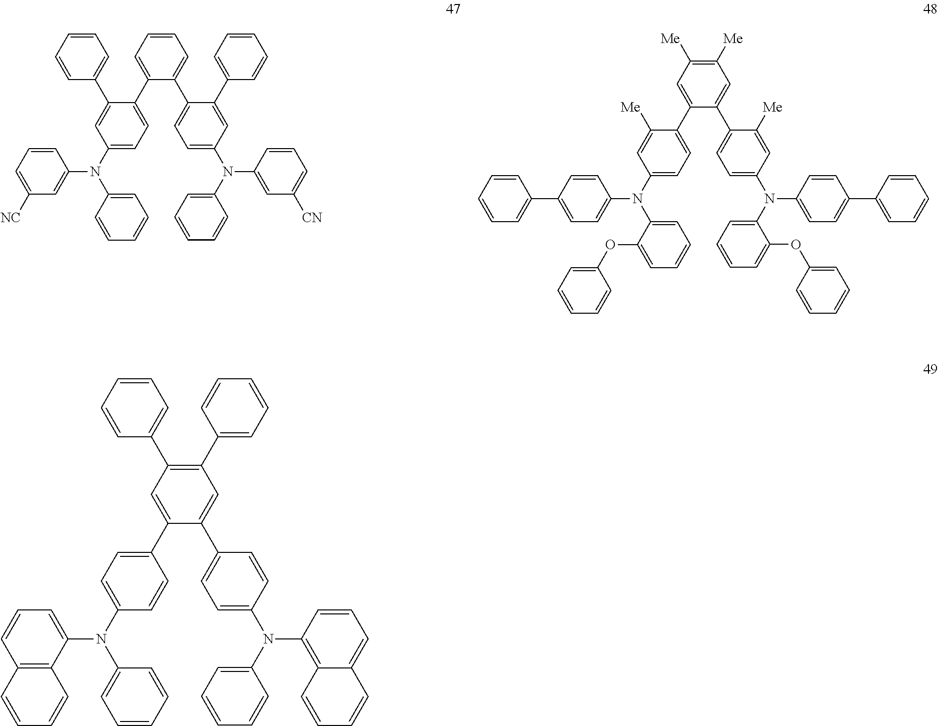 [SMILES: N#Cc1cccc(N(c2ccccc2)c2ccc(-c3ccccc3-c3ccc(N(c4ccccc4)c4cccc(C#N)c4)cc3-c3ccccc3)c(-c3ccccc3)c2)c1 ; Cc1cc(-c2ccc(N(c3ccc(-c4ccccc4)cc3)c3ccccc3Oc3ccccc3)cc2C)c(-c2ccc(N(c3ccc(-c4ccccc4)cc3)c3ccccc3Oc3ccccc3)cc2C)cc1C ; c1ccc(-c2cc(-c3ccc(N(c4ccccc4)c4cccc5ccccc45)cc3)c(-c3ccc(N(c4ccccc4)c4cccc5ccccc45)cc3)cc2-c2ccccc2)cc1]

The emission layer-side hole transport layer 135 may include the compound represented by the above Formula 1 as the emission layer-side hole transport material and may protect the hole transport layer 130 from the diffusion of electrons not consumed in the emission layer 140. In addition, since the emission layer-side hole transport layer 135 includes the compound represented by Formula 1, the diffusion of the energy in an excited state (e.g., the diffusion of excitons) generated in the emission layer 140 to the hole transport layer 130 may be prevented or reduced. Therefore, the emission layer-side hole transport layer 135 according to embodiments of the present disclosure may improve the current flow durability of the hole transport layer 130.

The emission layer-side hole transport layer 135 may be formed around (or near) the emission layer 140, for example, may be formed adjacent to the emission layer 140, to effectively (or suitably) prevent or reduce the diffusion of electrons or energy (e.g., excitons) from the emission layer 140.

In addition, since the emission layer-side hole transport layer 135 includes the compound represented by Formula 1, the charge balance of the whole organic electroluminescent device 100 may be controlled, and the diffusion of the electron accepting material doped into the anode-side hole transport layer 131 into the emission layer 140 may be restrained or reduced. Accordingly, the emission layer-side hole transport layer 135 may improve the hole transport property of the hole transport layer 130.

When the emission layer-side hole transport layer 135 includes the compound represented by Formula 1, the charge transport property and current flow durability of the hole transport layer 130 may be improved, thereby improving the emission efficiency and emission life of the organic electroluminescent device 100.

As described above, the hole transport layer 130 including the anode-side hole transport layer 131, the middle hole transport layer 133, and the emission layer-side hole transport layer 135 may improve the current flow durability and hole transport property of the organic electroluminescent device 100. Therefore, the organic electroluminescent device 100 according to embodiments of the present disclosure may have improved emission efficiency and emission life.

### 1-1-5. Configuration of Emission Layer

The emission layer 140 may include a host material, a dopant material as a luminescent material, etc., and may emit light via fluorescence or phosphorescence. The emission layer 140 may be formed, for example, on the hole transport layer 130 to a layer thickness from about 10 nm to about 60 nm.

The host material and the dopant material included in the emission layer 140 may include any suitable host materials and dopant materials. For example, the emission layer 140 may include a fluoranthene derivative, pyrene and/or the derivative thereof, an arylacetylene derivative, a fluorene derivative, perylene and/or the derivative thereof, a chrysene derivative, a styryl derivative, etc., as the host material and/or the dopant material. For example, the emission layer 140 may include tris(8-quinolinolato)aluminum (Alq3), 4,4′-N,N′-dicarbazole-biphenyl (CBP), poly(n-vinylcarbazole) (PVK), 4,4′,4″-tris(N-carbazolyl)triphenylamine (TCTA), 1,3,5-tris(N-phenylbenzimidazole-2-yl)benzene (TPBI), 3-tert-butyl-9,10-di(naphtho-2-yl)anthracene (TBADN), distyrylarylene (DSA), 4,4′-bis(9-carbazole)-2,2′-dimethyl-biphenyl (dmCBP), bis(2,2-diphenyl vinyl)-1,1′-biphenyl (DPVBi), 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-(E)-2-(6-((E)-4-(diphenylamino)styryl)naphthalen-2-Avinyl)phenyl)-N-phenylbenzeneamine (N-BDAVBi), 2,5,8,11-tetra-t-butylperylene (TBPe), 1,1-dipyrene, 1,4-dipyrenylbenzene, 1,4-bis(N,N-diphenylamino)pyrene, etc., as the host material and/or the dopant material.

In some embodiments, the emission layer 140 may include a compound represented by the following Formula 4.

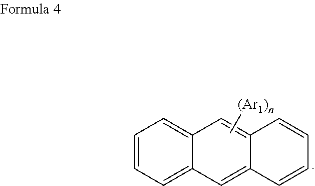

In Formula 4, Ar₁ may be selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group, and a hydroxyl group, and n may be an integer from 1 to 10.

Non-limiting examples of the compound represented by Formula 4 may include the following Compounds 3-1 to 3-12 collectively denoted as Formula 10. However, the compound represented by Formula 4 is not limited to the following Compounds 3-1 to 3-12.

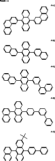

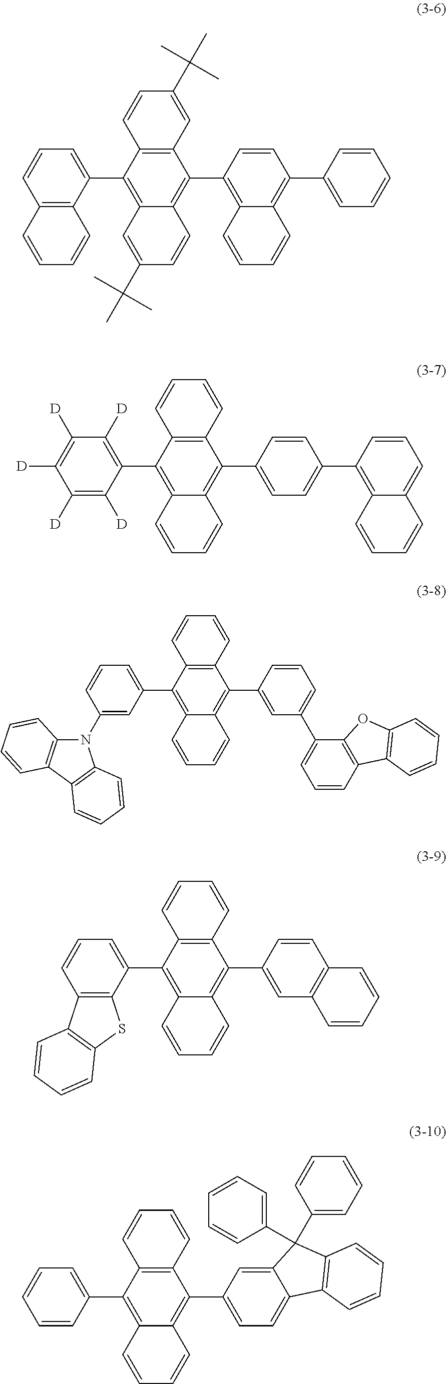

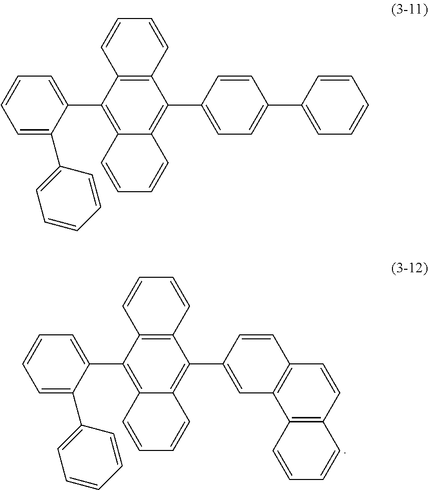

In embodiments where the emission layer 140 includes the compound represented by Formula 4, the anode-side hole transport layer 131 may further improve the hole injection from the first electrode 120. Therefore, the emission layer 140 including the compound represented by Formula 4 may improve the emission efficiency and emission life of the organic electroluminescent device 100.

In some embodiments, the emission layer 140 may include the compound represented by Formula 4 as a host material or as a dopant material.

The emission layer 140 may be formed as an emission layer emitting light of a specific color. For example, the emission layer 140 may be formed as a red emitting layer, a green emitting layer, or a blue emitting layer.

In embodiments where the emission layer 140 is the blue emitting layer, any suitable blue dopants may be used. For example, perylene and/or the derivative thereof, an iridium (Ir) complex (such as bis[2-(4,6-difluorophenyl)pyridinate]picolinate iridium(III) (Flrpic)), etc. may be used as a blue dopant.

In embodiments where the emission layer 140 is the red emitting layer, any suitable red dopants may be used. For example, rubrene and/or the derivative thereof, 4-dicyanomethylene-2-(p-dimethylaminostyryl)-6-methyl-4H-pyrane (DCM) and/or the derivative thereof, an iridium complex (such as bis(1-phenylisoquinoline)(acetylacetonate) iridium(III) (Ir(piq)₂(acac)), an osmium (Os) complex, a platinum complex, etc. may be used as a red dopant.

In embodiments where the emission layer 140 is the green emitting layer, any suitable green dopants may be used. For example, coumarin and/or the derivative thereof, an iridium complex (such as tris(2-phenylpyridine) iridium(III) (Ir(ppy)₃)), etc. may be used.

### 1-1-6. Configuration of Electron Transport Layer

The electron transport layer 150 is a layer including an electron transport material and having an electron transporting function. The electron transport layer 150 may be formed, for example, on the emission layer 140 to a layer thickness from about 15 nm to about 50 nm. The electron transport material included in the electron transport layer 150 may be any suitable electron transport material. Non-limiting examples of the suitable electron transport material may include, for example, a quinoline derivative (such as tris(8-quinolinolato)aluminum (Alq3)), a 1,2,4-triazole derivative (TAZ), bis(2-methyl-8-quinolinolato)-(p-phenylphenolate)-aluminum (BAlq), berylliumbis(benzoquinoline-10-olate) (BeBq2), a Li complex (such as lithium quinolate (LiQ)), a material having a nitrogen-containing aromatic ring, etc. Examples of the nitrogen-containing aromatic ring may include a material including a pyridine ring (such as 1,3,5-tri[(3-pyridyl)-phen-3-yl]benzene), a material including a triazine ring (such as 2,4,6-tris(3′-(pyridine-3-yl)biphenyl-3-yl)-1,3,5-triazine), a material including an imidazole derivative (such as 2-(4-(N-phenylbenzoim idazolyl-1-ylphenyl)-9,10-dinaphthylanthracene)), etc.

### 1-1-7. Configuration of Electron Injection Layer

The electron injection layer 160 is a layer having the function of facilitating the injection of electrons from a second electrode 170. The electron injection layer 160 may be formed, for example, on the electron transport layer 150 to a layer thickness from about 0.3 nm to about 9 nm. The electron injection layer 160 may be formed using any suitable material that may be used as a material for forming an electron injection layer. Non-liming examples of the material for forming the electron injection layer 160 may include lithium fluoride (LiF), sodium chloride (NaCl), cesium fluoride (CsF), lithium oxide (Li₂O), barium oxide (BaO), lithium quinolinolate (LiQ), etc.

### 1-1-8. Configuration of Second Electrode

The second electrode 170 may be, for example, a cathode and may be formed on the electron injection layer 160 using an evaporation method or a sputtering method. For example, the second electrode 170 may be formed as a reflection type electrode (e.g., reflection electrode) using a metal, an alloy, a conductive compound, etc. having small work function. The second electrode 170 may be formed using, for example, lithium (Li), magnesium (Mg), aluminum (Al), silver (Ag), aluminum-lithium (Al—Li), calcium (Ca), magnesium-indium (Mg—In), magnesium-silver (Mg—Ag), etc. In some embodiments, the second electrode 170 may be formed as a transmission type electrode (e.g., transmission electrode) using ITO, IZO, etc.

### 1-1-9. Modification Example of Organic Electroluminescent Device

The structure of the organic electroluminescent device 100 shown in the drawing is an embodiment of the present disclosure, and the structure of the organic electroluminescent device 100 according to the present embodiments is not limited to the drawing. For example, in the organic electroluminescent device 100 according to embodiments of the present disclosure, some layers may be formed as a multi-layer (e.g., having a multi-layer structure), or additional layers may be formed. In some embodiments, in the organic electroluminescent device 100 according to an embodiment, the electron transport layer 150 and the electron injection layer 160 may be a single integrated layer or may not include more than at least one layer. In some embodiments, the organic electroluminescent device 100 may not include (e.g., may exclude) at least one layer selected from the electron transport layer 150 and the electron injection layer 160.

In some embodiments, in the organic electroluminescent device 100 according to an embodiment, a hole injection layer may be provided between the first electrode 120 and the hole transport layer 130.

The hole injection layer is a layer having the function of facilitating the hole injection from the first electrode 120. The hole injection layer may be formed, for example, on the first electrode 120 to a layer thickness from about 10 nm to about 150 nm. The hole injection layer may be formed using any suitable material that may be used as a material for forming a hole injection layer. Non-limiting examples of the material for forming the hole injection layer may include a triphenylamine-containing polyether ketone (TPAPEK), 4-isopropyl-4′-methyldiphenyliodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), a phthalocyanine compound (such as copper phthalocyanine), 4,4′,4″-tris(3-methylphenylphenylamino)triphenylamine (m-MTDATA), N,N′-di(1-naphthyl)-N,N′-diphenylbenzidine (NPB), 4,4′,4″-tris{N,N-diamino}triphenylamine (TDATA), 4,4′,4″-tris(N,N-2-naphthylphenylamino)triphenylamine (2-TNATA), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), and polyaniline/poly(4-styrenesulfonate (PANI/PSS).

### 1-1-10. Method of Manufacturing Organic Electroluminescent Device

Each layer of the organic electroluminescent device 100 according to an embodiment of the present disclosure as described above may be formed by selecting one or more appropriate layer forming methods, according to the materials used for forming each layer, such as vacuum evaporation, sputtering, and/or various suitable coating methods.

For example, a metal layer such as the first electrode 120, the second electrode 170, and the electron injection layer 160 may be formed using an evaporation method including an electron beam evaporation method, a hot filament evaporation method and/or a vacuum evaporation method; a sputtering method; and/or a plating method (such as an electroplating method and/or an electroless plating method).

An organic layer (such as the hole transport layer 130, the emission layer 140 and/or the electron transport layer 150) may be formed using a physical vapor deposition (PVD) method (such as a vacuum deposition method); a printing method (such as a screen printing method and/or an ink jet printing method); a laser transcription method; and/or a coating method (such as a spin coating method).

Hereinabove, embodiments of the organic electroluminescent device 100 have been explained in some detail.

### 1-2. Examples

Hereinafter, the organic electroluminescent devices according to example embodiments of the present disclosure will be explained with reference to examples and comparative examples. However, it will be understood that the following examples are provided only for illustration, and the organic electroluminescent devices according to example embodiments are not limited thereto.

### 1-2-1. Synthesis of Compounds

### Synthetic Example 1

### Synthesis of Compound 17

Compound 17 was synthesized by the following synthetic scheme.

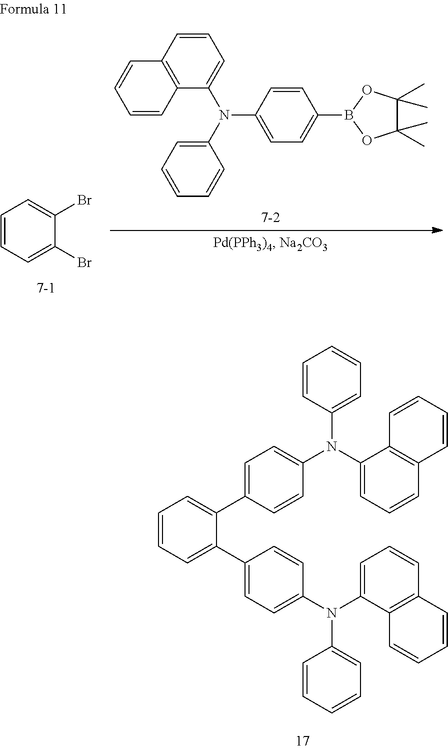 [SMILES: CC1(C)OB(c2ccc(N(c3ccccc3)c3cccc4ccccc34)cc2)OC1(C)C ; Brc1ccccc1Br ; c1ccc(N(c2ccc(-c3ccccc3-c3ccc(N(c4ccccc4)c4cccc5ccccc45)cc3)cc2)c2cccc3ccccc23)cc1]

To a mixture of 1.82 g (7.71 mmol) of Compound 7-1 (dibromobenzene), 6.83 g (16.2 mmol) of Compound 7-2 (boronic acid), 200 mL of toluene, 20 mL of ethanol and 20 ml of 2M-sodium carbonate aqueous solution, 891 mg (0.771 mmol) of tetrakistriphenylphosphine palladium (0) was added under an argon atmosphere, followed by refluxing the resultant for about 8 hours. The reaction product was cooled to room temperature, water was added to the reaction product, and extraction with toluene was conducted three times. A resulting organic layer was washed with a saturated saline solution, dried with anhydrous magnesium sulfate and concentrated. The obtained residual product was separated using column chromatography to produce 3.33 g (Yield 65%) of Compound 17 as a pale yellow solid. The molecular weight of Compound 17 thus obtained was measured by Fast Atom Bombardment Mass Spectrometry (FAB-MS), and the molecular weight of Compound 17 (C₅₀H₃₆N₂) was 664. In addition, chemical shift values (δ) of Compound 17 measured by ¹H NMR (300 MHz, CDCl₃) were 7.05-7.18 (12H), 7.20-7.55 (18H), 7.75 (d, J=7 Hz, 2H), 7.88 (d, J=7 Hz, 2H), 7.95 (d, J=7 Hz, 2H). The resulting product was confirmed to be Compound 17.

### Synthetic Example 2

### Synthesis of Compound 33

Compound 33 was synthesized by the following synthetic scheme.

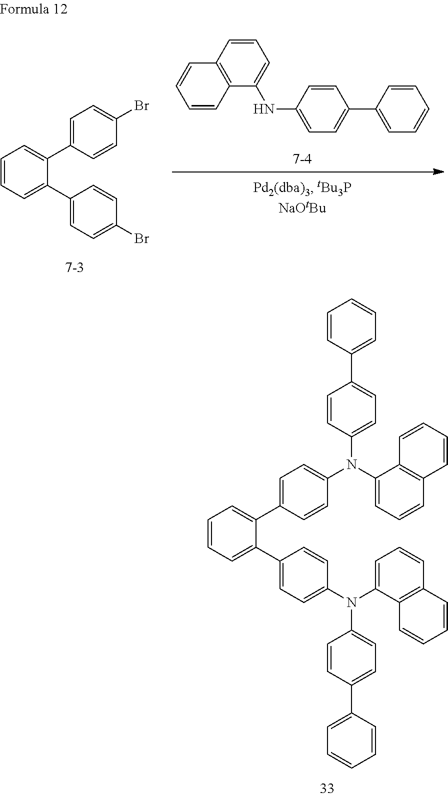 [SMILES: Brc1ccc(-c2ccccc2-c2ccc(Br)cc2)cc1 ; c1ccc(-c2ccc(Nc3cccc4ccccc34)cc2)cc1 ; c1ccc(-c2ccc(N(c3ccc(-c4ccccc4-c4ccc(N(c5ccc(-c6ccccc6)cc5)c5cccc6ccccc56)cc4)cc3)c3cccc4ccccc34)cc2)cc1]

To a mixture of 2.08 g (5.37 mmol) of Compound 7-3 (a dibromo compound), 3.25 g (11.0 mmol) of Compound 7-4 (an amine compound), 278 mg (0.268 mmol) of a tris(dibenzylideneacetone)dipalladium(0)chloroform addition product, 1.58 g (16.1 mmol) of sodium-t-butoxide and 200 mL of an anhydrous xylene solution, 0.201 mL of tri-t-butylphosphine and 0.322 mmol of 1.6 M xylene solution were added under an argon atmosphere, followed by stirring the resultant at about 120° C. for about 12 hours. The reaction product was cooled to room temperature, water was added to the reaction product, and extraction with toluene was conducted three times. A resulting organic layer was washed with a saturated saline solution, dried with anhydrous magnesium sulfate and concentrated. The obtained residual product was separated using column chromatography to produce 2.50 g (Yield 57%) of Compound 33 as a pale yellow solid. The molecular weight of Compound 33 thus obtained was measured by FAB-MS, and the molecular weight of Compound 33 (C₆₂H₄₄N₂) was 816. In addition, chemical shift values (δ) of Compound 33 measured by ¹H NMR (300 MHz, CDCl₃) were 7.02-7.20 (10H), 7.20-7.57 (28H), 7.78 (d, J=7 Hz, 2H), 7.90 (d, J=7 Hz, 2H), 7.96 (d, J=7 Hz, 2H). The resulting product was confirmed to be Compound 33.

### Synthetic Example 3

### Synthesis of Compound 49

Compound 49 was synthesized according to the following synthetic scheme.

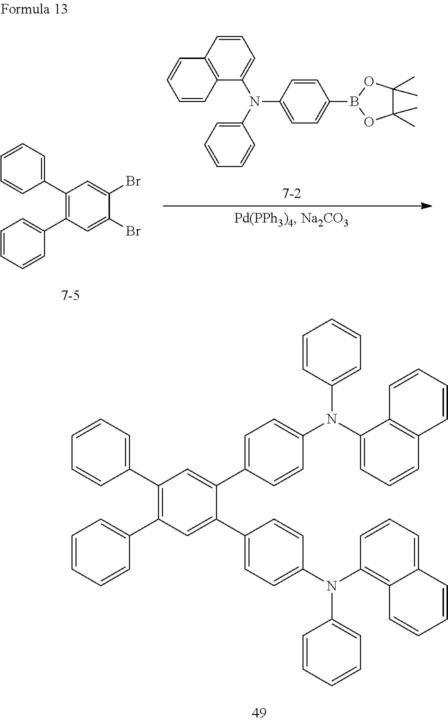 [SMILES: Brc1cc(-c2ccccc2)c(-c2ccccc2)cc1Br ; CC1(C)OB(c2ccc(N(c3ccccc3)c3cccc4ccccc34)cc2)OC1(C)C ; c1ccc(-c2cc(-c3ccc(N(c4ccccc4)c4cccc5ccccc45)cc3)c(-c3ccc(N(c4ccccc4)c4cccc5ccccc45)cc3)cc2-c2ccccc2)cc1]

To a mixture of 2.01 g (5.18 mmol) of Compound 7-5 (a dibromo compound), 4.58 g (10.9 mmol) of Compound 7-2 (boronic acid), 300 mL of toluene, 20 mL of ethanol and 20 ml of 2M-sodium carbonate aqueous solution, 599 mg (0.518 mmol) of tetrakistriphenylphosphine palladium (0) was added under an argon atmosphere, followed by refluxing the resultant for about 13 hours. The reaction product was cooled to room temperature, water was added to the reaction product, and extraction with toluene was conducted three times. A resulting organic layer was washed with a saturated saline solution, dried with anhydrous magnesium sulfate and concentrated. The obtained residual product was separated using column chromatography to produce 2.67 g (Yield 63%) of Compound 49 (a diamine compound) as a pale yellow solid. The molecular weight of Compound 49 thus obtained was measured by FAB-MS, and the molecular weight of Compound 49 (C₆₂H₄₄N₂) was 816. In addition, chemical shift values (δ) of Compound 49 measured by ¹H NMR (300 MHz, CDCl₃) were 6.98-7.22 (12H), 7.22-7.65 (26H), 7.80 (d, J=7 Hz, 2H), 7.92 (d, J=7 Hz, 2H), 7.98 (d, J=7 Hz, 2H). The resulting product was confirmed to be Compound 49.

### 1-2-2. Manufacture of Organic Electroluminescent Device Including Anode-Side Hole Transport Layer Containing Anode-Side Hole Transport Material and Doped with Electron Accepting Material

An organic electroluminescent device according to an embodiment was manufactured by the following manufacturing method.

First, an ITO-glass substrate that was patterned and washed in advance, was subjected to surface treatment using UV-Ozone (O₃). The layer thickness of the ITO layer (herein, a first electrode) on a glass substrate was about 150 nm. After ozone treatment, the substrate was washed and inserted in a glass bell jar type evaporator (e.g., a glass bell jar evaporator) for forming an organic layer, and an anode-side hole transport layer, a middle hole transport layer, an emission layer-side hole transport layer, an emission layer, and an electron transport layer were evaporated one by one under a vacuum degree of about 10⁻⁴ to about 10⁻⁵ Pa. The layer thickness of each of the anode-side hole transport layer, the middle hole transport layer, and the emission layer-side hole transport layer was about 10 nm. The layer thickness of the emission layer was about 25 nm, and the layer thickness of the electron transport layer was about 25 nm. Then, the substrate was moved into a glass bell jar type evaporator (e.g., a glass bell jar evaporator) for forming a metal layer, and the electron injection layer and the second electrode were evaporated under a vacuum degree of about 10⁻⁴ to about 10⁻⁵ Pa. The layer thickness of the electron injection layer was about 1 nm and the layer thickness of the second electrode was about 100 nm.

Here, the anode-side hole transport layer, the middle hole transport layer and the emission layer-side hole transport layer collectively form the hole transport layer having a laminated structure. The anode-side hole transport layer, the middle hole transport layer and the emission layer-side hole transport layer of Examples 1-1 to 1-7 and Comparative Examples 1-1 to 1-4 were manufactured using the materials as shown in the following Table 1.

As used herein, the expression of “Compound 2-3 (a wt %)+4-15 (b wt %)” in Table 1 refers to Compound 2-3, which is an anode-side hole transport material, being doped with Compound 4-15, which is an electron accepting material. The amount (e.g., weight ratio) of Compound 2-3 to Compound 4-15 is a:b.

Compounds 6-1, 6-2 and 6-3 (illustrated below and collectively denoted as Formula 14), as used in Table 1, are suitable hole transport materials in the art of organic electroluminescent devices.

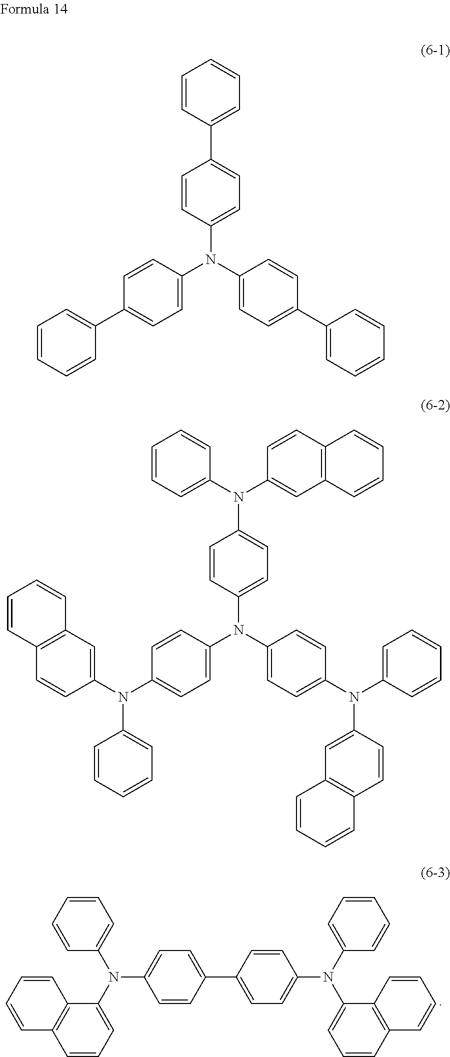 [SMILES: c1ccc(-c2ccc(N(c3ccc(-c4ccccc4)cc3)c3ccc(-c4ccccc4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

9,10-di(2-naphthyl)anthracene (ADN, Compound 3-2) was used as the host material of the emission layer, and 2,5,8,11-tetra-t-butylperylene (TBP) was used as a dopant material. The dopant material was added in an amount (e.g., weight ratio) of about 3 wt % on the basis of the amount of the host material. An electron transport layer was formed using Alq3, an electron injection layer was formed using LiF, and a second electrode was formed using aluminum (Al).

### 1-3. Evaluation Results

The driving voltage, the emission efficiency, and half life of each organic electroluminescent device manufactured according to the above-described method were evaluated. Evaluation results are shown in the following Table 2. Here, the driving voltage and the emission efficiency in each Example and Comparative Example were obtained by measuring with current density of about 10 mA/cm². In addition, the half life was obtained by measuring luminance based on the initial luminance of about 1,000 cd/m².

The measurements were conducted using a source meter of 2400 series produced by Keithley Instruments Co., Color brightness photometer CS-200 (Konica Minolta, measurement angle of 1°), and a PC program LabVIEW8.2 (National instruments, Japan) for measurement in a dark room.

TABLE 1

| Device | | | Emission |
|---|---|---|---|
| manufacturing | Anode-side hole | Middle hole | layer-side hole |
| examples | transport layer | transport layer | transport layer |
| Example 1-1 | Compound 2-3 | Compound 2-3 | Compound 33 |
| | (97 wt %) + 4-15 | | |
| | (3 wt %) | | |
| Example 1-2 | Compound 2-3 | Compound 2-3 | Compound 49 |
| | (97 wt %) + 4-15 | | |
| | (3 wt %) | | |
| Example 1-3 | Compound 2-3 | Compound 2-17 | Compound 49 |
| | (97 wt %) + 4-15 | | |
| | (3 wt %) | | |
| Example 1-4 | Compound 2-3 | Compound 2-3 | Compound 33 |
| | (97 wt %) + 4-15 | | |
| | (3 wt %) | | |
| Example 1-5 | Compound 6-2 | Compound 2-3 | Compound 33 |
| | (97 wt %) + 4-15 | | |
| | (3 wt %) | | |
| Example 1-6 | Compound 2-3 | Compound 6-3 | Compound 33 |
| | (97 wt %) + 4-15 | | |
| | (3 wt %) | | |
| Example 1-7 | Compound 2-3 | Compound 2-3 | Compound 17 |
| | (97 wt %) + 4-15 | | |
| | (3 wt %) | | |
| Comparative | Compound 2-3 | Compound 33 | Compound 2-3 |
| Example 1-1 | (97 wt %) + 4-15 | | |
| | (3 wt %) | | |
| Comparative | Compound 2-3 | Compound 2-3 | Compound 33 |
| Example 1-2 | | | |
| Comparative | Compound 2-3 | Compound 2-3 | Compound 6-1 |
| Example 1-3 | (97 wt %) + 4-15 | | |
| | (3 wt %) | | |
| Comparative | Compound 2-3 | Compound 2-3 | Compound 33 |
| Example 1-4 | (97 wt %) + 4-15 | | |
| | (3 wt %) | | |

TABLE 2

| | Current | | Emission | Half life |
|---|---|---|---|---|
| | density | Voltage | efficiency | LT₅₀ |
| | (mA/cm²) | (V) | (cd/A) | (h) |
| Example 1-1 | 10 | 6.1 | 7.7 | 4,000 |
| Example 1-2 | 10 | 6.2 | 7.6 | 4,000 |
| Example 1-3 | 10 | 6.1 | 7.6 | 3,900 |
| Example 1-4 | 10 | 6.3 | 7.3 | 3,500 |
| Example 1-5 | 10 | 6.4 | 7.5 | 3,100 |
| Example 1-6 | 10 | 6.3 | 7.6 | 3,100 |
| Example 1-7 | 10 | 6.1 | 7.7 | 3,800 |
| Comparative | 10 | 6.4 | 7.1 | 2,000 |
| Example 1-1 | | | | |
| Comparative | 10 | 7.4 | 6.8 | 2,200 |
| Example 1-2 | | | | |
| Comparative | 10 | 6.4 | 7.3 | 2,300 |
| Example 1-3 | | | | |
| Comparative | 10 | 8.2 | 5.1 | 1,000 |
| Example 1-4 | | | | |

Referring to the results in Tables 1 and 2, the organic electroluminescent devices according to Examples 1-1 to 1-7 exhibited same or improved emission efficiency and increased half life, when compared to those according to Comparative Examples 1-1 to 1-4. Without being bound by any particular theory, it is believed that the emission efficiency and emission life of the organic electroluminescent devices according to the Examples were increased at least in part due to providing the anode-side hole transport layer, the middle hole transport layer, and the emission layer-side hole transport layer between the first electrode and the emission layer, according to embodiments of the present disclosure. In addition, the driving voltage of the organic electroluminescent devices of Examples 1-1 to 1-7 was either the same as or lower than that of the organic electroluminescent devices of Comparative Examples 1-1 to 1-4.

For example, when comparing the organic electroluminescent device of Example 1-1 with that of Comparative Example 1-2, the properties of Example 1-1 were improved. In Comparative Example 1-2, the electron accepting material (e.g., Compound 4-15) was not doped into the anode-side hole transport layer. Accordingly, in one embodiment, the anode-side hole transport layer doped with the electron accepting material is preferable.

When comparing Example 1-1 with Comparative Example 1-1, the properties of Example 1-1 were improved. In Comparative Example 1-1, the compounds included in the middle hole transport layer and the emission layer-side hole transport layer were switched, when compared to those in Example 1-1. Therefore, in one embodiment, it is preferable to position the emission layer-side hole transport layer including the compound represented by Formula 1 adjacent to the emission layer.

When comparing Examples 1-1 and 1-2 with Comparative Example 1-3, the properties of Examples 1-1 and 1-2 were improved. In Comparative Example 1-3, Compound 6-1 was used as the emission layer-side hole transport material included in the emission layer-side hole transport layer instead of the compound represented by Formula 1. Therefore, in one embodiment, the inclusion of the compound represented by Formula 1 in the emission layer-side hole transport layer is preferable.

When comparing Example 1-1 with Comparative Example 1-4, the properties of Example 1-1 were improved. In Comparative Example 1-4, an anode-side hole transport material is doped with an electron accepting material. Therefore, in one embodiment, the anode-side hole transport layer doped with the electron accepting material would preferably be used in the anode-side hole transport layer.

In Examples 1-2 to 1-4 and 1-7, one of the middle hole transport material and the emission layer-side hole transport material was changed, as compared to Example 1-1, to a different material according to embodiments of the present disclosure. The organic electroluminescent devices of Examples 1-2 to 1-4 and 1-7 exhibited similarly improved characteristics, when compared to those of the Comparative Examples, as did the organic electroluminescent device of Example 1-1.

When comparing Example 1-1 with Example 1-5, the properties of Example 1-1 were improved. In Example 1-5, Compound 6-2 not including a carbazolyl group was used as the anode-side hole transport material included in the anode-side hole transport layer instead of the compound represented by Formula 3. Therefore, in one embodiment, the anode-side hole transport material included in the anode-side hole transport layer is preferably the compound represented by Formula 3.

In addition, when comparing Example 1-1 with Example 1-6, the properties of Example 1-1 were improved. In Example 1-6, Compound 6-3 not including a carbazolyl group was used as the middle hole transport material included in the middle hole transport layer instead of the compound represented by Formula 3. Therefore, in one embodiment, the middle hole transport material included in the middle hole transport layer is preferably the compound represented by Formula 3.

As described above, according to example embodiments, when the anode-side hole transport layer doped with the electron accepting material, the middle hole transport layer, and the emission layer-side hole transport layer including the compound represented by Formula 1 are laminated between the first electrode (e.g., anode) and the emission layer, the emission efficiency and emission life of the organic electroluminescent device may be increased.

It is believed that the emission layer-side hole transport layer including the compound represented by Formula 1 is capable of protecting the hole transport layer from the diffusion of electrons not consumed in the emission layer and thus may prevent or reduce the diffusion of excited state energy (e.g., excitons) generated in the emission layer into the hole transport layer, thereby controlling the charge balance of the whole organic electroluminescent device. In addition, it is believed that the emission layer-side hole transport layer including the compound represented by Formula 1 may also restrain or reduce the diffusion of the electron accepting material included in the anode-side hole transport layer provided near the first electrode (e.g., anode) into the emission layer.

Example embodiments of the inventive concept have been explained hereinabove in more detail by referring to the attached drawing, however embodiments of the present inventive concept are not limited thereto. As those skilled in the art would recognize, the inventive concept may be embodied in many different forms and should not be construed as being limited to the embodiments set forth herein.

### 2-1. Configuration of Organic Electroluminescent Device Including Anode-Side Hole Transport Layer Containing Mainly Electron Accepting Material

Hereinafter, an organic electroluminescent device including an anode-side hole transport layer including mainly an electron accepting material will be explained with reference to the drawing.

The organic electroluminescent device including the anode-side hole transport layer including mainly the electron accepting material may include the above-mentioned anode-side hole transport material and may have the same whole configuration as the organic electroluminescent device including the anode-side hole transport layer doped with the electron accepting material, including the same configuration of the substrate, the same configuration of the first electrode, the same configuration of the emission layer, the same configuration of the electron transport layer, the same configuration of the electron injection layer, and the same configuration of the second electrode, and may be manufactured via the same method of manufacturing an organic electroluminescent device, except that the organic electroluminescent device of the present embodiment may have a different configuration of the hole transport layer. Therefore, the configuration of the hole transport layer will be explained in more detail, hereinafter.

### 2-1-1. Configuration of Hole Transport Layer

The hole transport layer 130 may include a hole transport material having a hole transporting function. The hole transport layer 130 may be formed, for example, on the first electrode 120 to a layer thickness (the total layer thickness of a laminated structure of the hole transport layer) from about 10 nm to about 150 nm.

For example, the hole transport layer 130 of the organic electroluminescent device 100 according to an embodiment may be formed as a multi-layer by sequentially laminating, on the first electrode 120, an anode-side hole transport layer 131, a middle hole transport layer 133, and an emission layer-side hole transport layer 135. The ratio of the thicknesses of the hole transport layers is not specifically limited.

### 2-1-1-1. Configuration of Anode-Side Hole Transport Layer

The anode-side hole transport layer 131 may be a layer including mainly (e.g., as a major component) an electron accepting material. For example, the anode-side hole transport layer 131 may be formed on the first electrode 120.

The anode-side hole transport layer 131 may include a material other than the electron accepting material, however, it may mainly include (e.g., include as a major component) the electron accepting material. For example, the anode-side hole transport layer 131 may include greater than about 50 wt % of the electron accepting material on the basis of the total amount of the anode-side hole transport layer 131, and may in some embodiments include only the electron accepting material.

The anode-side hole transport layer 131 may be formed to include mainly the electron accepting material and may improve hole injection from the first electrode 120. Therefore, in one embodiment, the anode-side hole transport layer 131 may preferably be around (or near) the first electrode 120, for example, may be provided adjacent to the first electrode 120.

The electron accepting material included in the anode-side hole transport layer 131 may be any suitable electron accepting material. In some embodiments, the electron accepting material included in the anode-side hole transport layer 131 may have a lowest unoccupied molecular orbital (LUMO) level from about −9.0 eV to about −4.0 eV, for example, the LUMO level from about −6.0 eV to about −4.0 eV.

Non-limiting examples of the electron accepting material having the LUMO level from about −9.0 eV to about −4.0 eV may include the following Compounds 4-1 to 4-14 collectively denoted as Formula 4.

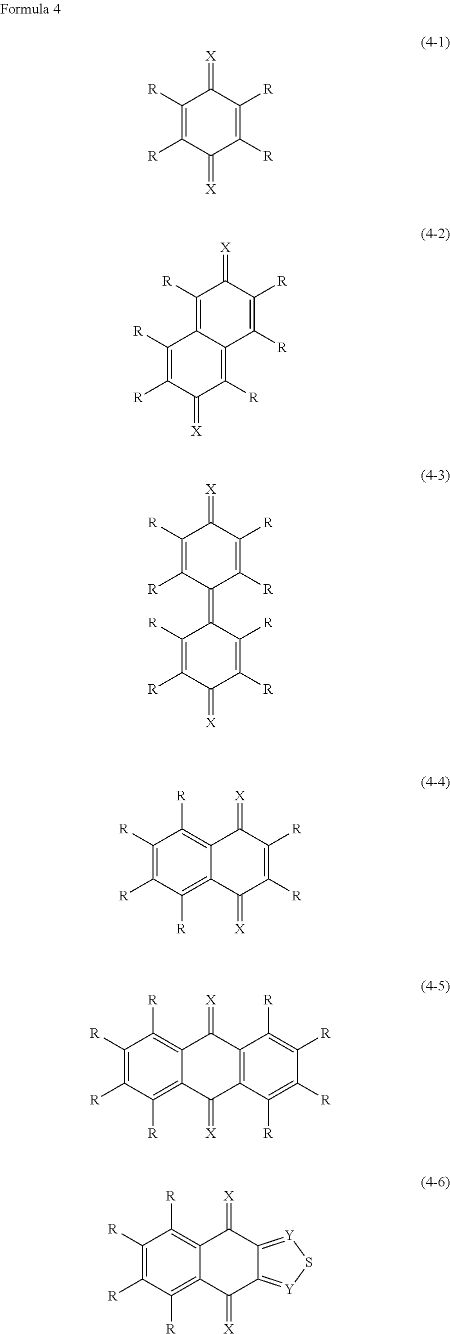

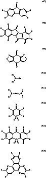

In the above Compounds 4-1 to 4-14, R may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms, and a heteroaryl group having 5 to 50 carbon atoms for forming a ring. Ar may be selected from an aryl group substituted with an electron withdrawing group, an unsubstituted aryl group having 6 to 50 carbon atoms for forming a ring, and a substituted or unsubstituted heteroaryl group having 5 to 50 carbon atoms for forming a ring, Y may be a methine group (—CH═) or a nitrogen atom (—N═), Z may be a pseudohalogen (e.g., a pseudohalogen group) or may include sulfur (S) (e.g., Z may be a sulfur-containing group), n may be an integer of 10 or less, and X may be one of the substituent groups represented by Compounds X1 to X7 and collectively denoted as Formula 6.

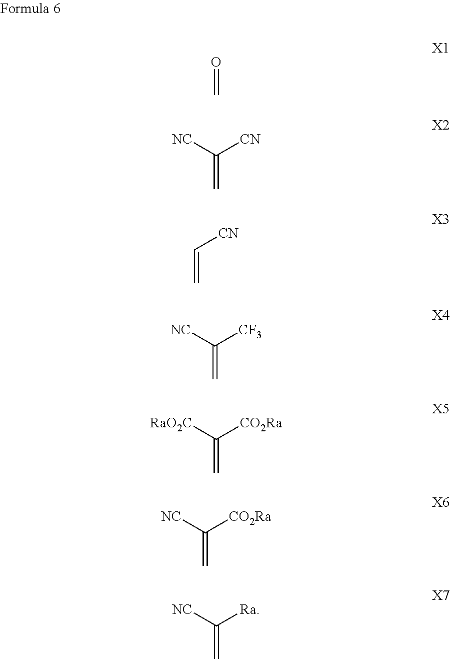

In Compounds X1 to X7 in Formula 6, Ra may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 carbon atoms for forming a ring, and a substituted or unsubstituted heteroaryl group having 5 to 50 carbon atoms for forming a ring.

Non-limiting examples of the substituted or unsubstituted aryl group having 6 to 50 carbon atoms for forming a ring represented by, for example, R, Ar and/or Ra may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, an m-terphenyl-4-yl group, an m-terphenyl-3-yl group, an m-terphenyl-2-yl group, an o-tolyl group, an m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, etc.

Non-limiting examples of the substituted or unsubstituted heteroaryl group having 5 to 50 carbon atoms for forming a ring represented by, for example, R, Ar and/or Ra may include an 1-pyrrolyl group, a 2-pyrrolyl group, a 3-pyrrolyl group, a pyridinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, an 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, an 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, etc.

Non-limiting examples of the substituted or unsubstituted fluoroalkyl group having 1 to 50 carbon atoms represented by, for example, R and/or Ra may include a perfluoroalkyl group (such as a trifluoromethyl group, a pentafluoroethyl group, a heptafluoropropyl group and/or a heptadecafluorooctane group), a monofluoromethyl group, a difluoromethyl group, a trifluoroethyl group, a tetrafluoropropyl group, an octafluoropentyl group, etc.

Non-limiting examples of the substituted or unsubstituted alkyl group having 1 to 50 carbon atoms represented by, for example, R and/or Ra may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-am inoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The substituted or unsubstituted alkoxy group having 1 to 50 carbon atoms represented by, for example, R and/or Ra may be a group represented by —OY. Non-limiting examples of Y may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc.

Non-limiting examples of the halogen atom represented by, for example, R and/or Ra may include fluorine (F), chlorine (CI), bromine (Br), iodine (I), etc.

In some embodiments, the electron accepting material may include Compounds 4-15 and 4-16 collectively denoted as Formula 7. For example, the LUMO level of Compound 4-15 may be about −4.40 eV, and the LUMO level of Compound 4-16 may be about −5.20 eV. However, the electron accepting material is not limited to the following Compounds 4-15 and 4-15.

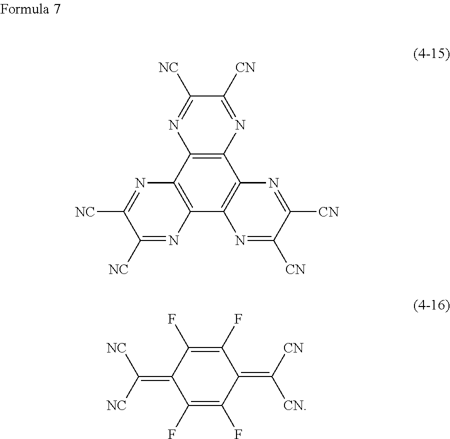 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

### 2-1-1-2. Configuration of Middle Hole Transport Layer

The middle hole transport layer 133 may include a middle hole transport material. The middle hole transport layer 133 may be formed, for example, on the anode-side hole transport layer 131.

The middle hole transport material included in the middle hole transport layer 133 may be any suitable hole transport materials. Non-limiting examples of the middle hole transport material included in the middle hole transport layer 133 may be TAPC, a carbazole derivative (such as N-phenyl carbazole and/or polyvinyl carbazole), TPD, TCTA, NPB, etc.

In some embodiments, the middle hole transport material may be a compound represented by the following Formula 3.

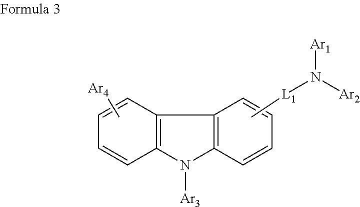

In Formula 3, Ar₁, Ar₂, and Ar₃ may be each independently selected from a substituted or unsubstituted aryl group having 6 to 50 carbon atoms for forming a ring, and a substituted or unsubstituted heteroaryl group having 5 to 50 carbon atoms for forming a ring. Ar₄ may be hydrogen, deuterium, a halogen atom, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms. L₁ may be a direct linkage (e.g., a bond such as a single bond), a substituted or unsubstituted arylene group having 6 to 18 carbon atoms for forming a ring, and a substituted or unsubstituted heteroarylene group having 5 to 15 carbon atoms for forming a ring.

Non-limiting examples of Ar₁, Ar₂ and Ar₃ may include a phenyl group, a biphenyl group, a terphenyl group, a naphthyl group, an anthryl group, a phenanthryl group, a fluorenyl group, an indenyl group, a pyrenyl group, an acenaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. For example, Ar₁, Ar₂ and Ar₃ may each independently include the phenyl group, the biphenyl group, the terphenyl group, the fluorenyl group, the carbazolyl group, the dibenzofuranyl group, etc.

Non-limiting examples of Ar₄ may include a phenyl group, a biphenyl group, a terphenyl group, a naphthyl group, an anthryl group, a phenanthryl group, a fluorenyl group, an indenyl group, a pyrenyl group, an acenaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, a methyl group, an ethyl group, a propyl group, an isopropyl group, an n-butyl group, etc. For example, Ar₄ may include the phenyl group, the biphenyl group, the terphenyl group, the fluorenyl group, the carbazolyl group, the dibenzofuranyl group, the methyl group, the ethyl group, etc.

Non-limiting examples of L₁, other than the direct linkage, may include a phenylene group, a biphenylene group, a terphenylene group, a naphthylene group, an anthrylene group, a phenanthrylene group, a fluorenylene group, an indenylene group, a pyrenylene group, an acenaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienylene group, etc. For example, L₁ may include a direct linkage, the phenylene group, the biphenylene group, the terphenylene group, the fluorenylene group, the carbazolylene group, and/or the dibenzofuranylene group.

Non-limiting examples of the compound represented by Formula 3 may include the following Compounds 2-1 to 2-17 collectively denoted as Formula 8. However, the compound represented by Formula 3 is not limited to Compounds 2-1 to 2-17.

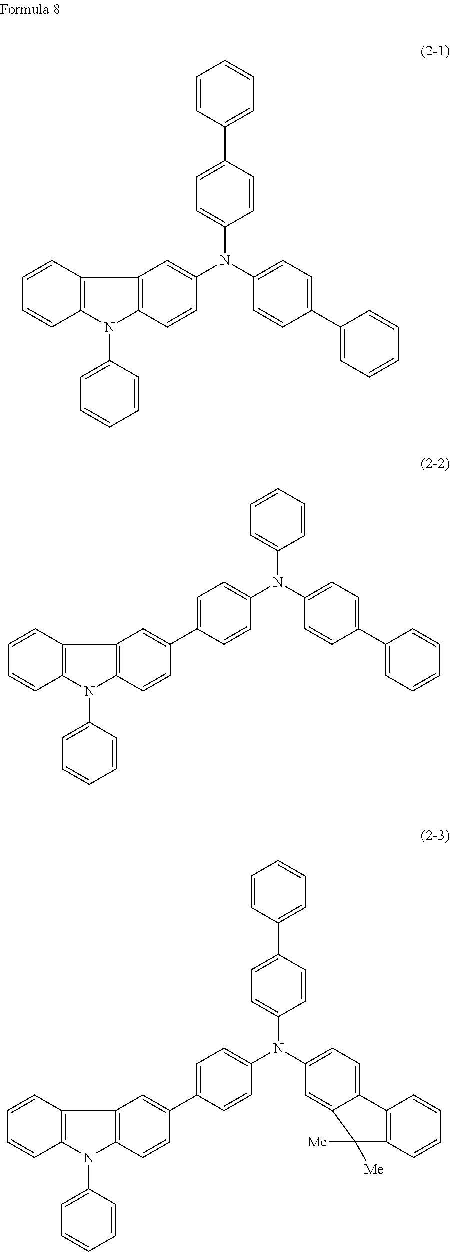 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

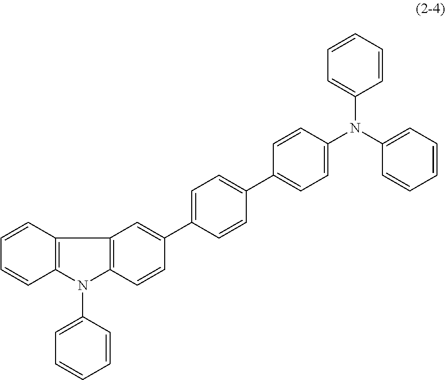 [SMILES: c1ccc(N(c2ccccc2)c2ccc(-c3ccc(-c4ccc5c(c4)c4ccccc4n5-c4ccccc4)cc3)cc2)cc1]

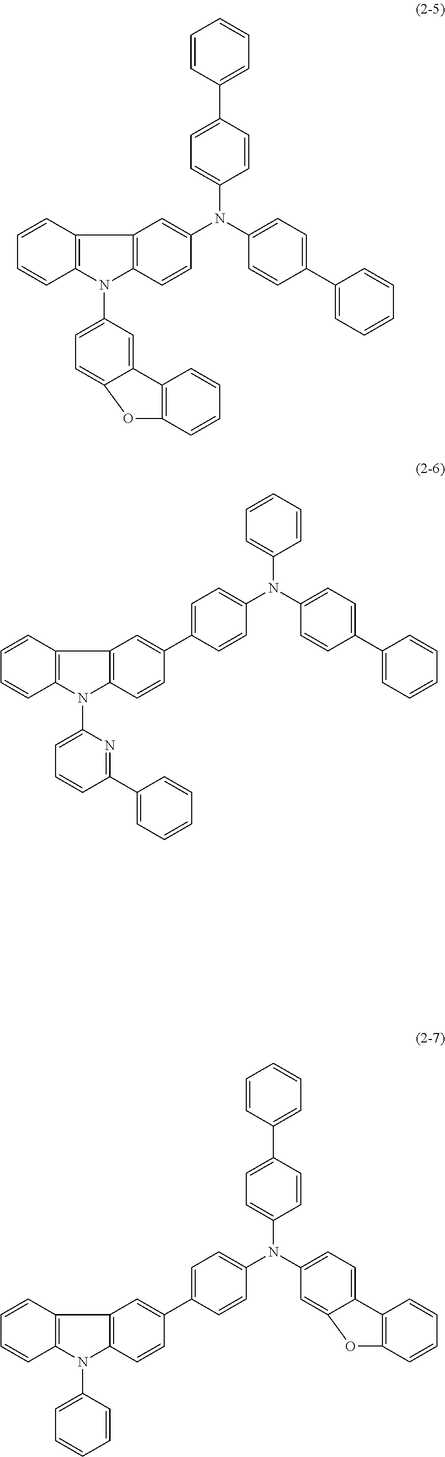 [SMILES: c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1 ; c1ccc(-c2ccc(N(c3ccc(-c4ccc5c(c4)c4ccccc4n5-c4ccccc4)cc3)c3ccc4c(c3)oc3ccccc34)cc2)cc1]

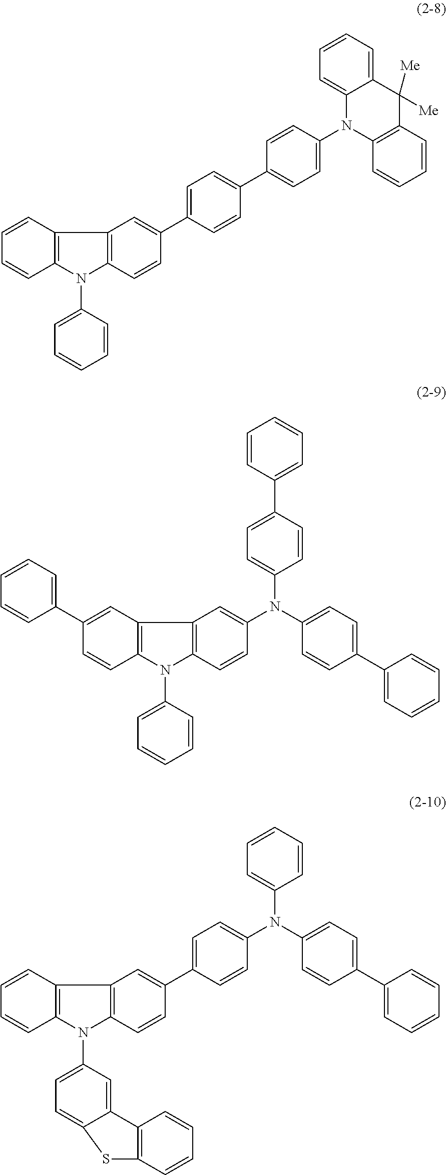 [SMILES: CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1 ; c1ccc(-c2ccc(N(c3ccccc3)c3ccc(-c4ccc5c(c4)c4ccccc4n5-c4ccc5sc6ccccc6c5c4)cc3)cc2)cc1]

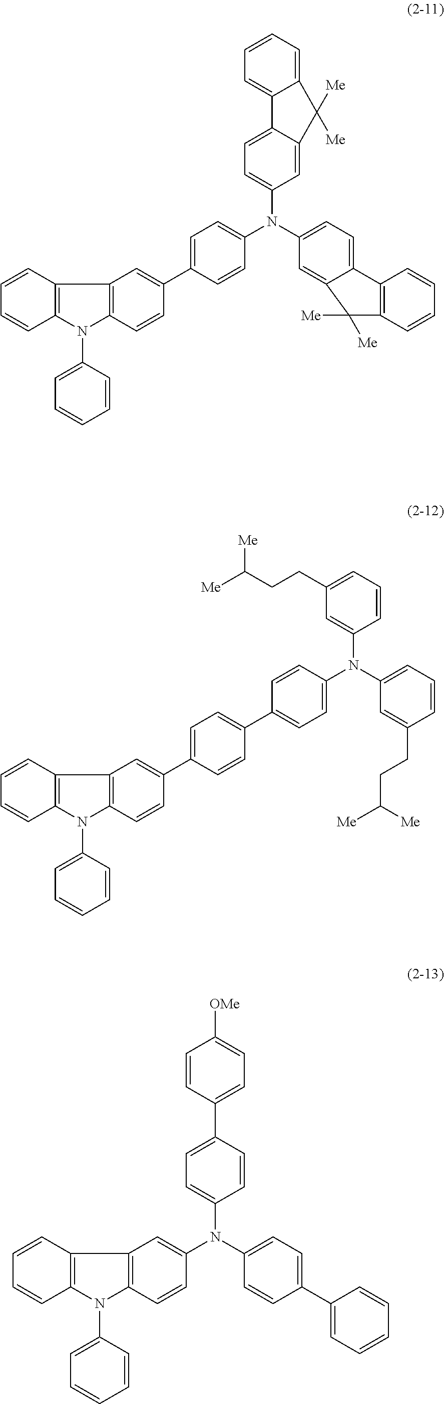 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1 ; COc1ccc(-c2ccc(N(c3ccc(-c4ccccc4)cc3)c3ccc4c(c3)c3ccccc3n4-c3ccccc3)cc2)cc1]

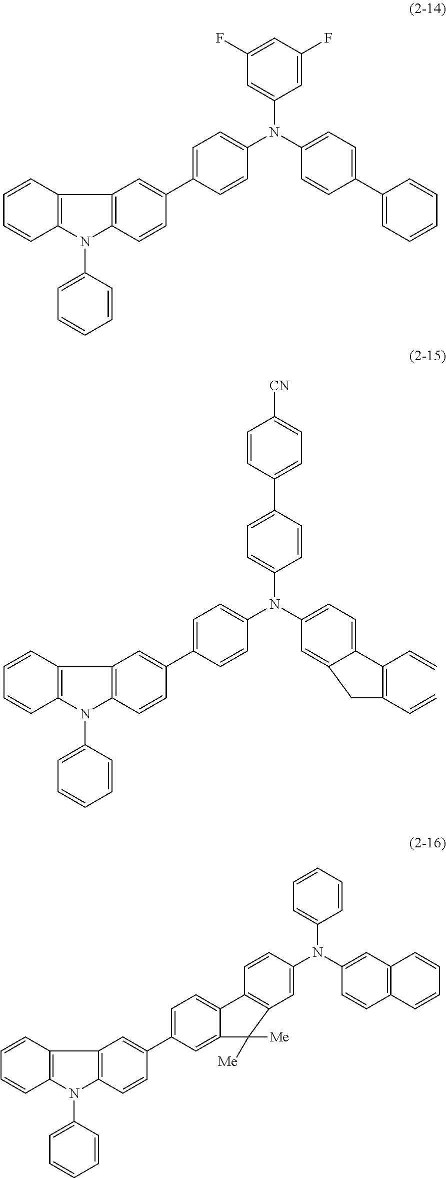 [SMILES: Fc1cc(F)cc(N(c2ccc(-c3ccccc3)cc2)c2ccc(-c3ccc4c(c3)c3ccccc3n4-c3ccccc3)cc2)c1 ; C=CC1=C(C=C)c2ccc(N(c3ccc(-c4ccc(C#N)cc4)cc3)c3ccc(-c4ccc5c(c4)c4ccccc4n5-c4ccccc4)cc3)cc2C1 ; CC1(C)c2cc(-c3ccc4c(c3)c3ccccc3n4-c3ccccc3)ccc2-c2ccc(N(c3ccccc3)c3ccc4ccccc4c3)cc21]

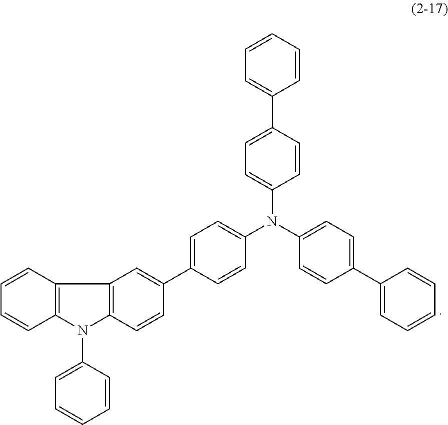 [SMILES: c1ccc(-c2ccc(N(c3ccc(-c4ccccc4)cc3)c3ccc(-c4ccc5c(c4)c4ccccc4n5-c4ccccc4)cc3)cc2)cc1]

The middle hole transport layer 133 including the compound represented by Formula 3 may improve the hole transporting property of the hole transport layer 130, and thus may improve the emission property (e.g., emission efficiency) of the organic electroluminescent device 100. For example, in embodiments where the ratio of the carbazole derivative such as the compound represented by Formula 3 in the hole transport layer 130 is great (e.g., high), the emission life of the organic electroluminescent device 100 may be further increased.

### 2-1-1-3. Configuration of Emission Layer-Side Hole Transport Layer

The emission layer-side hole transport layer 135 may include a compound represented by the following Formula 1. The emission layer-side hole transport layer 135 may be formed, for example, on the middle hole transport layer 133, adjacent to the emission layer 140.

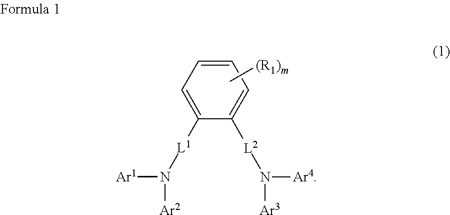

In Formula 1, Ar¹ to Ar⁴ may be each independently selected from a substituted or unsubstituted aryl group having 6 to 50 carbon atoms for forming a ring, and a substituted or unsubstituted heteroaryl group having 5 to 50 carbon atoms for forming a ring.

In addition, m may be an integer from 0 to 4, R¹ may be selected from hydrogen, deuterium, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms. A plurality of adjacent R¹ may form a ring.

Non-limiting examples of R¹, other than hydrogen and deuterium may include a phenyl group, a biphenyl group, a terphenyl group, a naphthyl group, an anthryl group, a phenanthryl group, a fluorenyl group, an indenyl group, a pyrenyl group, an acenaphthenyl group, a fluoranthenyl group, a triphenylenyl group, a pyridyl group, a pyranyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a dibenzofuranyl group, a dibenzothienyl group, etc. For example, R₁ may include the phenyl group, the biphenyl group, the terphenyl group, the fluorenyl group, the carbazolyl group, the dibenzofuranyl group, etc.

L¹ and L² may each independently be selected from a direct linkage (e.g., a bond such as a single bond), a substituted or unsubstituted arylene group having 6 to 18 carbon atoms for forming a ring, and a substituted or unsubstituted heteroarylene group having 5 to 15 carbon atoms for forming a ring.

Non-limiting examples of L¹ and L² may include a phenylene group, a biphenylene group, a terphenylene group, a naphthylene group, an anthrylene group, a phenanthrylene group, a fluorenediyl group, an indanediyl group, a pyrenediyl group, an acenaphthenediyl group, a fluoranthenediyl group, a triphenylenediyl group, a pyridinediyl group, a pyran-diyl group, a quinolinediyl group, an isoquinolinediyl group, a benzofuran-diyl group, a benzothiophenediyl group, an indolediyl group, a carbazolediyl group, a benzooxazolediyl group, a benzothiazolediyl group, a quinoxalinediyl group, a benzoimidazolediyl group, and a dibenzofuran-diyl group. In some embodiments, L¹ and L² may each independently include a substituent other than the anthrylene group, for example, L¹ and L² may each independently include the phenylene group, the terphenylene group, the fluorenediyl group, the carbazolediyl group, etc.

In Formula 1, Ar¹ to Ar⁴ may each independently include a compound represented by one of the following Formulae (1a)-(1c) collectively denoted as Formula 2.

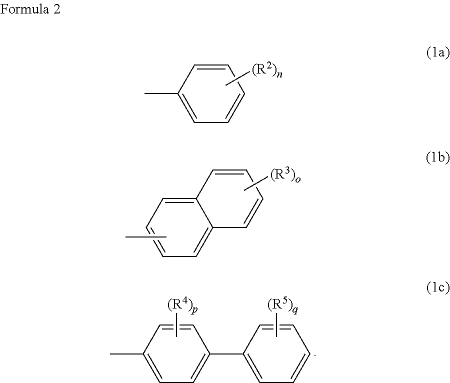

In Formulae (1a)-(1c) in Formula 2, p may be an integer from 0 to 4, n and q may each independently be an integer from 0 to 5, and o may be an integer from 0 to 7. R², R³, R⁴ and R⁵ may be each independently selected from hydrogen, deuterium, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms. R², R³, R⁴ and R⁵ may each independently form a ring between adjacent groups among R², R³, R⁴ and R⁵, respectively. Non-limiting examples of R², R³, R⁴ and R⁵ may be the same as those described herein in connection with R₁.

Non-limiting examples of the compound represented by Formula 1 may include the following Compounds 1 to 49 collectively denoted as Formula 9. However, the compound represented by Formula 1 is not limited to Compounds 1 to 49.

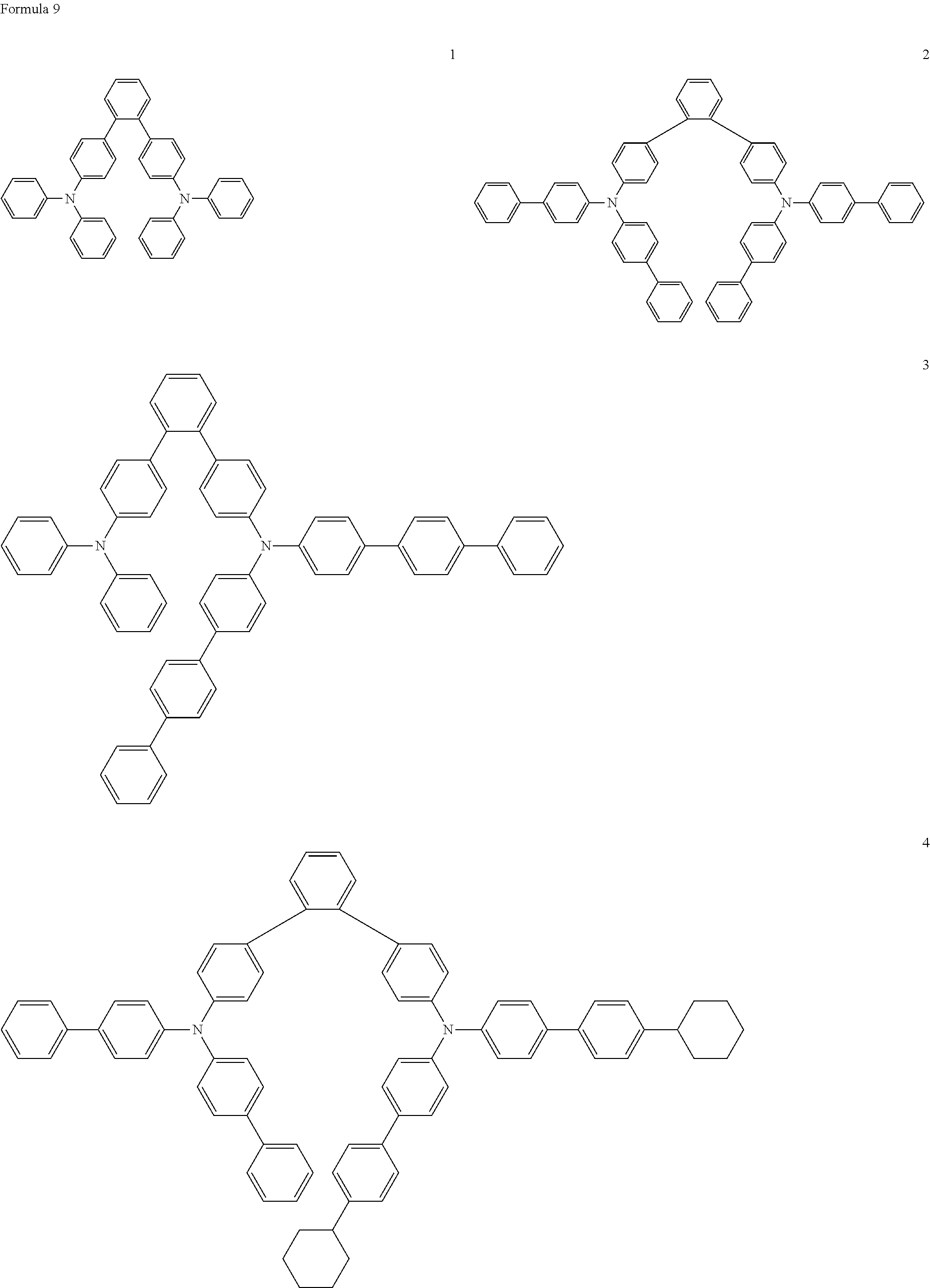 [SMILES: c1ccc(N(c2ccccc2)c2ccc(-c3ccccc3-c3ccc(N(c4ccccc4)c4ccccc4)cc3)cc2)cc1 ; c1ccc(-c2ccc(N(c3ccc(-c4ccccc4)cc3)c3ccc(-c4ccccc4-c4ccc(N(c5ccc(-c6ccccc6)cc5)c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccccc5-c5ccc(N(c6ccccc6)c6ccccc6)cc5)cc4)cc3)cc2)cc1 ; c1ccc(-c2ccc(N(c3ccc(-c4ccccc4)cc3)c3ccc(-c4ccccc4-c4ccc(N(c5ccc(-c6ccc(C7CCCCC7)cc6)cc5)c5ccc(-c6ccc(C7CCCCC7)cc6)cc5)cc4)cc3)cc2)cc1]

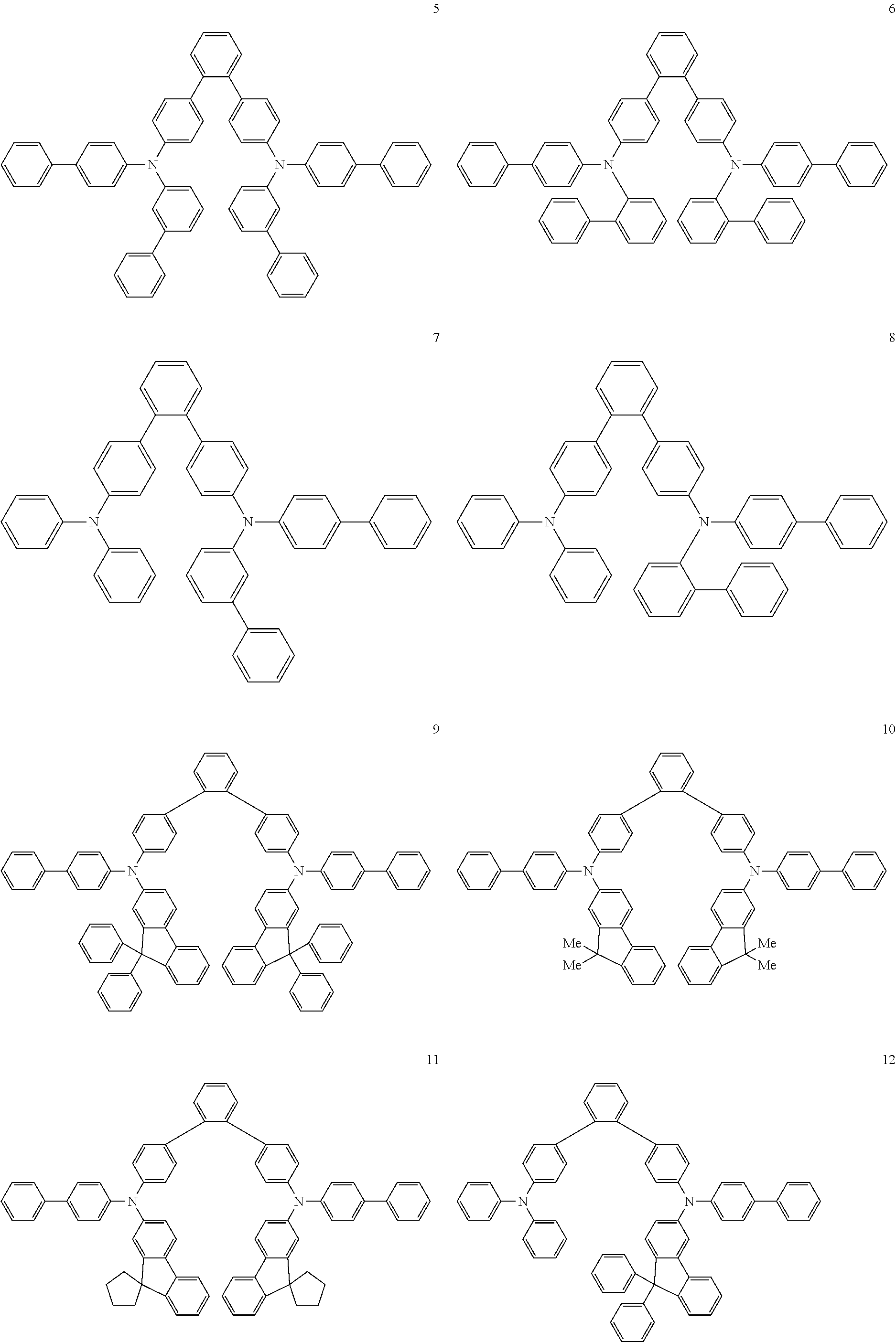

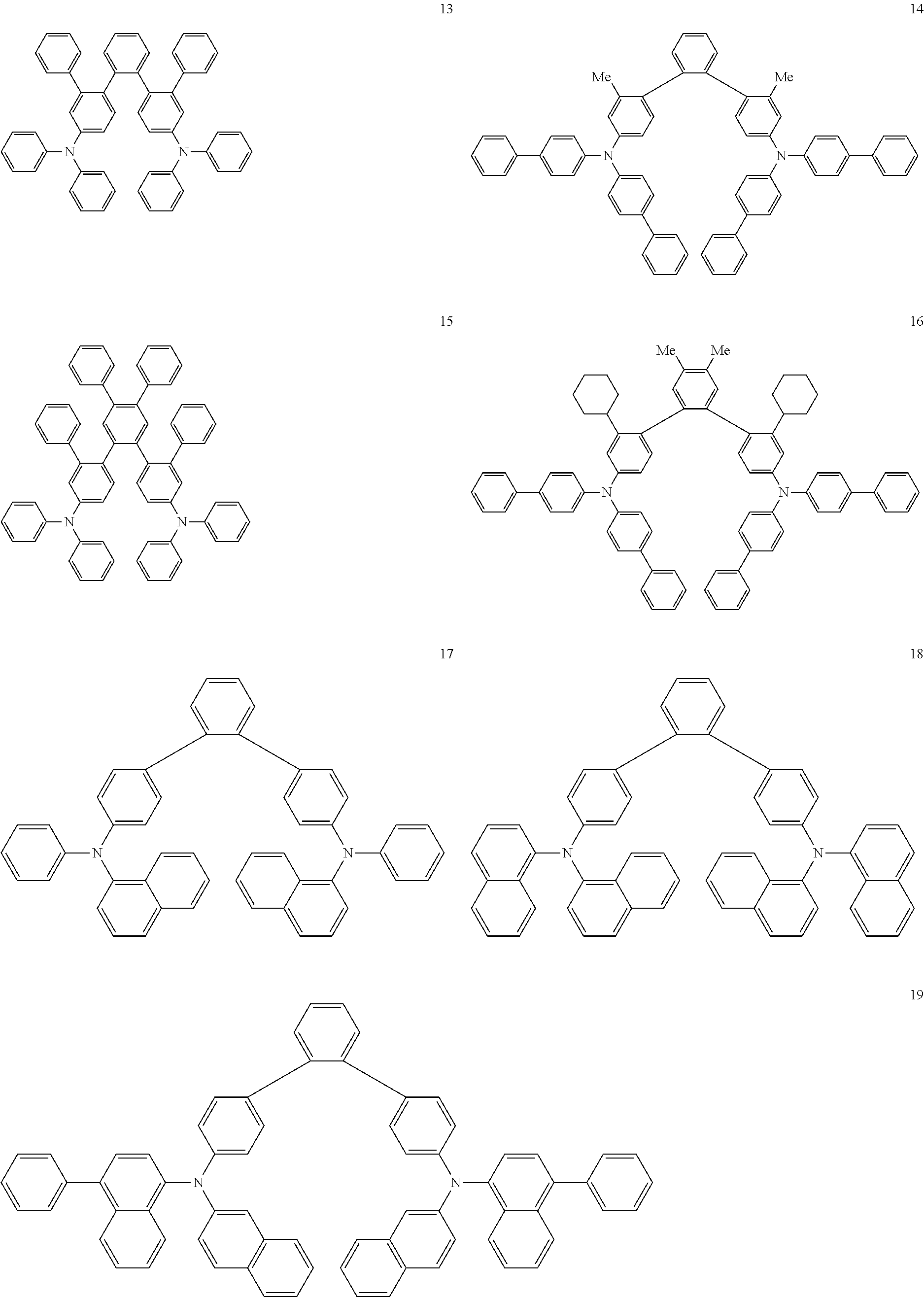

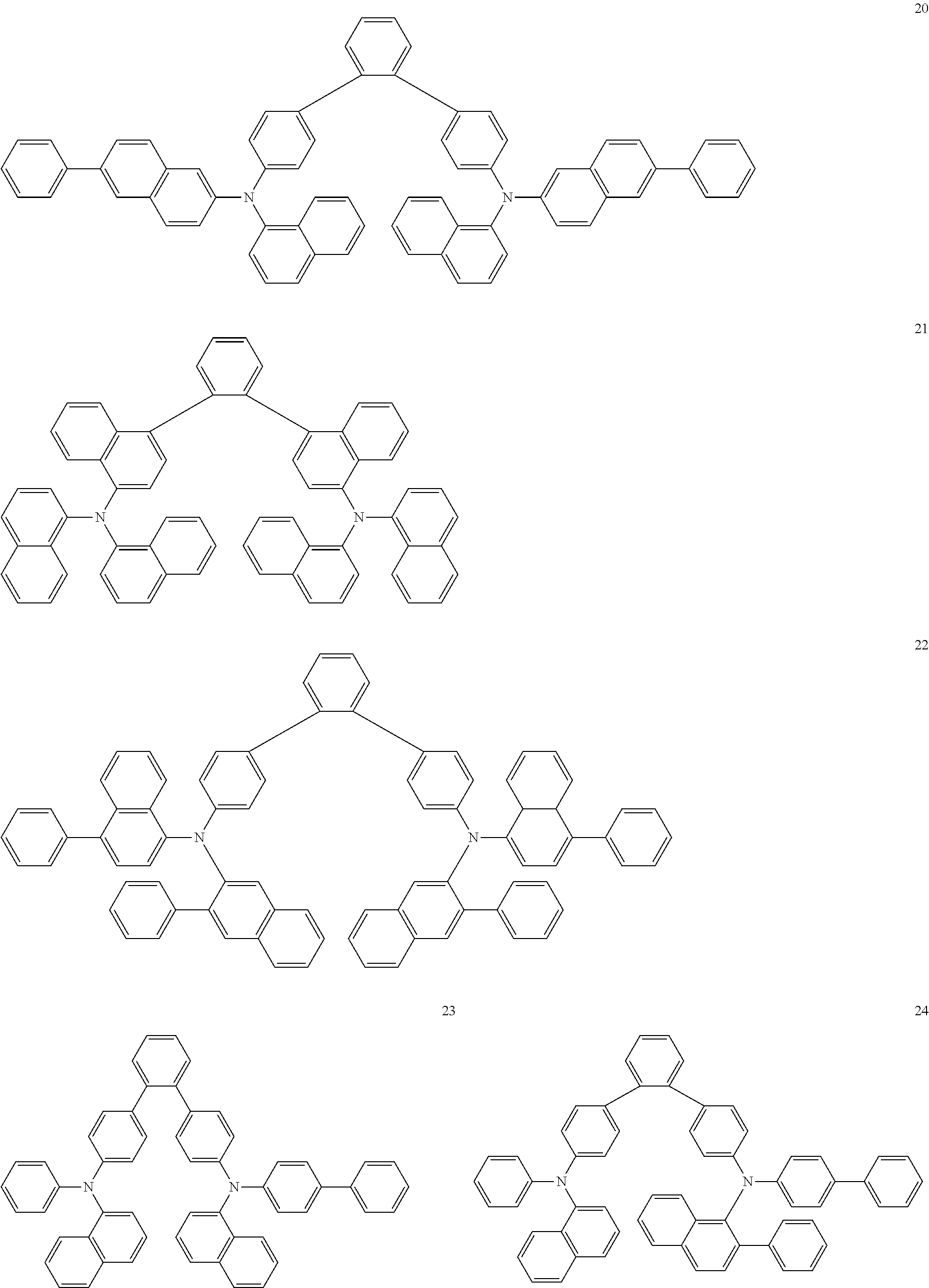

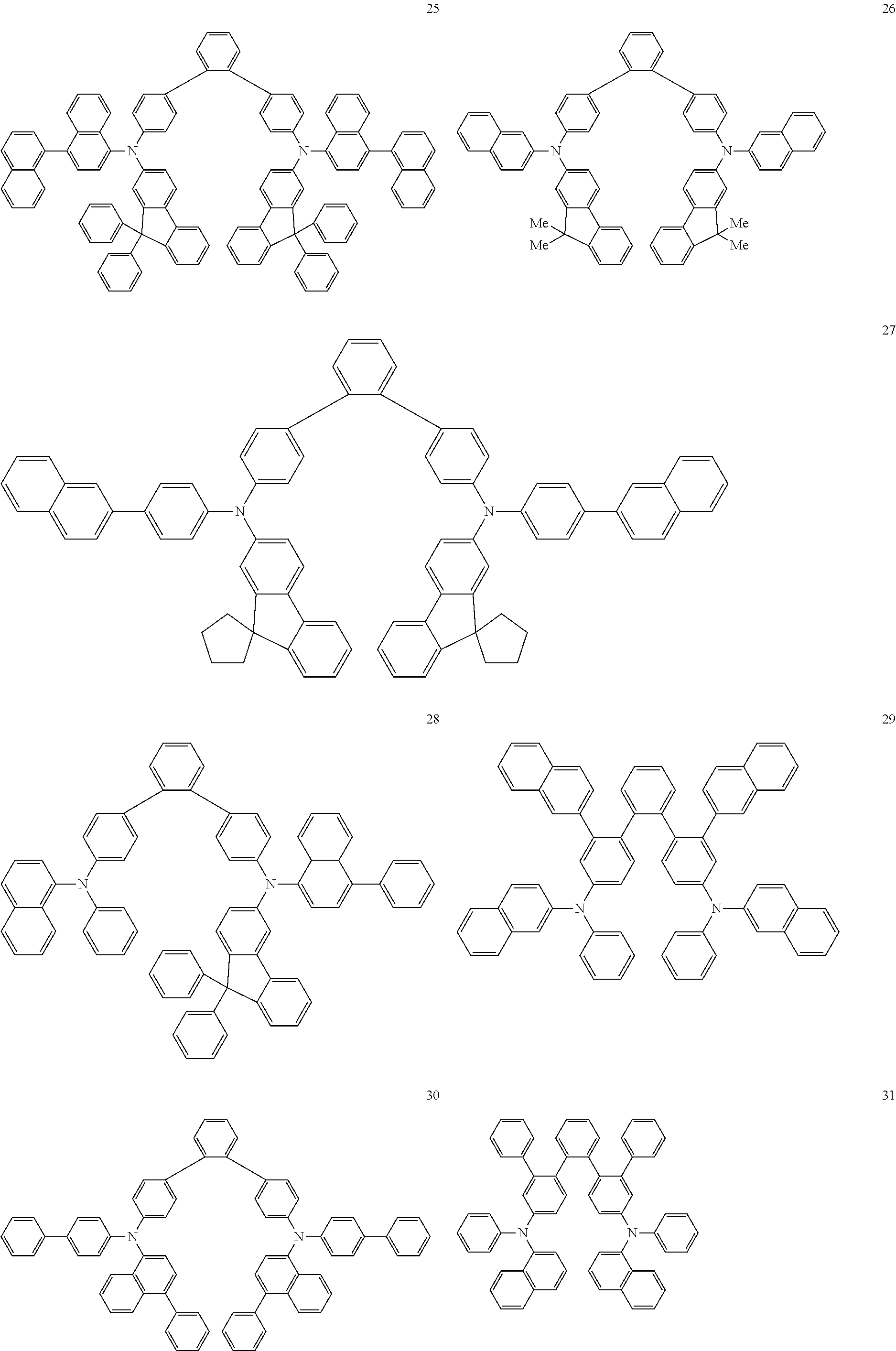

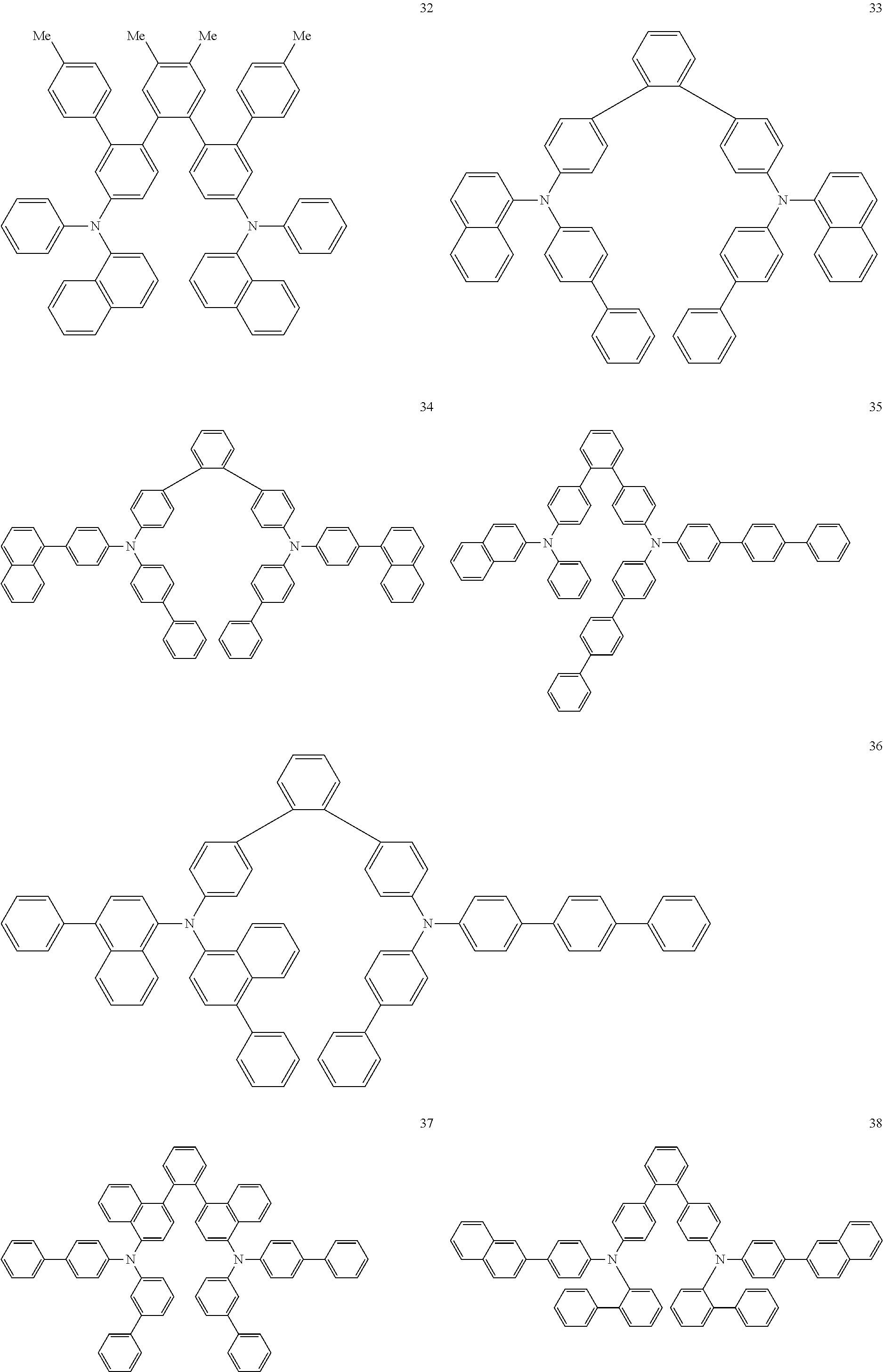

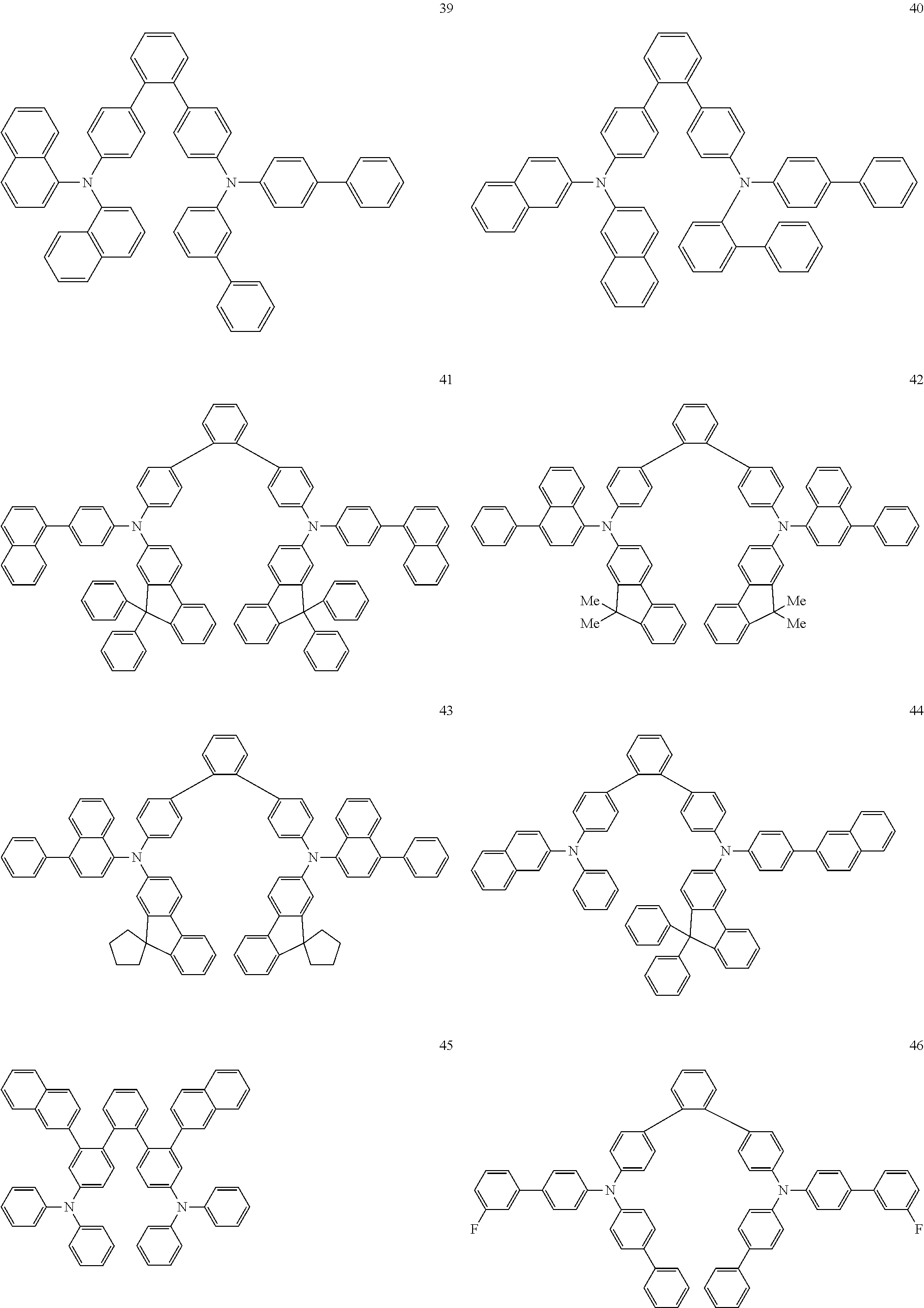

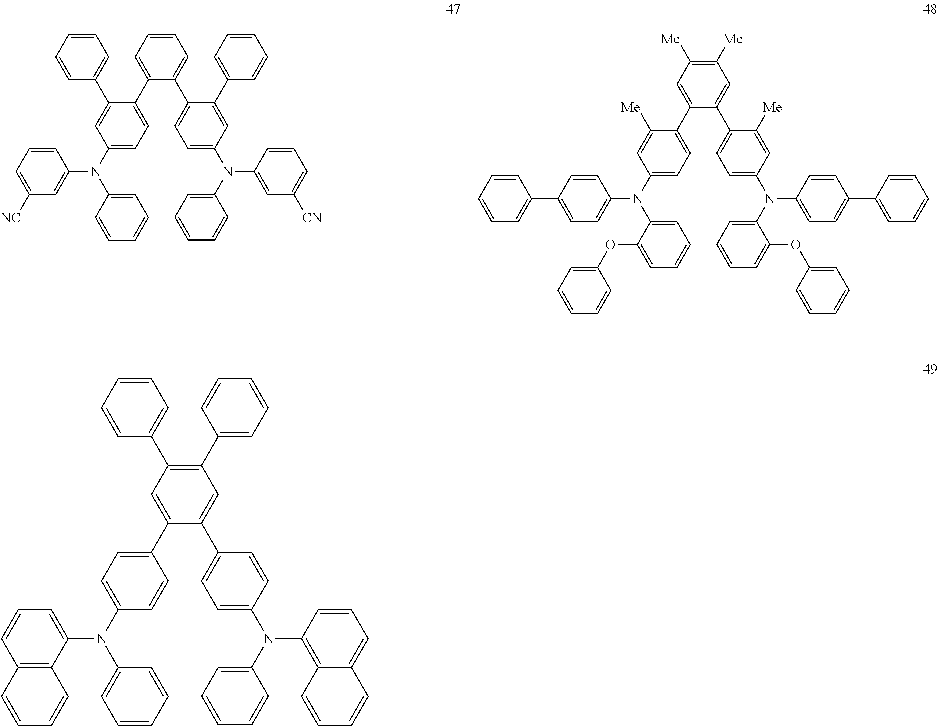 [SMILES: N#Cc1cccc(N(c2ccccc2)c2ccc(-c3ccccc3-c3ccc(N(c4ccccc4)c4cccc(C#N)c4)cc3-c3ccccc3)c(-c3ccccc3)c2)c1 ; Cc1cc(-c2ccc(N(c3ccc(-c4ccccc4)cc3)c3ccccc3Oc3ccccc3)cc2C)c(-c2ccc(N(c3ccc(-c4ccccc4)cc3)c3ccccc3Oc3ccccc3)cc2C)cc1C ; c1ccc(-c2cc(-c3ccc(N(c4ccccc4)c4cccc5ccccc45)cc3)c(-c3ccc(N(c4ccccc4)c4cccc5ccccc45)cc3)cc2-c2ccccc2)cc1]

The emission layer-side hole transport layer 135 may include the compound represented by the above Formula 1 as the emission layer-side hole transport material and may protect the hole transport layer 130 from the diffusion of electrons not consumed in the emission layer 140. In addition, since the emission layer-side hole transport layer 135 includes the compound represented by Formula 1, the diffusion of the energy in an excited state (e.g., the diffusion of excitons) generated in the emission layer 140 to the hole transport layer 130 may be prevented or reduced. Thus, the emission layer-side hole transport layer 135 according to embodiments of the present disclosure, may improve the current flow durability of the hole transport layer 130.

The emission layer-side hole transport layer 135 may be formed around (or near) the emission layer 140, for example, may be formed adjacent to the emission layer 140, to effectively (or suitably) prevent or reduce the diffusion of electrons or energy (e.g., excitons) from the emission layer 140.

In addition, since the emission layer-side hole transport layer 135 includes the compound represented by Formula 1, the charge balance of the whole organic electroluminescent device 100 may be controlled, and the diffusion of the electron accepting material included in the anode-side hole transport layer 131 into the emission layer 140 may be restrained or reduced. Accordingly, the emission layer-side hole transport layer 135 may improve the charge transport property of the hole transport layer 130.

When the emission layer-side hole transport layer 135 includes the compound represented by Formula 1, the charge transport property and current flow durability of the hole transport layer 130 may be improved, and the emission efficiency and emission life of the organic electroluminescent device 100 may be improved.

As described above, the hole transport layer 130 including the anode-side hole transport layer 131, the middle hole transport layer 133, and the emission layer-side hole transport layer 135 may improve the current flow durability and hole transport property of the organic electroluminescent device 100. Therefore, the organic electroluminescent device 100 according to embodiments of the present disclosure may have improved emission efficiency and emission life.

### 2-2. Examples

Hereinafter, the organic electroluminescent devices according to example embodiments will be explained in more detail with reference to examples and comparative examples. However, the following examples are provided only for illustration, and the organic electroluminescent device according to example embodiments of the present disclosure is not limited thereto.

### 2-2-1. Synthesis of Compounds

### Synthetic Example 1

### Synthesis of Compound 17

Compound 17 was synthesized by the following synthetic scheme.

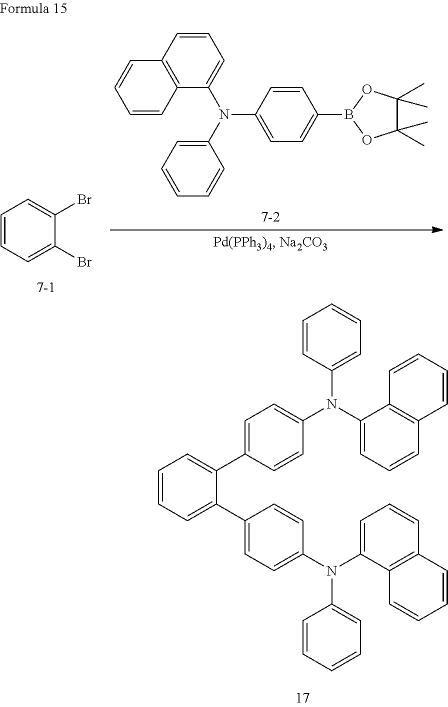 [SMILES: CC1(C)OB(c2ccc(N(c3ccccc3)c3cccc4ccccc34)cc2)OC1(C)C ; Brc1ccccc1Br ; c1ccc(N(c2ccc(-c3ccccc3-c3ccc(N(c4ccccc4)c4cccc5ccccc45)cc3)cc2)c2cccc3ccccc23)cc1]

To a mixture of 1.82 g (7.71 mmol) of Compound 7-1 (dibromobenzene), 6.83 g (16.2 mmol) of Compound 7-2 (boronic acid), 200 mL of toluene, 20 mL of ethanol and 20 ml of 2M-sodium carbonate aqueous solution, 891 mg (0.771 mmol) of tetrakistriphenylphosphine palladium (0) was added under an argon atmosphere, followed by refluxing the resultant for about 8 hours. The reaction product was cooled to room temperature, water was added to the reaction product, and extraction with toluene was conducted three times. A resulting organic layer was washed with a saturated saline solution, dried with anhydrous magnesium sulfate and concentrated.

The obtained residual product was separated using column chromatography to produce 3.33 g (Yield 65%) of Compound 17 as a pale yellow solid. The molecular weight of Compound 17 thus obtained was measured by FAB-MS, and the molecular weight of Compound 17 (C₅₀H₃₆N₂) was 664. In addition, chemical shift values (δ) of Compound 17 measured by ¹H NMR (300 MHz, CDCl₃) were 7.05-7.18 (12H), 7.20-7.55 (18H), 7.75 (d, J=7 Hz, 2H), 7.88 (d, J=7 Hz, 2H), 7.95 (d, J=7 Hz, 2H). The resulting product was confirmed to be Compound 17.

### Synthetic Example 2

### Synthesis of Compound 33

Compound 33 was synthesized by the following synthetic scheme.

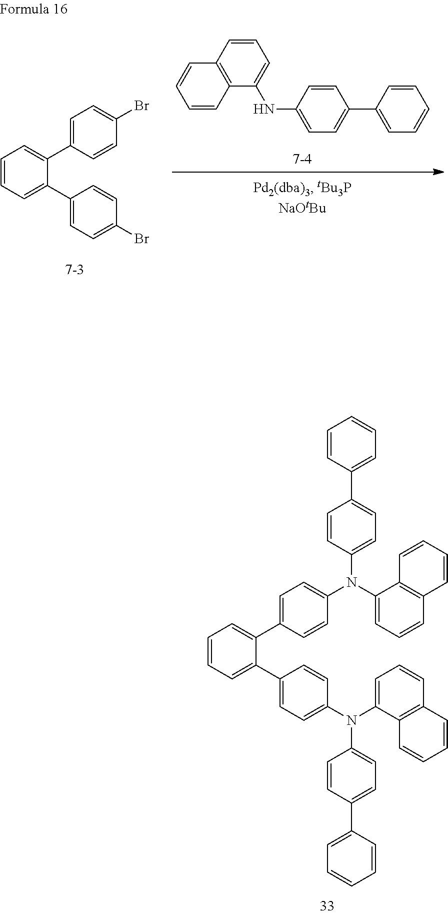 [SMILES: Brc1ccc(-c2ccccc2-c2ccc(Br)cc2)cc1 ; c1ccc(-c2ccc(Nc3cccc4ccccc34)cc2)cc1 ; c1ccc(-c2ccc(N(c3ccc(-c4ccccc4-c4ccc(N(c5ccc(-c6ccccc6)cc5)c5cccc6ccccc56)cc4)cc3)c3cccc4ccccc34)cc2)cc1]

To a mixture of 2.08 g (5.37 mmol) of Compound 7-3 (a dibromo compound), 3.25 g (11.0 mmol) of Compound 7-4 (an amine compound), 278 mg (0.268 mmol) of a tris(dibenzylideneacetone)dipalladium(0)chloroform addition product, 1.58 g (16.1 mmol) of sodium-t-butoxide and 200 mL of an anhydrous xylene solution, 0.201 mL of tri-t-butylphosphine and 0.322 mmol of 1.6 M xylene solution were added under an argon atmosphere, followed by stirring the resultant at about 120° C. for about 12 hours. The reaction product was cooled to room temperature, water was added to the reaction product, and extraction with toluene was conducted three times. A resulting organic layer was washed with a saturated saline solution, dried with anhydrous magnesium sulfate and concentrated. The obtained residual product was separated using column chromatography to produce 2.50 g (Yield 57%) of Compound 33 (a diamine compound) as a pale yellow solid. The molecular weight of Compound 33 thus obtained was measured by FAB-MS, and the molecular weight of Compound 33 (C₆₂H₄₄N₂) was 816. In addition, chemical shift values (δ) of Compound 33 measured by ¹H NMR (300 MHz, CDCl₃) were 7.02-7.20 (10H), 7.20-7.57 (28H), 7.78 (d, J=7 Hz, 2H), 7.90 (d, J=7 Hz, 2H), 7.96 (d, J=7 Hz, 2H). The resulting product was confirmed to be Compound 33.

### Synthetic Example 3

### Synthesis of Compound 49

Compound 49 was synthesized according to the following synthetic scheme.

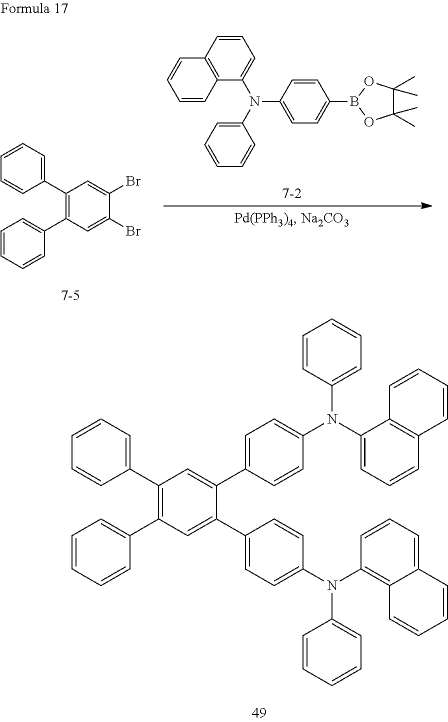 [SMILES: Brc1cc(-c2ccccc2)c(-c2ccccc2)cc1Br ; CC1(C)OB(c2ccc(N(c3ccccc3)c3cccc4ccccc34)cc2)OC1(C)C ; c1ccc(-c2cc(-c3ccc(N(c4ccccc4)c4cccc5ccccc45)cc3)c(-c3ccc(N(c4ccccc4)c4cccc5ccccc45)cc3)cc2-c2ccccc2)cc1]

To a mixture of 2.01 g (5.18 mmol) of Compound 7-5 (a dibromo compound), 4.58 g (10.9 mmol) of Compound 7-2 (boronic acid), 300 mL of toluene, 20 mL of ethanol and 20 ml of 2M-sodium carbonate aqueous solution, 599 mg (0.518 mmol) of tetrakistriphenylphosphine palladium (0) was added under an argon atmosphere, followed by refluxing for about 13 hours. The reaction product was cooled to room temperature, water was added to the reaction product, and extraction with toluene was conducted three times. A resulting organic layer was washed with a saturated saline solution, dried with anhydrous magnesium sulfate and concentrated. The obtained residual product was separated using column chromatography to produce 2.67 g (Yield 63%) of Compound 49 (a diamine compound) as a pale yellow solid. The molecular weight of Compound 49 thus obtained was measured by FAB-MS, and the molecular weight of Compound 49 (C₆₂H₄₄N₂) was 816. In addition, chemical shift values (δ) of Compound 49 measured by ¹H NMR (300 MHz, CDCl₃) were 6.98-7.22 (12H), 7.22-7.65 (26H), 7.80 (d, J=7 Hz, 2H), 7.92 (d, J=7 Hz, 2H), 7.98 (d, J=7 Hz, 2H). The resulting product was confirmed to be Compound 49.

### 2-2-2. Manufacture of Organic Electroluminescent Device Including Anode-Side Hole Transport Layer Including Mainly Electron Accepting Material

An organic electroluminescent device according to an embodiment was manufactured by the following manufacturing method.

First, an ITO-glass substrate that was patterned and washed in advance, was subjected to surface treatment using UV-Ozone (O₃) was conducted. The layer thickness of the ITO layer (herein, a first electrode) on a glass substrate was about 150 nm. After ozone treatment, the substrate was washed and inserted in a glass bell jar type evaporator (e.g., a glass bell jar evaporator) for forming an organic layer, and an anode-side hole transport layer, a middle hole transport layer, an emission layer-side hole transport layer, an emission layer and an electron transport layer were evaporated one by one under a vacuum degree of about 10⁻⁴ to about 10⁻⁵ Pa. The layer thickness of each of the anode-side hole transport layer, the middle hole transport layer, and the emission layer-side hole transport layer was about 10 nm. The layer thickness of the emission layer was about 25 nm, and the layer thickness of the electron transport layer was about 25 nm. Then, the substrate was moved into a glass bell jar type evaporator (e.g., a glass bell jar evaporator) for forming a metal layer, and the electron injection layer and the second electrode were evaporated under a vacuum degree of about 10⁻⁴ to about 10⁻⁵ Pa. The layer thickness of the electron injection layer was about 1 nm and the layer thickness of the second electrode was about 100 nm.

Here, the anode-side hole transport layer, the middle hole transport layer and the emission layer-side hole transport layer collectively form the hole transport layer having a laminated structure. The anode-side hole transport layer, the middle hole transport layer, and the emission layer-side hole transport layer of Examples 2-1 to 2-6 and Comparative Examples 2-1 to 2-4 were manufactured using the materials as shown in the following Table 3.

In Table 3, Compounds 6-1 and 6-2 correspond to the common hole transport materials represented by the following formulae and collectively denoted as Formula 18:

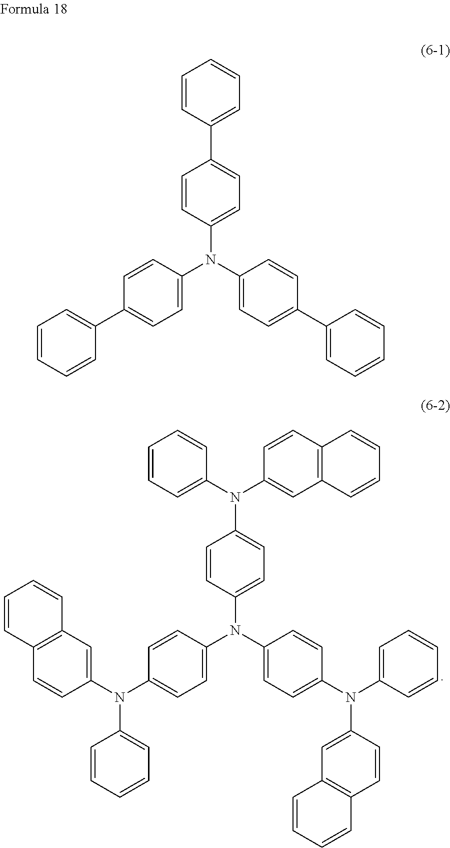 [SMILES: c1ccc(-c2ccc(N(c3ccc(-c4ccccc4)cc3)c3ccc(-c4ccccc4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

ADN (Compound 3-2) was used as the host material of the emission layer, and TBP was used as a dopant material. The dopant material was added in an amount (e.g., weight ratio) of about 3 wt % on the basis of the amount of the host material. An electron transport layer was formed using Alq3, an electron injection layer was formed using LiF, and a second electrode was formed using aluminum (Al).

### 2-3. Evaluation Results

The driving voltage, the emission efficiency, and the half life of each organic electroluminescent device manufactured according to the above-described method were evaluated. The evaluation results are shown in the following Table 3. The driving voltage and the emission efficiency in each Example and Comparative Example were obtained by measuring with current density of about 10 mA/cm². In addition, the half life was obtained by measuring luminance based on the initial luminance of about 1,000 cd/m².

The measurements were conducted using a source meter of 2400 series produced by Keithley Instruments Co., Color brightness photometer CS-200 (Konica Minolta, measurement angle of 1°), and a PC program LabVIEW8.2 (National instruments, Japan) for measurement in a dark room.

TABLE 3

| Device | | | Emission |
|---|---|---|---|
| manufacturing | Anode-side hole | Middle hole | layer-side hole |
| examples | transport layer | transport layer | transport layer |
| Example 2-1 | Compound 4-15 | Compound 2-3 | Compound 33 |
| Example 2-2 | Compound 4-15 | Compound 2-3 | Compound 49 |
| Example 2-3 | Compound 4-15 | Compound 2-17 | Compound 33 |
| Example 2-4 | Compound 4-15 | Compound 2-3 | Compound 33 |
| Example 2-5 | Compound 4-15 | Compound 6-2 | Compound 33 |
| Example 2-6 | Compound 4-15 | Compound 2-3 | Compound 17 |
| Comparative | Compound 4-15 | Compound 33 | Compound 2-3 |
| Example 2-1 | | | |
| Comparative | Compound 2-3 | Compound 4-15 | Compound 33 |
| Example 2-2 | | | |
| Comparative | Compound 33 | Compound 4-15 | Compound 33 |
| Example 2-3 | | | |
| Comparative | Compound 4-15 | Compound 2-3 | Compound 6-1 |
| Example 2-4 | | | |

TABLE 4

| Device | Current | | Emission | Half life |
|---|---|---|---|---|
| manufacturing | density | Voltage | efficiency | LT₅₀ |
| examples | (mA/cm²) | (V) | (cd/A) | (h) |
| Example 2-1 | 10 | 6.3 | 7.7 | 3,500 |
| Example 2-2 | 10 | 6.4 | 7.7 | 3,500 |
| Example 2-3 | 10 | 6.4 | 7.6 | 3,400 |
| Example 2-4 | 10 | 6.5 | 7.4 | 3,100 |
| Example 2-5 | 10 | 6.4 | 7.6 | 3,400 |
| Example 2-6 | 10 | 6.3 | 7.7 | 3,400 |
| Comparative | 10 | 6.7 | 6.3 | 1,400 |
| Example 2-1 | | | | |
| Comparative | 10 | 6.6 | 6.5 | 2,500 |
| Example 2-2 | | | | |
| Comparative | 10 | 6.7 | 6.5 | 2,400 |
| Example 2-3 | | | | |
| Comparative | 10 | 6.5 | 7.3 | 2,400 |
| Example 2-4 | | | | |

Referring to the results in Table 3, the organic electroluminescent devices according to Examples 2-1 to 2-3 exhibited increased emission efficiency and half life, when compared to those according to Comparative Examples 2-1 to 2-4. Without being bound by any particular theory, it is believed that the emission efficiency and emission life of the organic electroluminescent devices according to the Examples were improved at least in part due to providing the anode-side hole transport layer, the middle hole transport layer, and the emission layer-side hole transport layer between the first electrode and the emission layer, according to embodiments of the present disclosure. In addition, the driving voltage of the organic electroluminescent devices of Examples 2-1 to 2-6 was either the same as or lower than that of the organic electroluminescent devices of Comparative Examples 2-1 to 2-4.

For example, when comparing the organic electroluminescent device of Example 2-1 with that of Comparative Example 2-4, the properties of Example 2-1 were improved. In Comparative Example 2-4, Compound 6-1 was used as the emission layer-side hole transport material included in the emission layer-side hole transport layer instead of the compound represented by Formula 1. Therefore, in one embodiment, the inclusion of the compound represented by Formula 1 in the emission layer-side hole transport layer is preferable.

When comparing Example 2-1 with Comparative Example 2-1, the properties of Example 2-1 were improved. In Comparative Example 2-1, the compounds included in the middle hole transport layer and the emission layer-side hole transport layer were switched, as compared to Example 2-1. Therefore, in one embodiment, it is preferable to position the emission layer-side hole transport layer including the compound represented by Formula 1 adjacent to the emission layer.

When comparing Example 2-1 with Comparative Example 2-3, the properties of Example 2-1 were improved. In Comparative Example 2-3, a layer including an electron accepting material (Compound 4-15) is inserted into a layer including Compound 33 represented by Formula 1 and is provided at a position corresponding to a middle hole transport layer. Therefore, in one embodiment, it is preferable to position the anode-side hole transport layer including the electron accepting material adjacent to the first electrode (e.g., anode).

In Examples 2-2 to 2-4 and 2-6, one of the middle hole transport material and the emission layer-side hole transport material was changed, as compared to Example 2-1, to a different material according to embodiments of the inventive concept.

The organic electroluminescent devices of Examples 2-2 to 2-4 and 2-7 exhibited similarly improved characteristics, when compared to those of the Comparative Examples, as did the organic electroluminescent device of Example 2-1.

When comparing Example 2-1 with Example 2-5, the properties of Example 2-1 were improved. In Example 2-5, Compound 6-2 was used as the middle hole transport material included in the middle hole transport layer instead of Compound 2-3 represented by Formula 3. Therefore, in one embodiment, it is preferable that the compound represented by Formula 3 be included in the middle hole transport layer.

As described above, according to example embodiments, when the anode-side hole transport layer including the electron accepting material, the middle hole transport layer, and the emission layer-side hole transport layer including the compound represented by Formula 1 are laminated between the first electrode (e.g., anode) and the emission layer, the emission life of the organic electroluminescent device may be increased.

It is believed that the emission layer-side hole transport layer including the compound represented by Formula 1 is capable of protecting the hole transport layer from the diffusion of electrons not consumed in the emission layer and thus may prevent or reduce the diffusion of excited state energy (e.g. excitons) generated in the emission layer into the hole transport layer, thereby controlling the charge balance of the whole organic electroluminescent device. In addition, it is believed that the emission layer-side hole transport layer including the compound represented by Formula 1 may also restrain or reduce the diffusion of the electron accepting material included in the anode-side hole transport layer provided around (or near) the first electrode (e.g., anode) into the emission layer.

As described above, according to one or more embodiments of the present inventive concept, an anode-side hole transport layer, a middle hole transport layer, and an emission layer-side hole transport layer may be positioned between an anode and an emission layer of an organic electroluminescent device, and the emission efficiency and emission life of the organic electroluminescent device may be improved.

Expressions such as “at least one of,” “one of,” “at least one selected from,” and “one selected from,” when preceding a list of elements, modify the entire list of elements and do not modify the individual elements of the list. Further, the use of “may” when describing embodiments of the present invention refers to “one or more embodiments of the present invention.”

In addition, as used herein, the terms “use,” “using,” and “used” may be considered synonymous with the terms “utilize,” “utilizing,” and “utilized,” respectively.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112(a) and 35 U.S.C. §132(a).

The above-disclosed subject matter is to be considered illustrative and not restrictive, and the appended claims and equivalents thereof are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. An organic electroluminescent device, comprising:
an anode;
an emission layer;
an anode-side hole transport layer between the anode and the emission layer, the anode-side hole transport layer comprising an anode-side hole transport material doped with an electron accepting material;
a middle hole transport layer between the anode-side hole transport layer and the emission layer, the middle hole transport layer comprising a middle hole transport material; and
an emission layer-side hole transport layer between the middle hole transport layer and the emission layer, the emission layer-side hole transport layer being adjacent to the emission layer,
wherein the emission layer-side hole transport layer comprises an emission layer-side hole transport material represented by the following Formula 1: 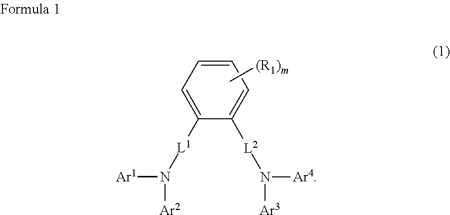
wherein, in Formula 1, Ar¹, Ar², Ar³ and Ar⁴ are each independently selected from a substituted or unsubstituted aryl group having 6 to 50 carbon atoms for forming a ring and a substituted or unsubstituted heteroaryl group having 5 to 50 carbon atoms for forming a ring,
m is an integer selected from 0 to 4,
R¹ is selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R¹(s), and
L¹ and L² are each independently selected from a direct linkage, a substituted or unsubstituted arylene group having 6 to 18 carbon atoms for forming a ring, and a substituted or unsubstituted heteroarylene group having 5 to 15 carbon atoms for forming a ring.

2. The organic electroluminescent device of claim 1, wherein Ar¹, Ar², Ar³ and Ar⁴ in Formula 1 are each independently a compound represented by one of the following Formulae (1a)-(1c) collectively denoted as Formula 2: 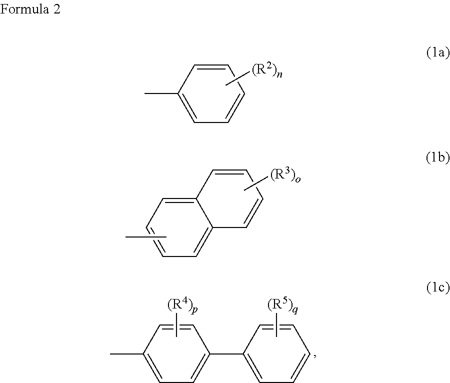
wherein, in Formulae (1a)-(1c), p is an integer selected from 0 to 4, n and q are each independently an integer selected from 0 to 5, o is an integer selected from 0 to 7, and
R², R³, R⁴ and R⁵ are each independently selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R²(s), R³(s), R⁴(s), and R⁵(s), respectively.

3. The organic electroluminescent device of claim 1, wherein the emission layer-side hole transport material comprises at least one compound selected from Compounds 1 to 49 collectively denoted as Formula 9:

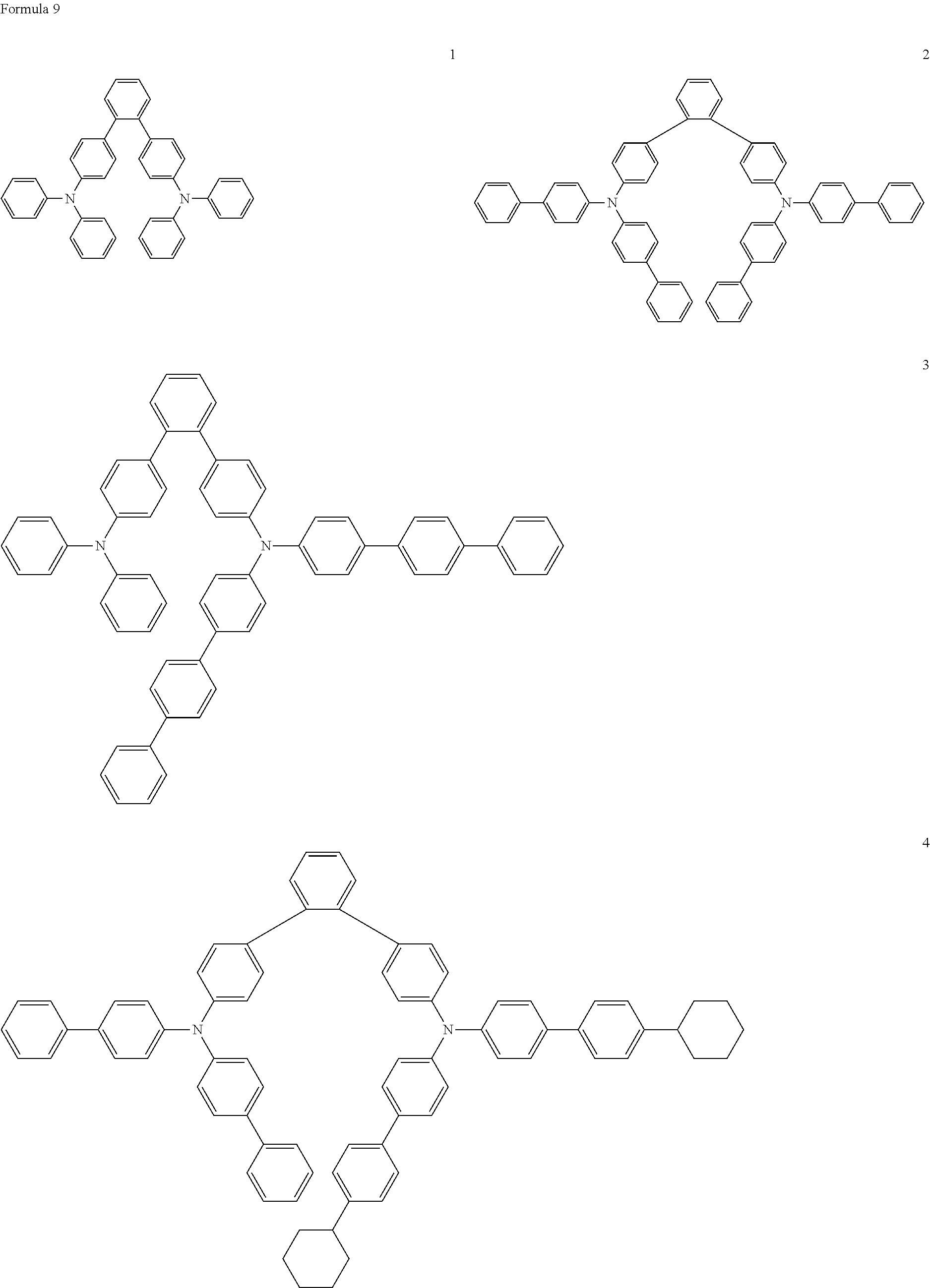 [SMILES: c1ccc(N(c2ccccc2)c2ccc(-c3ccccc3-c3ccc(N(c4ccccc4)c4ccccc4)cc3)cc2)cc1 ; c1ccc(-c2ccc(N(c3ccc(-c4ccccc4)cc3)c3ccc(-c4ccccc4-c4ccc(N(c5ccc(-c6ccccc6)cc5)c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccccc5-c5ccc(N(c6ccccc6)c6ccccc6)cc5)cc4)cc3)cc2)cc1 ; c1ccc(-c2ccc(N(c3ccc(-c4ccccc4)cc3)c3ccc(-c4ccccc4-c4ccc(N(c5ccc(-c6ccc(C7CCCCC7)cc6)cc5)c5ccc(-c6ccc(C7CCCCC7)cc6)cc5)cc4)cc3)cc2)cc1]

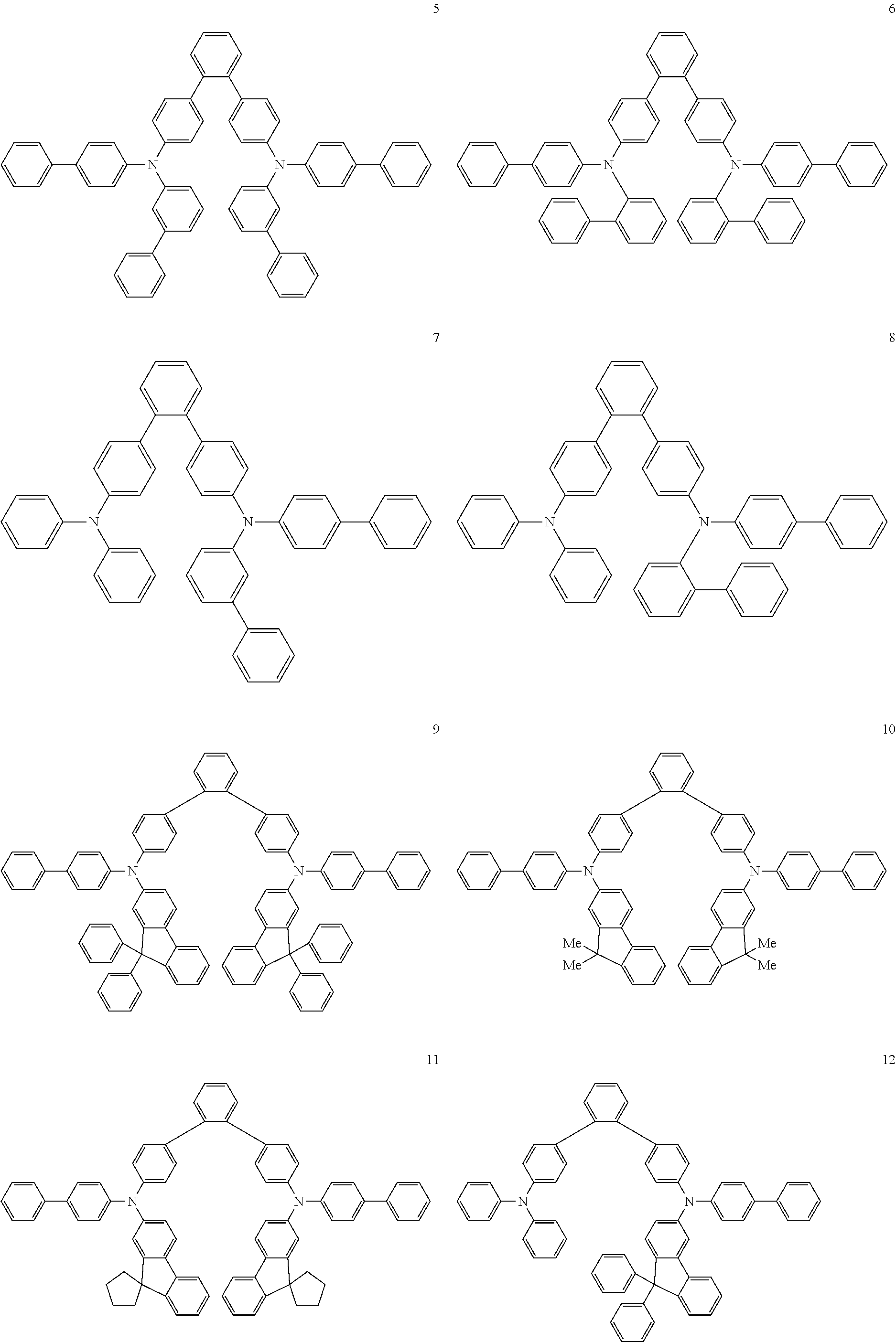

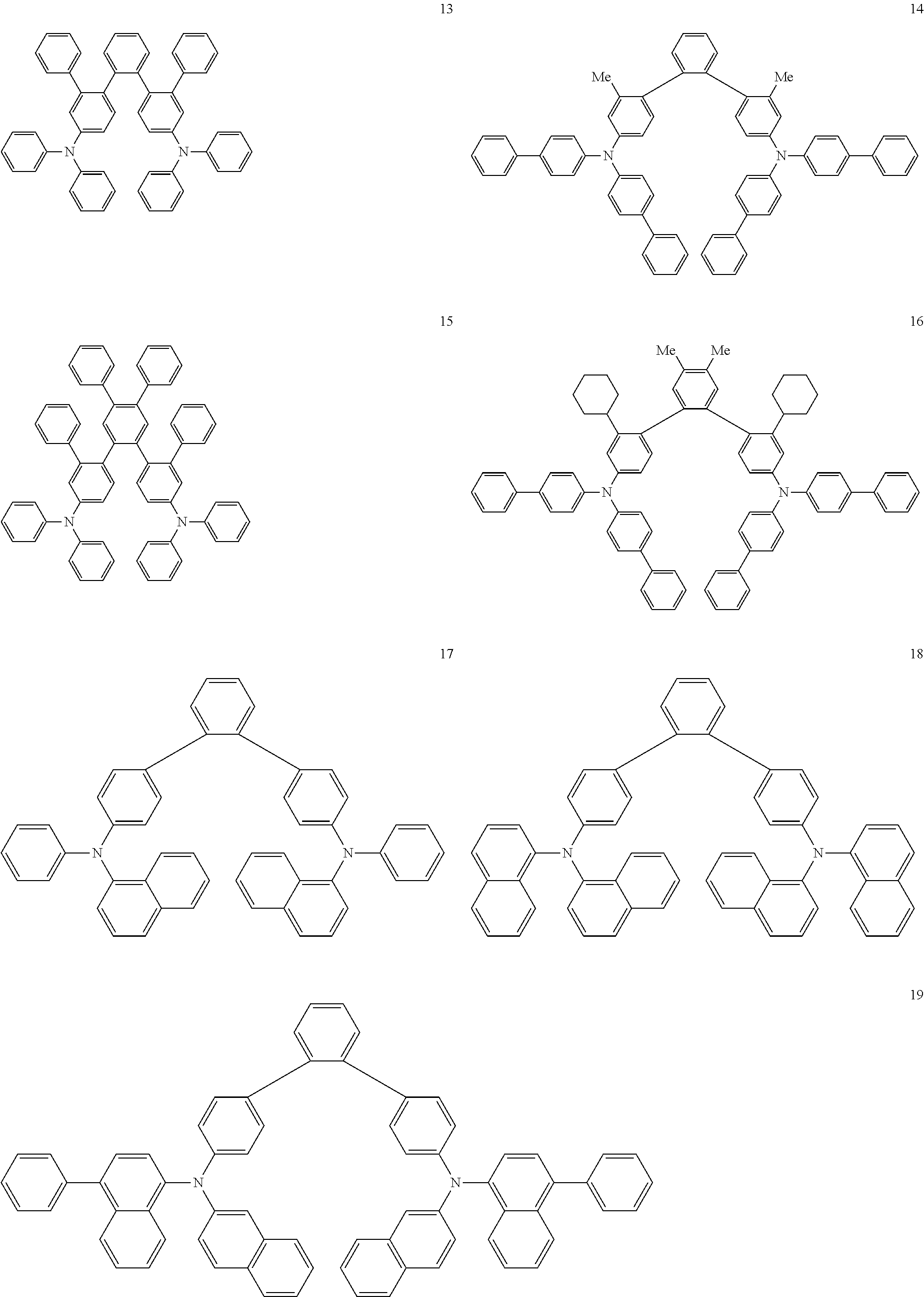

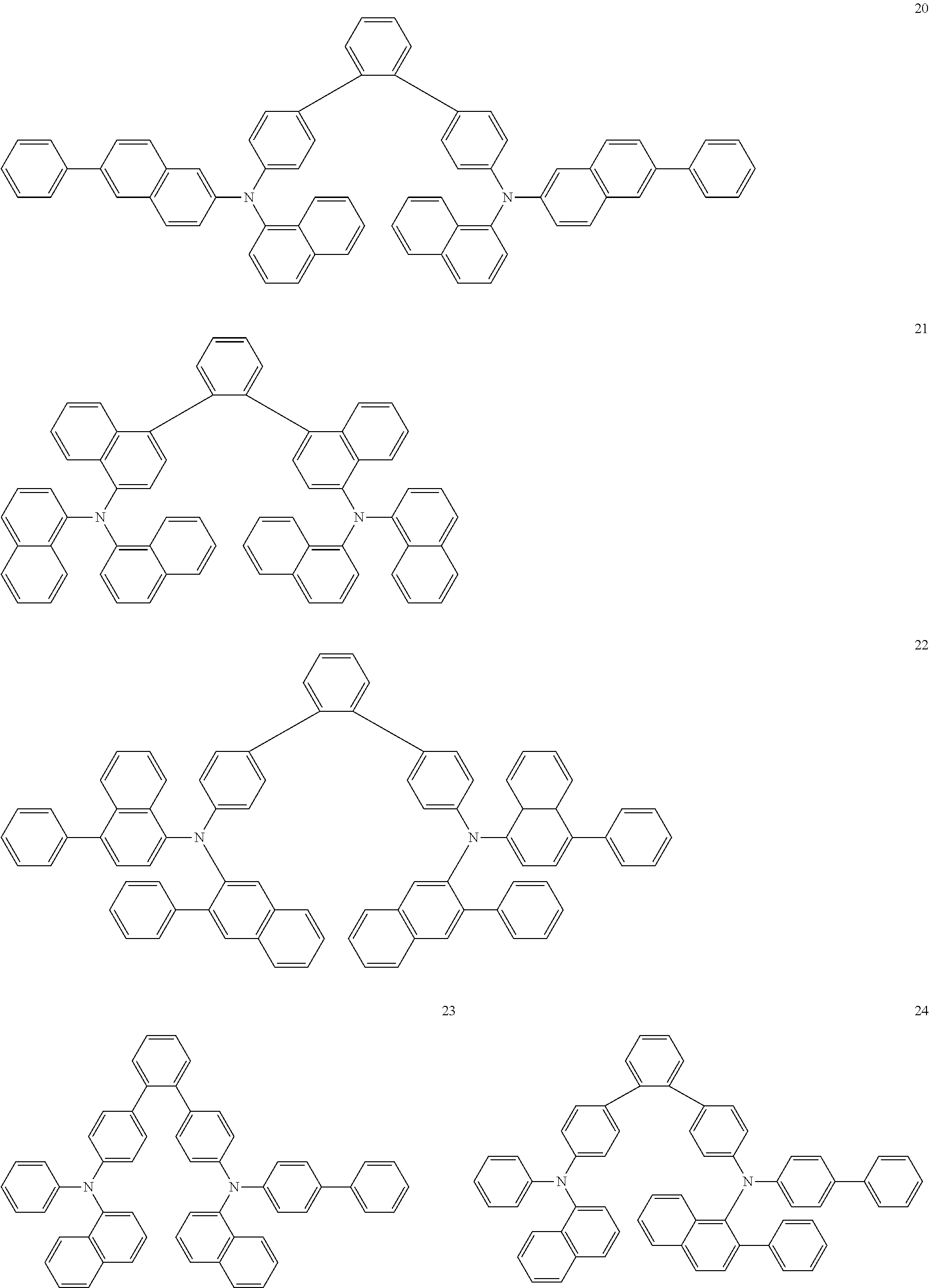

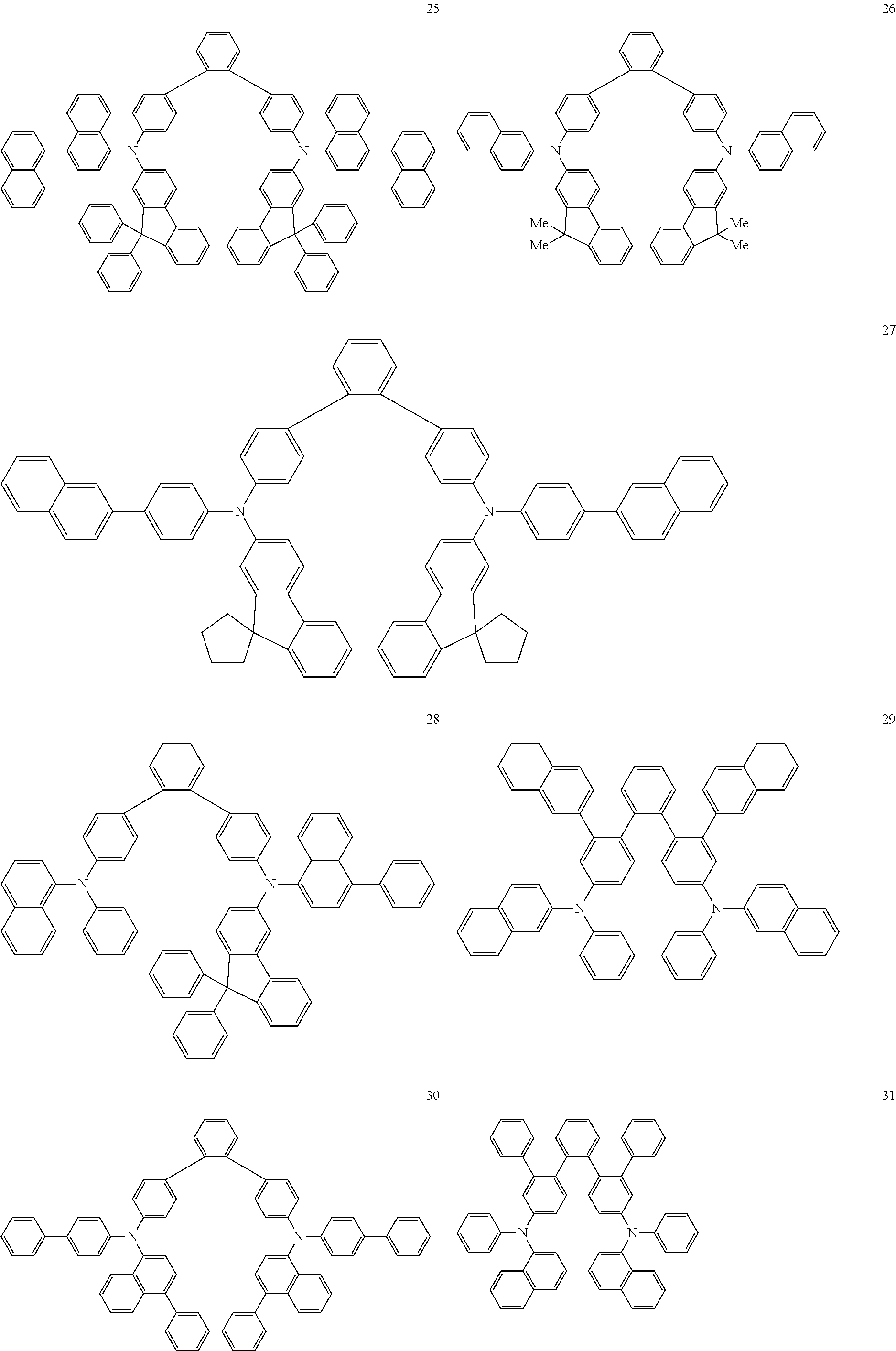

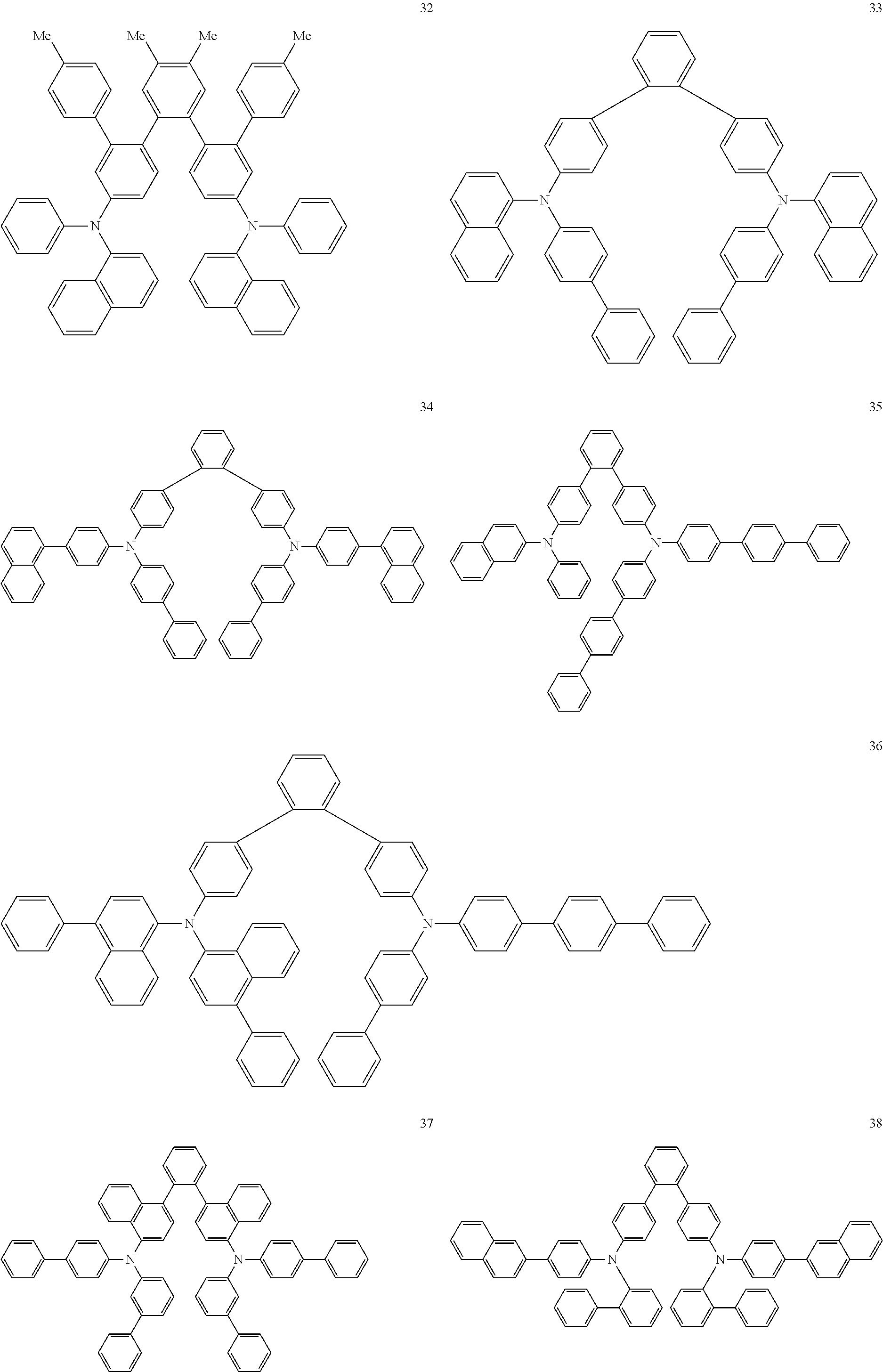

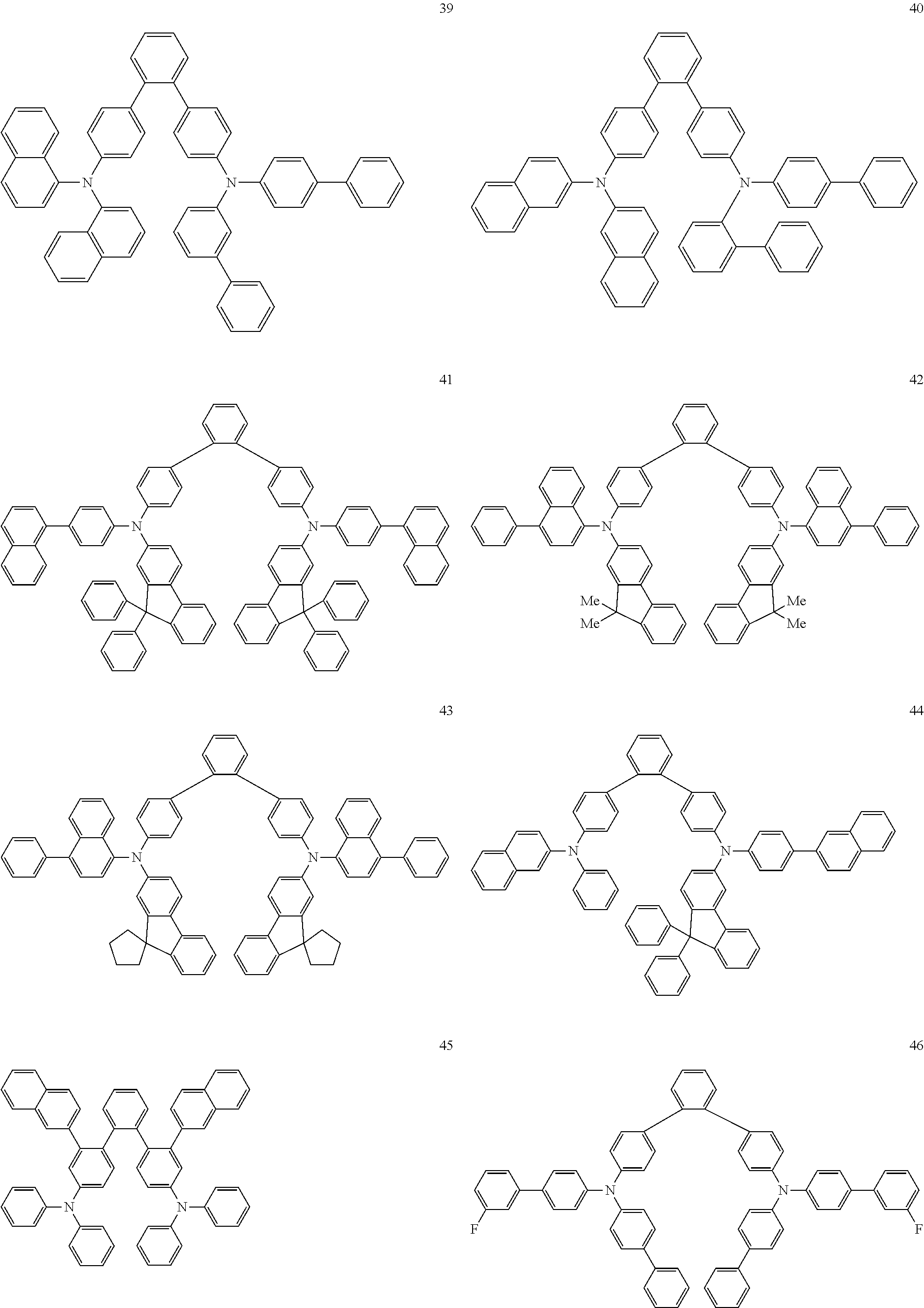

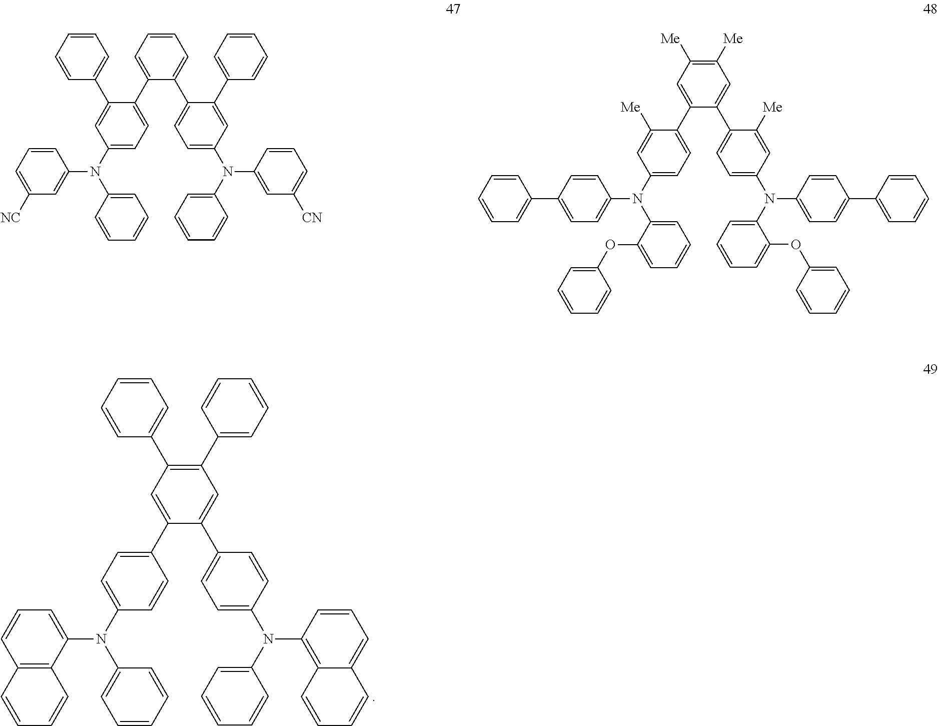 [SMILES: N#Cc1cccc(N(c2ccccc2)c2ccc(-c3ccccc3-c3ccc(N(c4ccccc4)c4cccc(C#N)c4)cc3-c3ccccc3)c(-c3ccccc3)c2)c1 ; Cc1cc(-c2ccc(N(c3ccc(-c4ccccc4)cc3)c3ccccc3Oc3ccccc3)cc2C)c(-c2ccc(N(c3ccc(-c4ccccc4)cc3)c3ccccc3Oc3ccccc3)cc2C)cc1C ; c1ccc(-c2cc(-c3ccc(N(c4ccccc4)c4cccc5ccccc45)cc3)c(-c3ccc(N(c4ccccc4)c4cccc5ccccc45)cc3)cc2-c2ccccc2)cc1]

4. The organic electroluminescent device of claim 1, wherein the middle hole transport material comprises a compound represented by the following Formula 3: 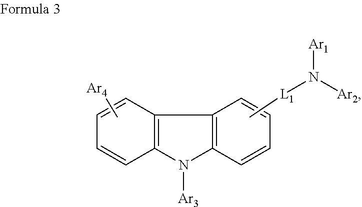
wherein, in Formula 3,
Ar₁, Ar₂, and Ar₃ are each independently selected from a substituted or unsubstituted aryl group having 6 to 50 carbon atoms for forming a ring, and a substituted or unsubstituted heteroaryl group having 5 to 50 carbon atoms for forming a ring,
Ar₄ is selected from hydrogen, deuterium, a halogen atom, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms, and
L₁ is selected from a direct linkage, a substituted or unsubstituted arylene group having 6 to 18 carbon atoms for forming a ring, and a substituted or unsubstituted heteroarylene group having 5 to 15 carbon atoms for forming a ring.

5. The organic electroluminescent device of claim 4, wherein the middle hole transport material comprises at least one compound selected from Compounds 2-1 to 2-17 collectively denoted as Formula 8:

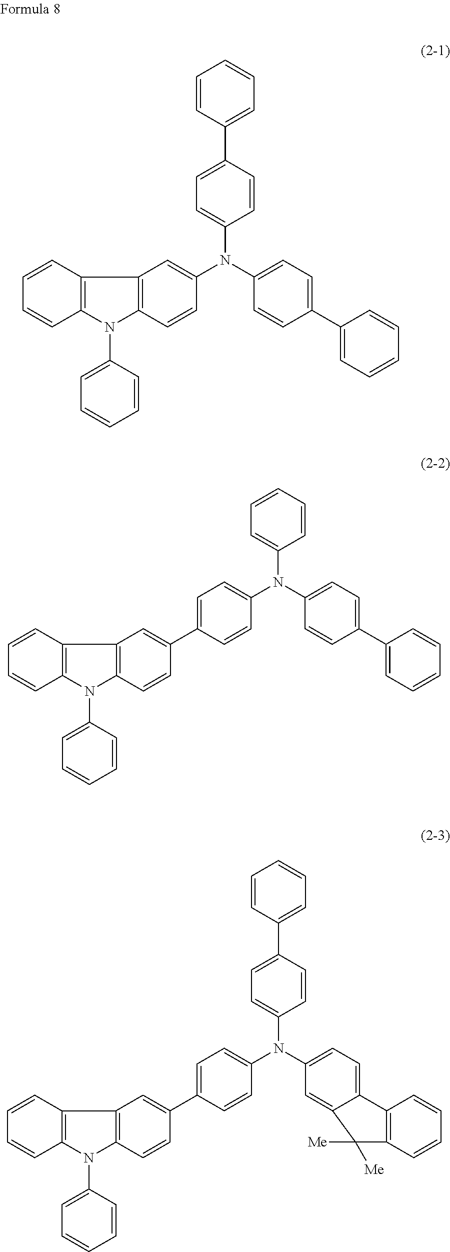 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

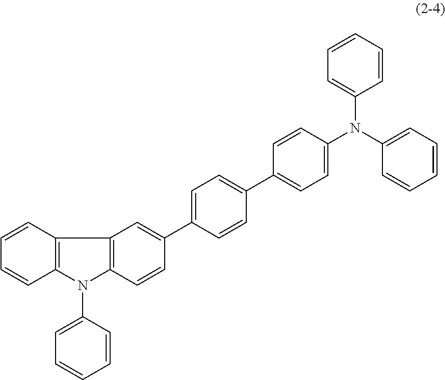 [SMILES: c1ccc(N(c2ccccc2)c2ccc(-c3ccc(-c4ccc5c(c4)c4ccccc4n5-c4ccccc4)cc3)cc2)cc1]

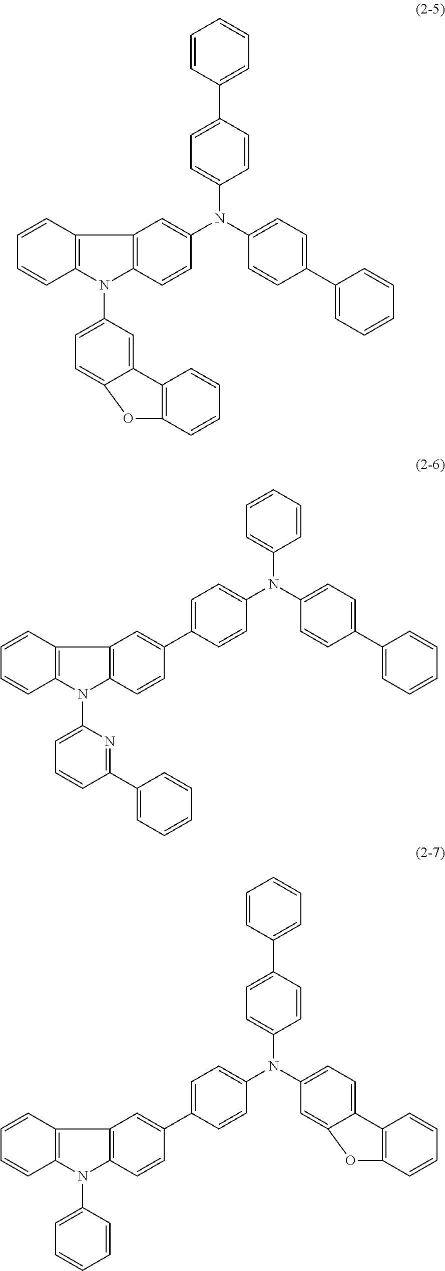 [SMILES: c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1 ; c1ccc(-c2ccc(N(c3ccc(-c4ccc5c(c4)c4ccccc4n5-c4ccccc4)cc3)c3ccc4c(c3)oc3ccccc34)cc2)cc1]

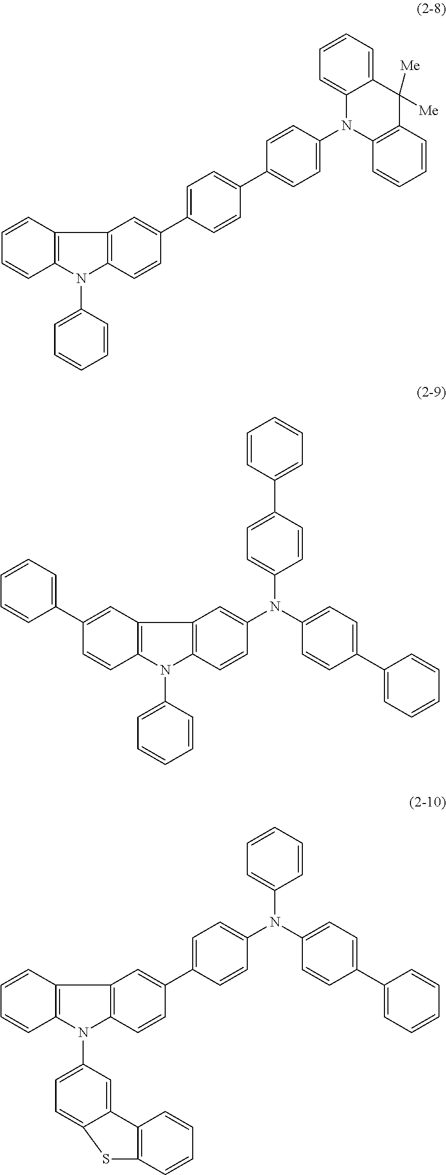 [SMILES: CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1 ; c1ccc(-c2ccc(N(c3ccccc3)c3ccc(-c4ccc5c(c4)c4ccccc4n5-c4ccc5sc6ccccc6c5c4)cc3)cc2)cc1]

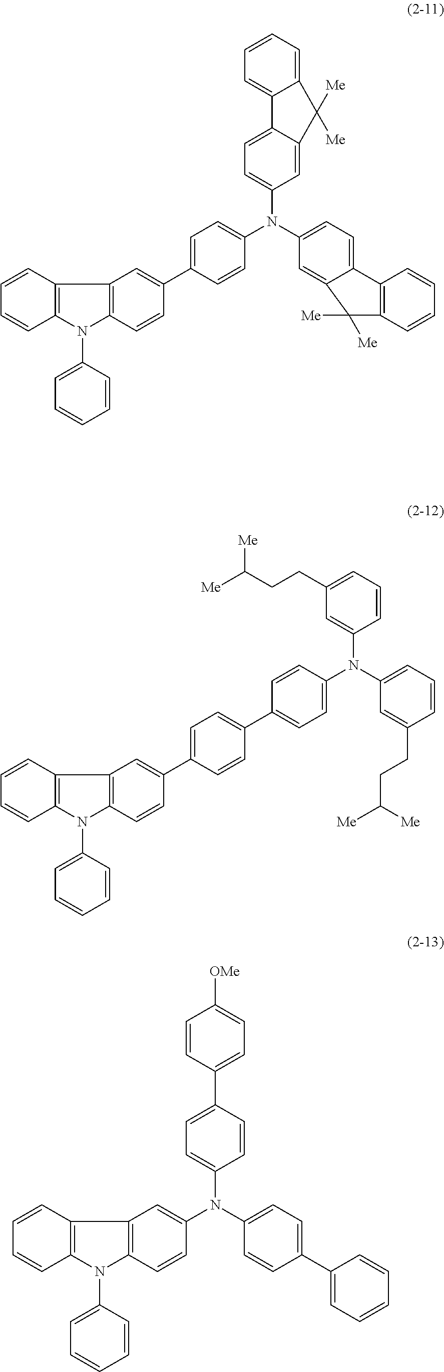 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1 ; COc1ccc(-c2ccc(N(c3ccc(-c4ccccc4)cc3)c3ccc4c(c3)c3ccccc3n4-c3ccccc3)cc2)cc1]

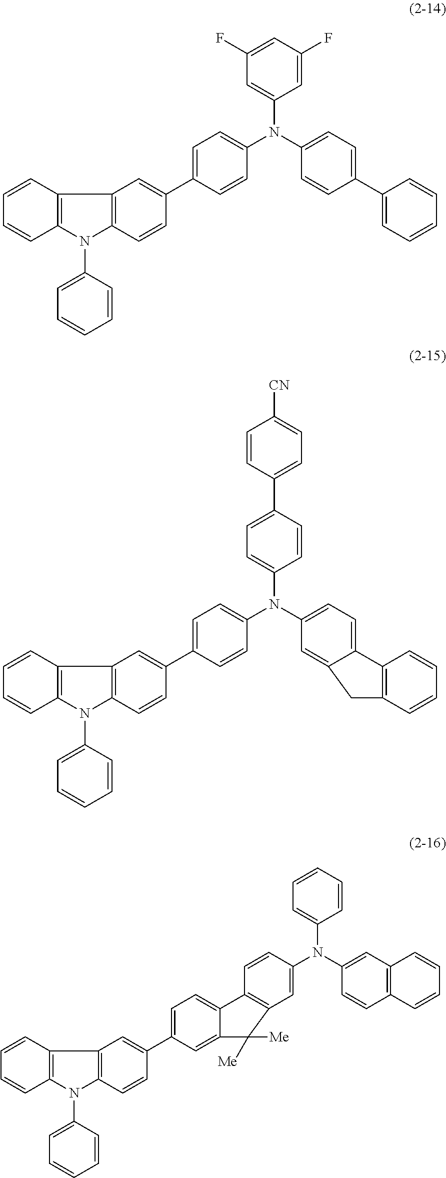 [SMILES: Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1 ; CC1(C)c2cc(-c3ccc4c(c3)c3ccccc3n4-c3ccccc3)ccc2-c2ccc(N(c3ccccc3)c3ccc4ccccc4c3)cc21]

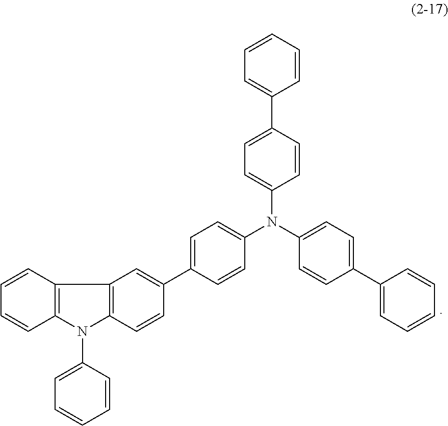 [SMILES: c1ccc(-c2ccc(N(c3ccc(-c4ccccc4)cc3)c3ccc(-c4ccc5c(c4)c4ccccc4n5-c4ccccc4)cc3)cc2)cc1]

6. The organic electroluminescent device of claim 1, wherein the electron accepting material has a lowest unoccupied molecular orbital (LUMO) level from about −9.0 eV to about −4.0 eV.

7. The organic electroluminescent device of claim 1, wherein the anode-side hole transport layer is adjacent to the anode.

8. The organic electroluminescent device of claim 1, wherein the emission layer comprises a compound represented by the following Formula 4: 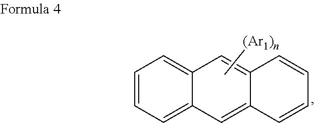
wherein, in Formula 4, Ar₁ is selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group, and a hydroxyl group, and
n is an integer selected from 1 to 10.

9. An organic electroluminescent device comprising:
an anode;
an emission layer;
an anode-side hole transport layer between the anode and the emission layer, the anode-side hole transport layer comprising an electron accepting material as a major component;
a middle hole transport layer between the anode-side hole transport layer and the emission layer, the middle hole transport layer comprising a middle hole transport material; and
an emission layer-side hole transport layer between the middle hole transport layer and the emission layer, the emission layer-side hole transport layer being adjacent to the emission layer,
wherein the emission layer-side hole transport layer comprises an emission layer-side hole transport material represented by the following Formula 1: 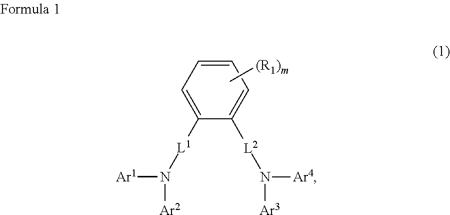
wherein, in Formula 1, Ar¹, Ar², Ar³ and Ar⁴ are each independently selected from a substituted or unsubstituted aryl group having 6 to 50 carbon atoms for forming a ring, and a substituted or unsubstituted heteroaryl group having 5 to 50 carbon atoms for forming a ring,
m is an integer selected from 0 to 4,
R¹ is selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R¹(s), and
L¹ and L² are each independently selected from a direct linkage, a substituted or unsubstituted arylene group having 6 to 18 carbon atoms for forming a ring, and a substituted or unsubstituted heteroarylene group having 5 to 15 carbon atoms for forming a ring.

10. The organic electroluminescent device of claim 9, wherein Ar¹, Ar², Ar³ and Ar⁴ in Formula 1 are each independently a compound represented by one of Formulae (1a)-(1c) collectively denoted as Formula 2: 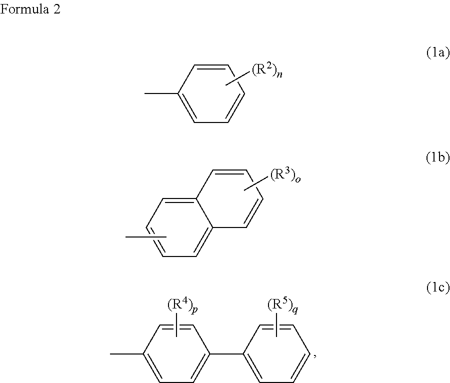
wherein, in Formulae (1a)-(1c), p is an integer selected from 0 to 4, n and q are each independently an integer selected from 0 to 5, o is an integer selected from 0 to 7, and
R², R³, R⁴ and R⁵ are each independently selected from hydrogen, deuterium, a substituted or unsubstituted aryl group having 6 to 50 carbon atoms for forming a ring, a substituted or unsubstituted heteroaryl group having 5 to 50 carbon atoms for forming a ring, a substituted or unsubstituted alkyl group having 1 to 50 carbon atoms, and a ring formed by a plurality of adjacent R²(s), R³(s), R⁴(s), and R⁵(s), respectively.

11. The organic electroluminescent device of claim 9, wherein the emission layer-side hole transport material comprises at least one compound selected from Compounds 1 to 49 collectively denoted as Formula 9:

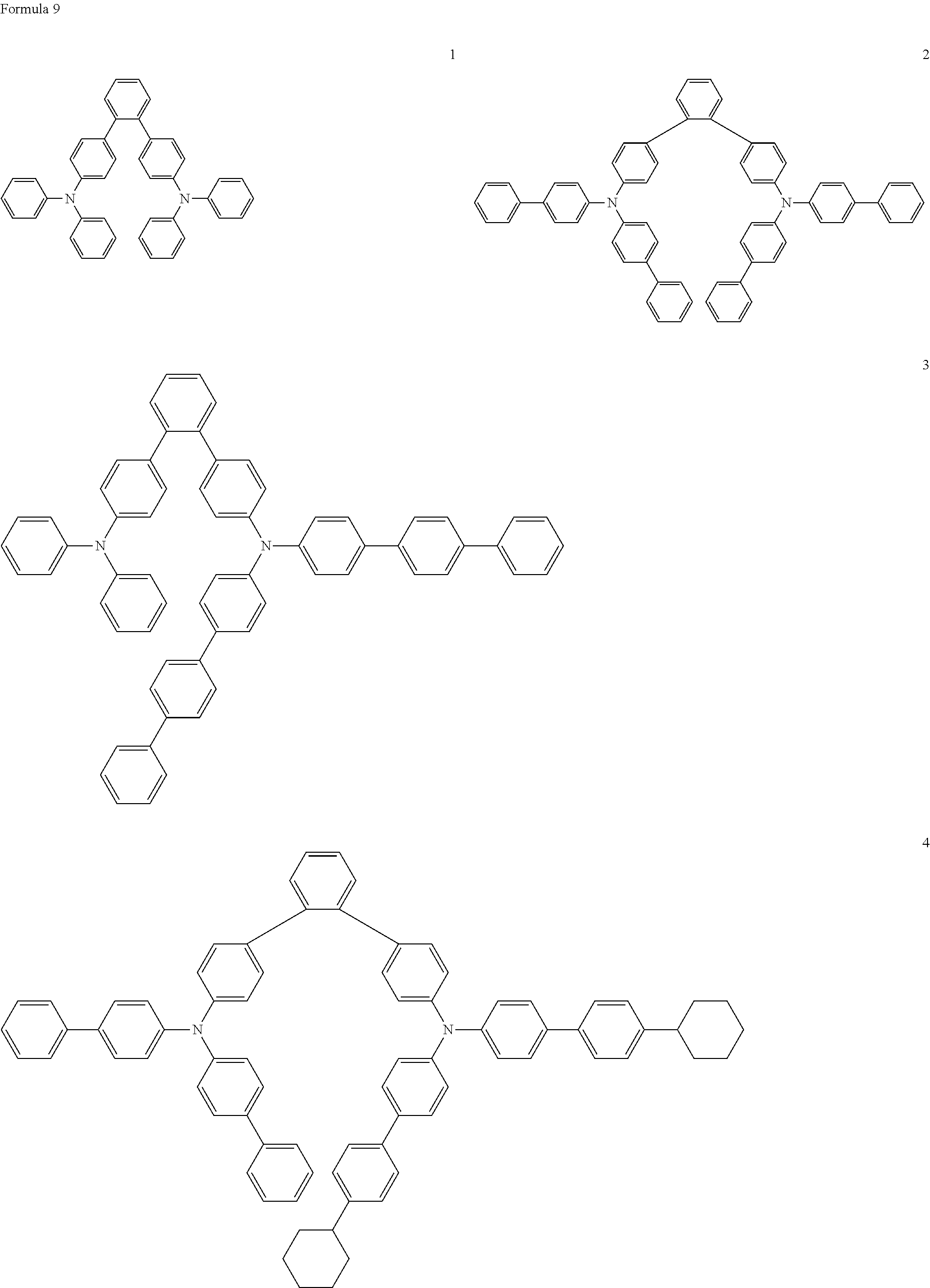 [SMILES: c1ccc(N(c2ccccc2)c2ccc(-c3ccccc3-c3ccc(N(c4ccccc4)c4ccccc4)cc3)cc2)cc1 ; c1ccc(-c2ccc(N(c3ccc(-c4ccccc4)cc3)c3ccc(-c4ccccc4-c4ccc(N(c5ccc(-c6ccccc6)cc5)c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccccc5-c5ccc(N(c6ccccc6)c6ccccc6)cc5)cc4)cc3)cc2)cc1 ; c1ccc(-c2ccc(N(c3ccc(-c4ccccc4)cc3)c3ccc(-c4ccccc4-c4ccc(N(c5ccc(-c6ccc(C7CCCCC7)cc6)cc5)c5ccc(-c6ccc(C7CCCCC7)cc6)cc5)cc4)cc3)cc2)cc1]

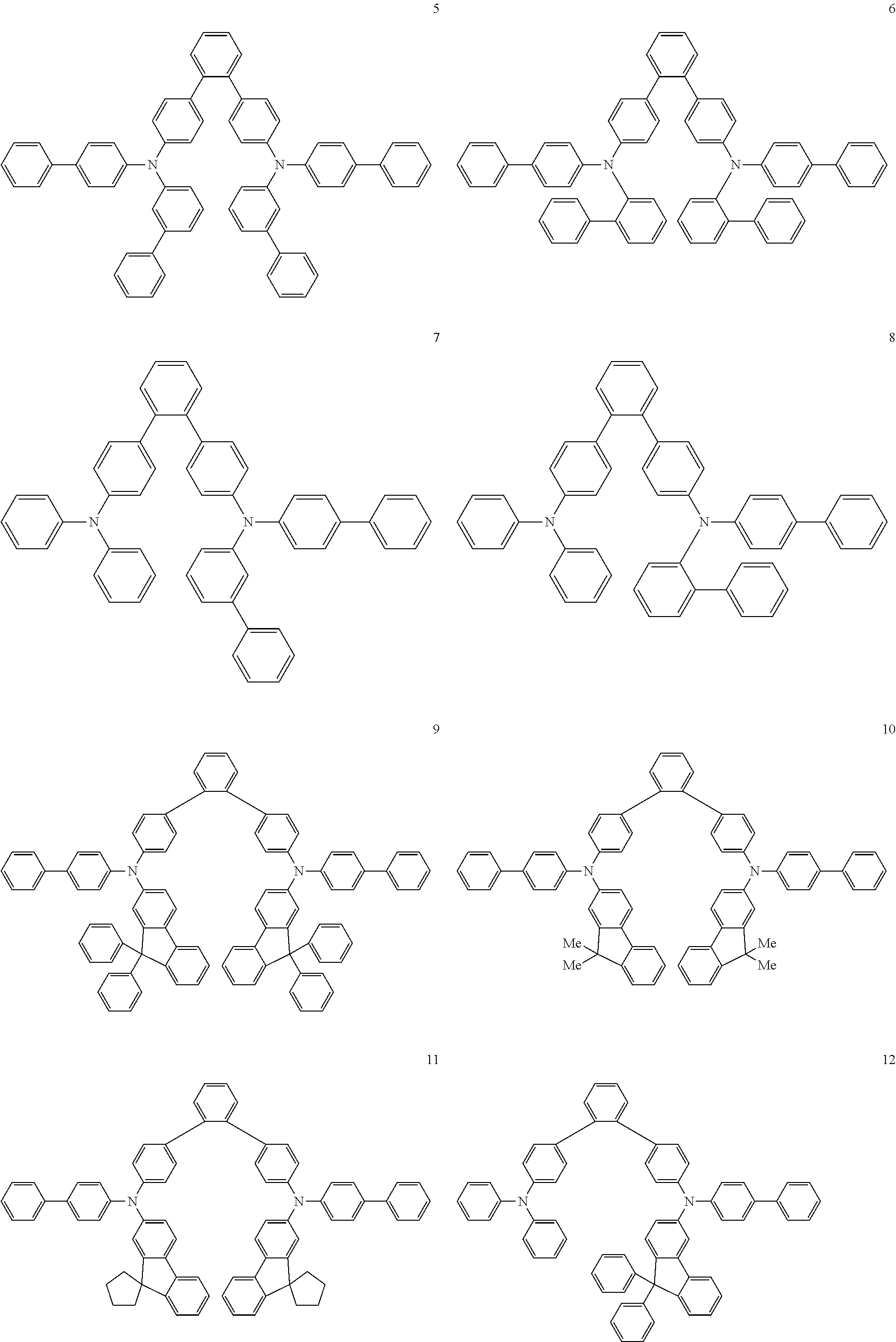

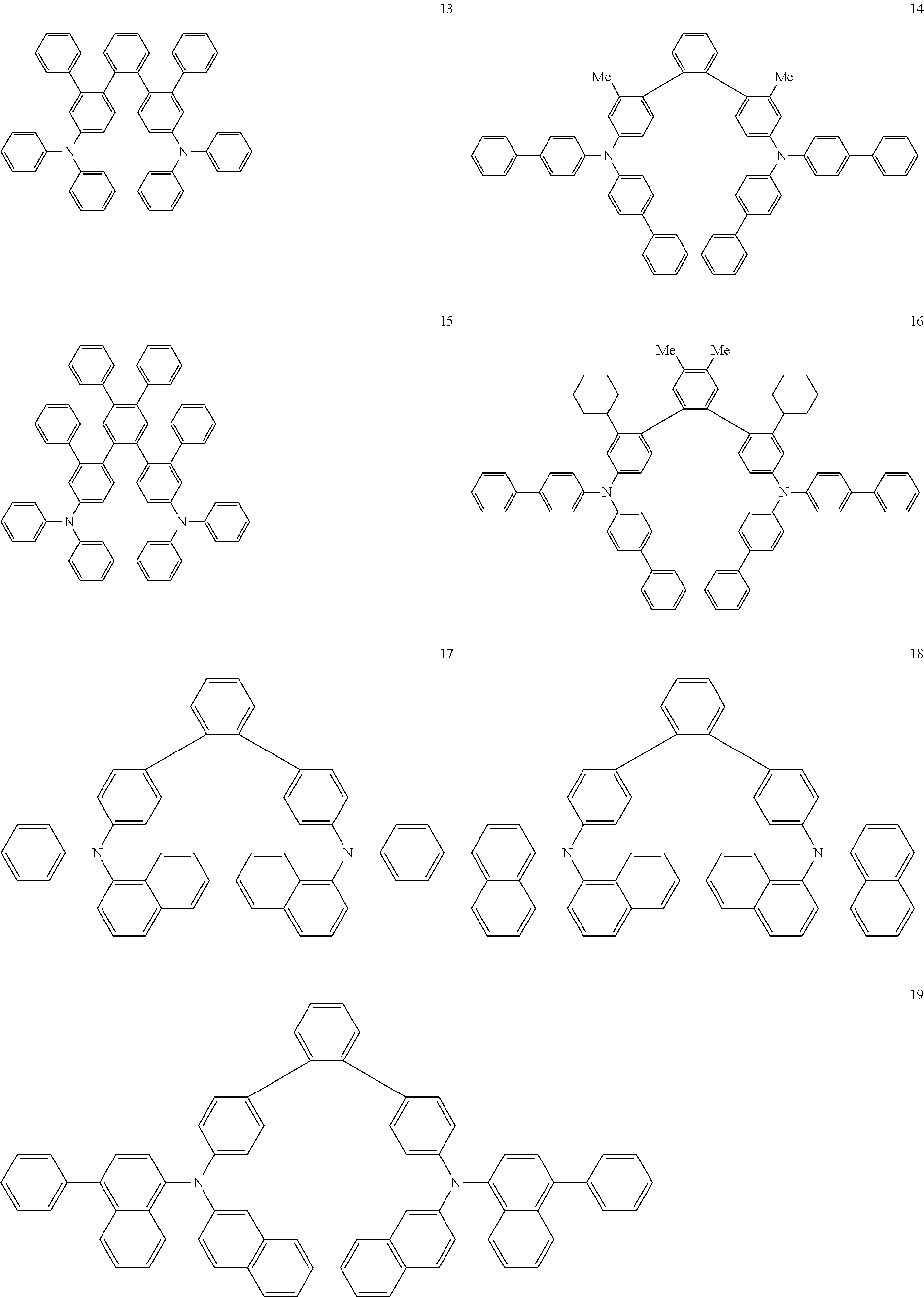

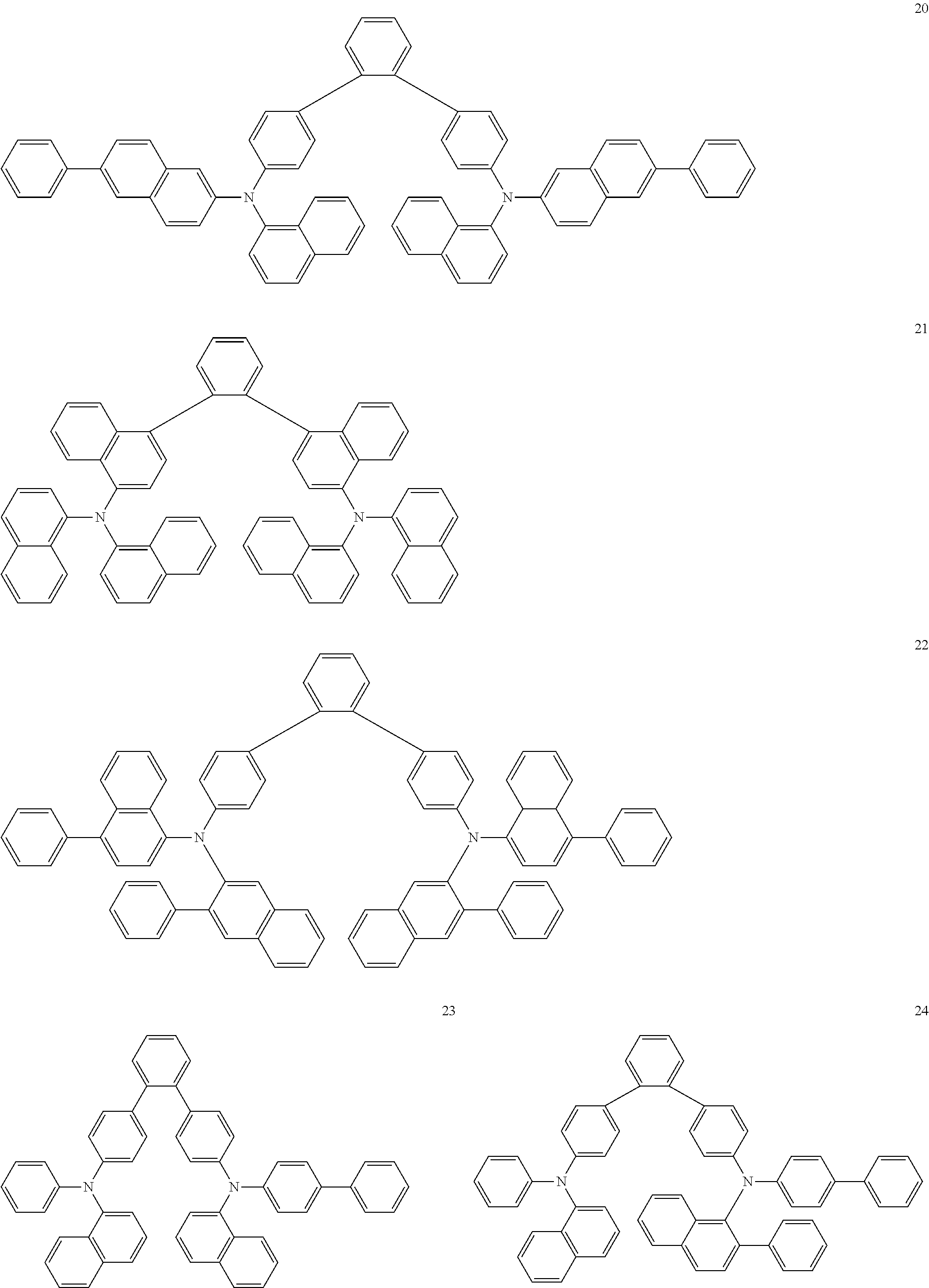

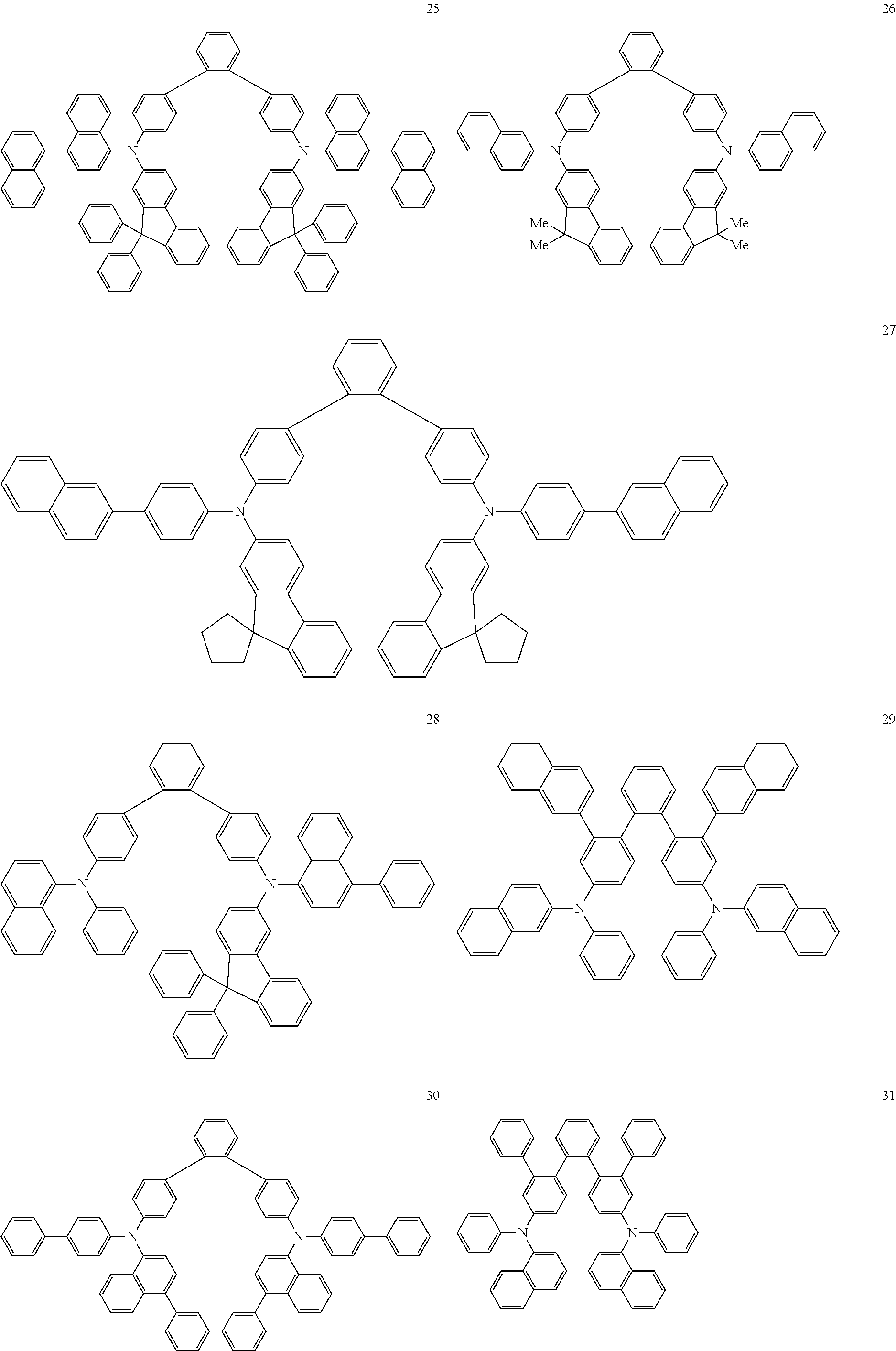

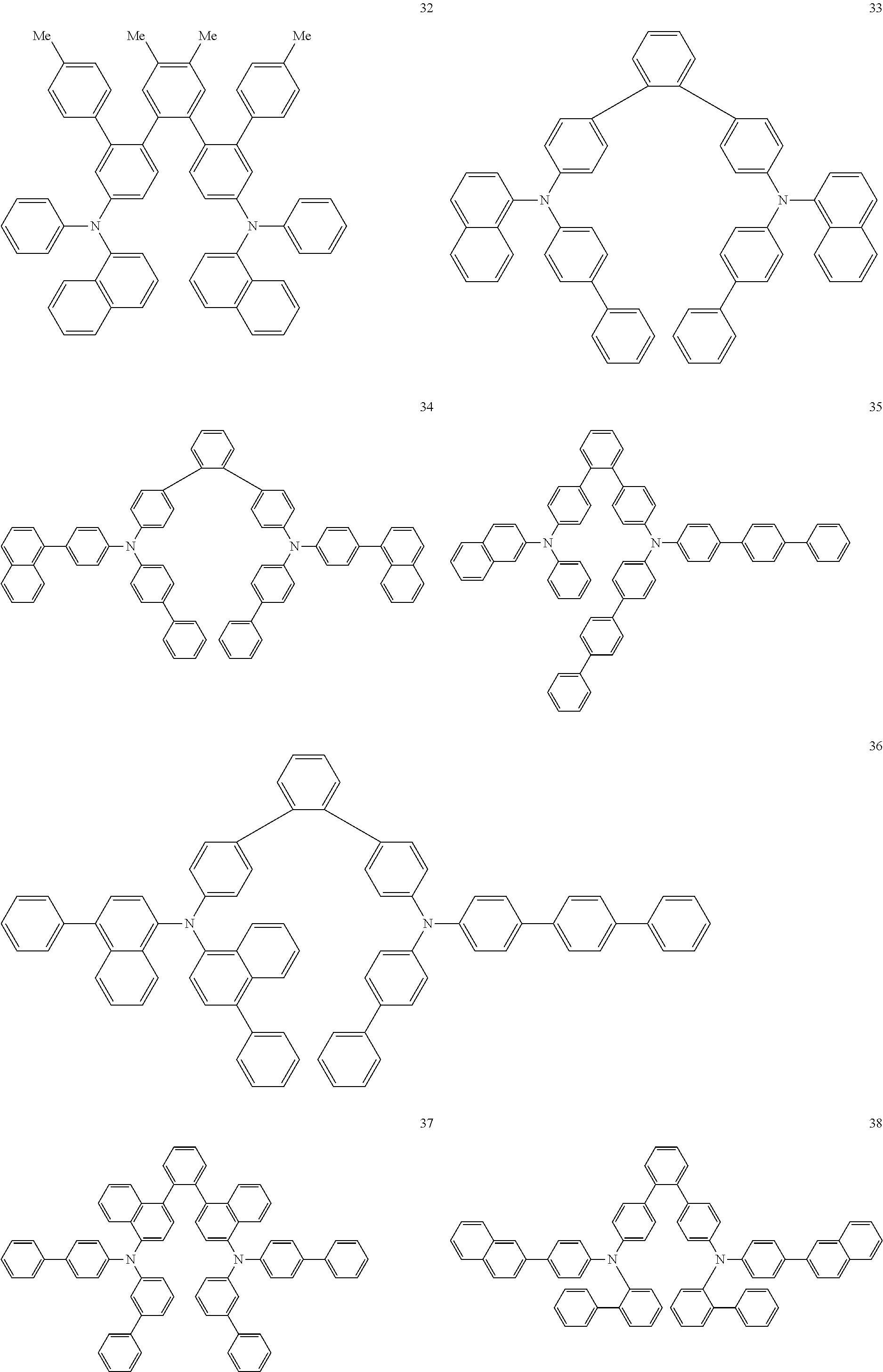

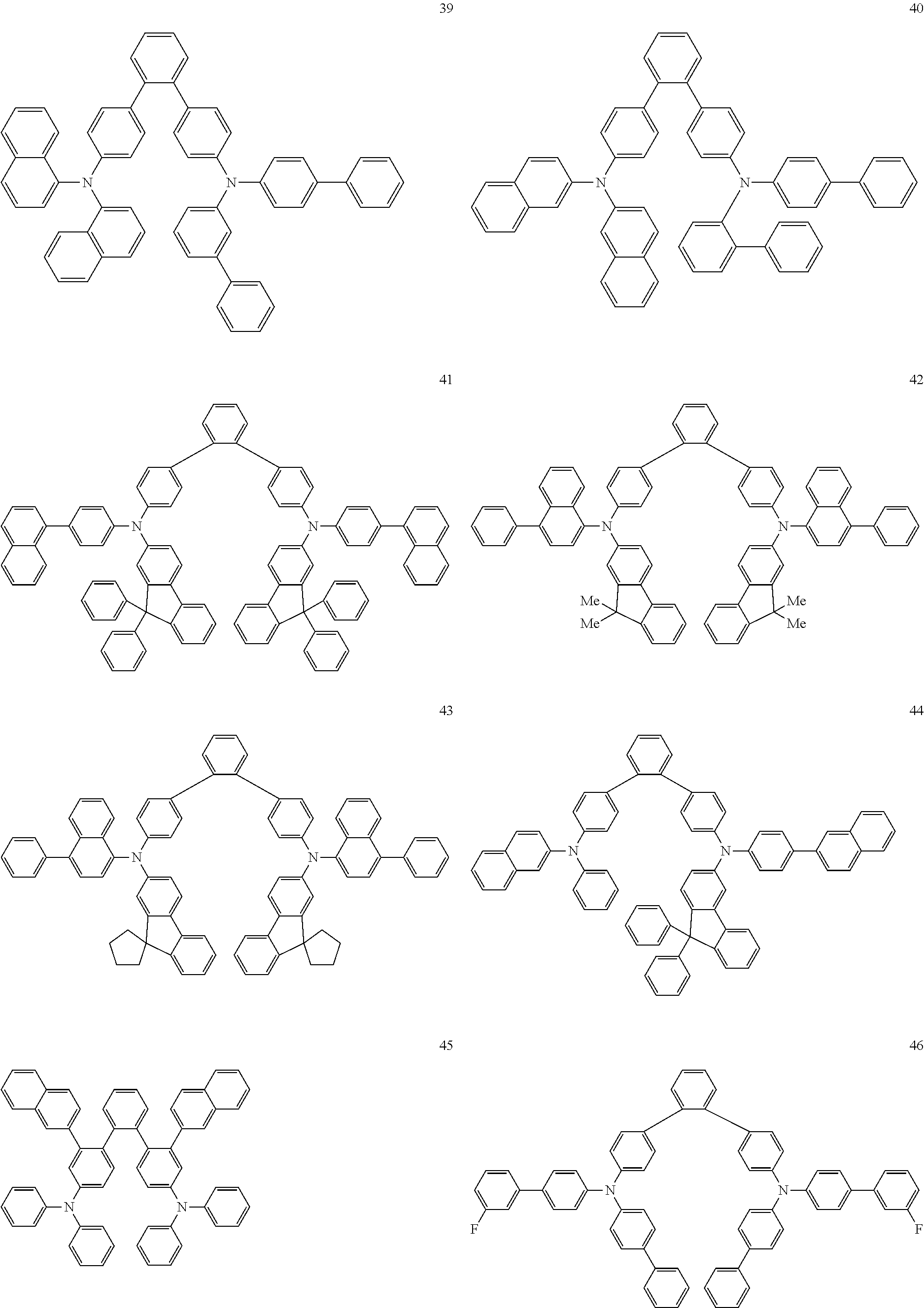

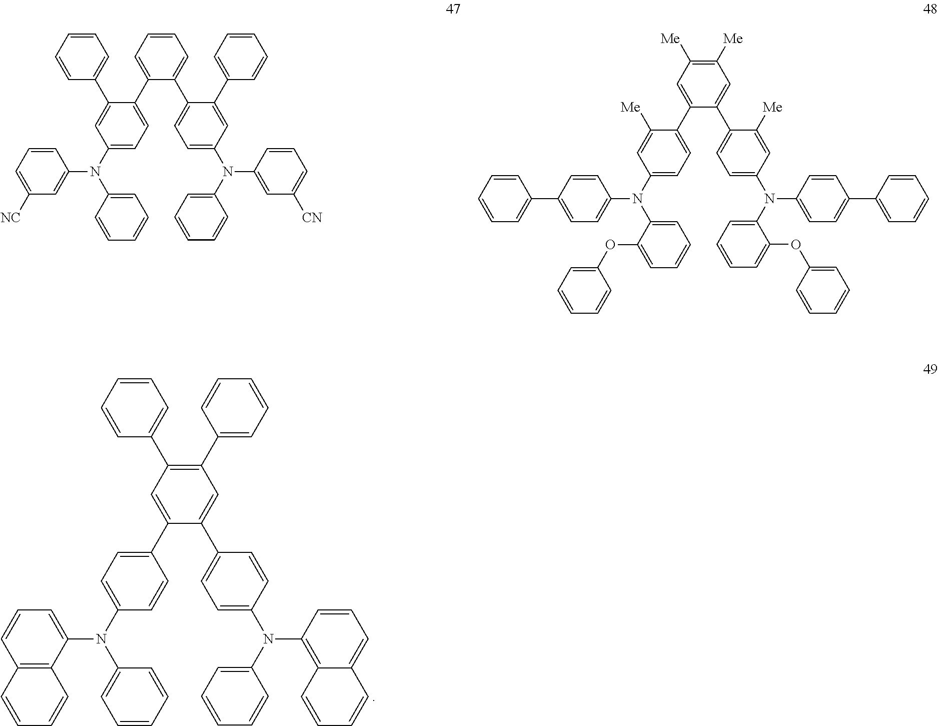 [SMILES: N#Cc1cccc(N(c2ccccc2)c2ccc(-c3ccccc3-c3ccc(N(c4ccccc4)c4cccc(C#N)c4)cc3-c3ccccc3)c(-c3ccccc3)c2)c1 ; Cc1cc(-c2ccc(N(c3ccc(-c4ccccc4)cc3)c3ccccc3Oc3ccccc3)cc2C)c(-c2ccc(N(c3ccc(-c4ccccc4)cc3)c3ccccc3Oc3ccccc3)cc2C)cc1C ; c1ccc(-c2cc(-c3ccc(N(c4ccccc4)c4cccc5ccccc45)cc3)c(-c3ccc(N(c4ccccc4)c4cccc5ccccc45)cc3)cc2-c2ccccc2)cc1]

12. The organic electroluminescent device of claim 9, wherein the middle hole transport material comprises a compound represented by the following Formula 3: 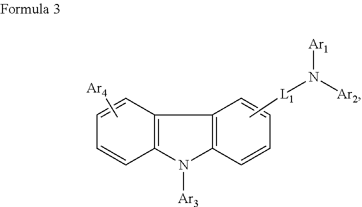
wherein, in Formula 3,
Ar₁, Ar₂, and Ar₃ are each independently selected from a substituted or unsubstituted aryl group having 6 to 50 carbon atoms for forming a ring, and a substituted or unsubstituted heteroaryl group having 5 to 50 carbon atoms for forming a ring,
Ar₄ is selected from hydrogen, deuterium, a halogen atom, a substituted or unsubstituted aryl group having 6 to 50 carbon atoms for forming a ring, a substituted or unsubstituted heteroaryl group having 5 to 50 carbon atoms for forming a ring, and a substituted or unsubstituted alkyl group having 1 to 50 carbon atoms, and
L₁ is selected from a direct linkage, a substituted or unsubstituted arylene group having 6 to 18 carbon atoms for forming a ring, and a substituted or unsubstituted heteroarylene group having 5 to 15 carbon atoms for forming a ring.

13. The organic electroluminescent device of claim 12, wherein the middle hole transport material comprises at least one compound selected from Compounds 2-1 to 2-17 collectively denoted as Formula 8:

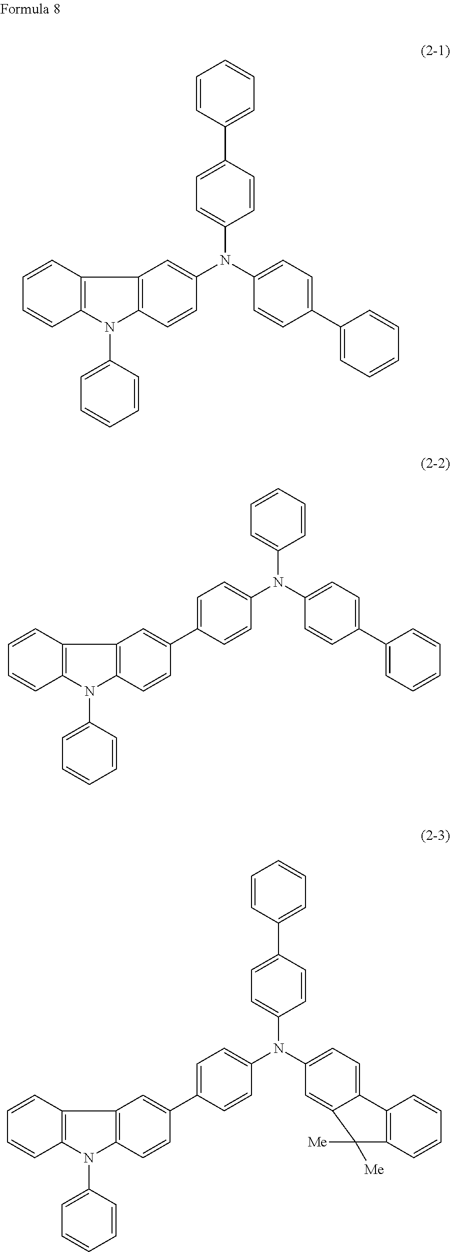 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

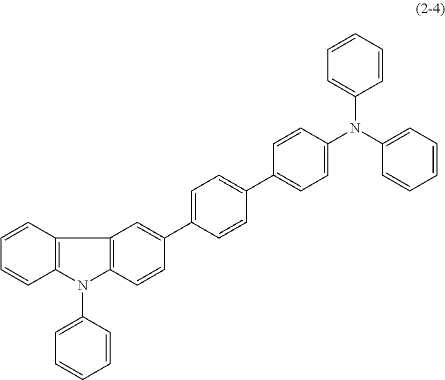 [SMILES: c1ccc(N(c2ccccc2)c2ccc(-c3ccc(-c4ccc5c(c4)c4ccccc4n5-c4ccccc4)cc3)cc2)cc1]

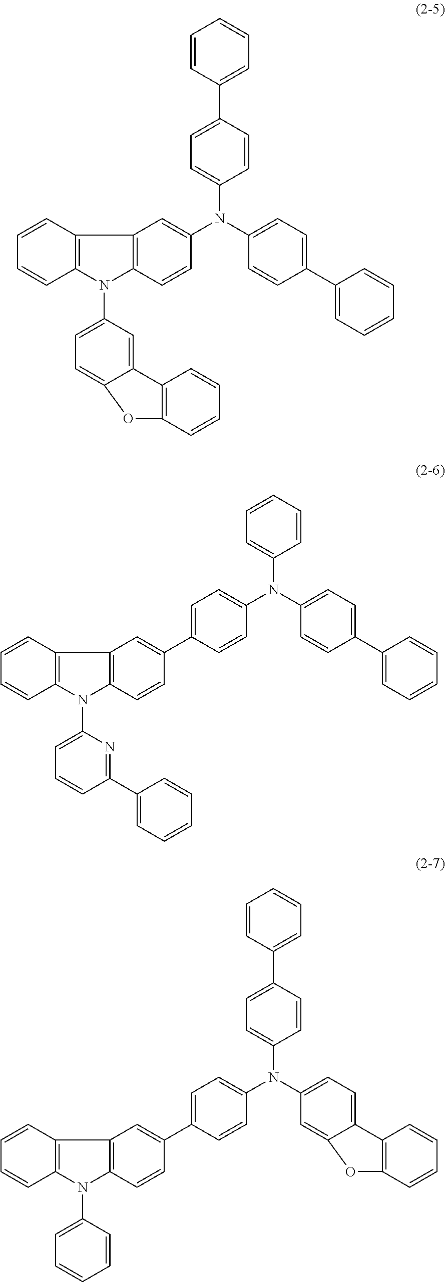 [SMILES: c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1 ; c1ccc(-c2ccc(N(c3ccc(-c4ccc5c(c4)c4ccccc4n5-c4ccccc4)cc3)c3ccc4c(c3)oc3ccccc34)cc2)cc1]

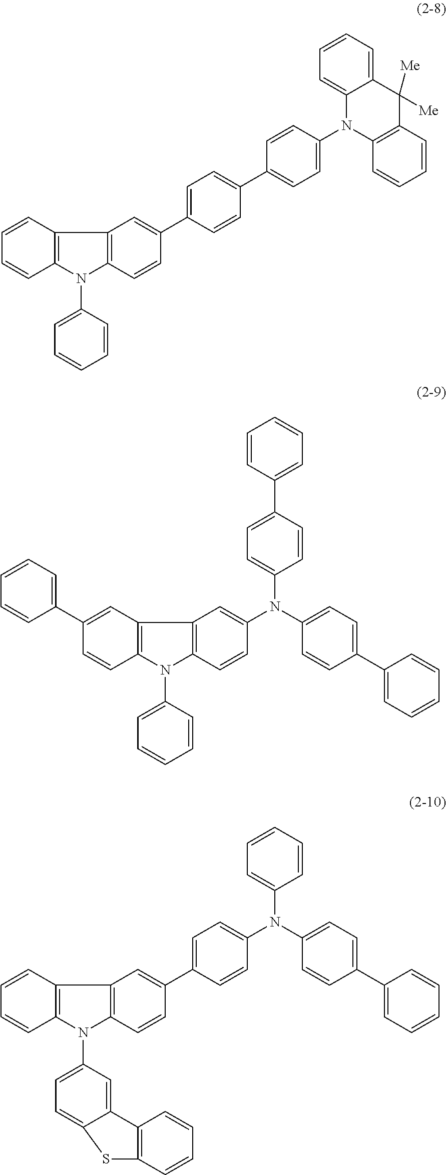 [SMILES: CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1 ; c1ccc(-c2ccc(N(c3ccccc3)c3ccc(-c4ccc5c(c4)c4ccccc4n5-c4ccc5sc6ccccc6c5c4)cc3)cc2)cc1]

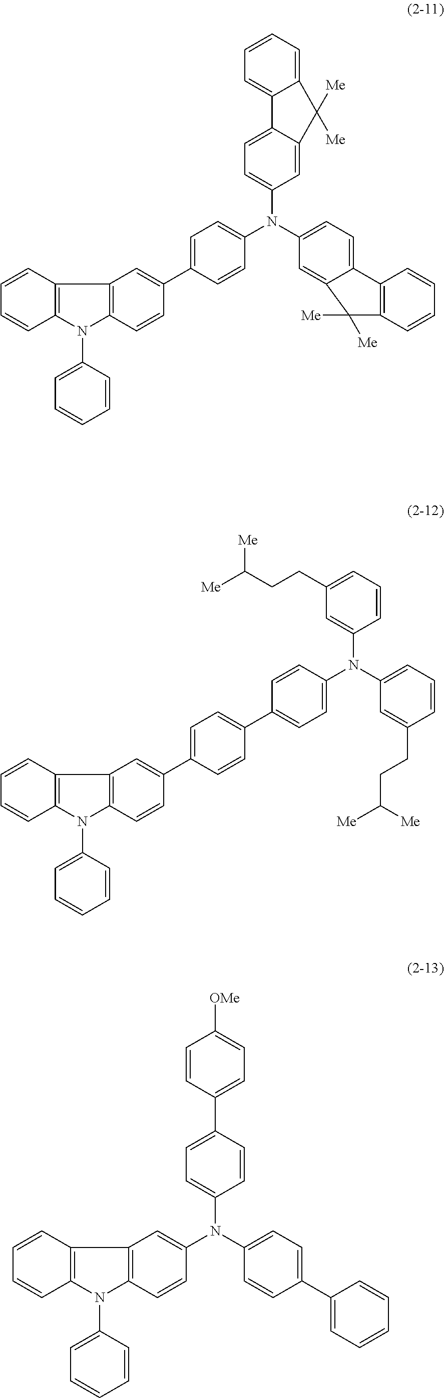 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1 ; COc1ccc(-c2ccc(N(c3ccc(-c4ccccc4)cc3)c3ccc4c(c3)c3ccccc3n4-c3ccccc3)cc2)cc1]

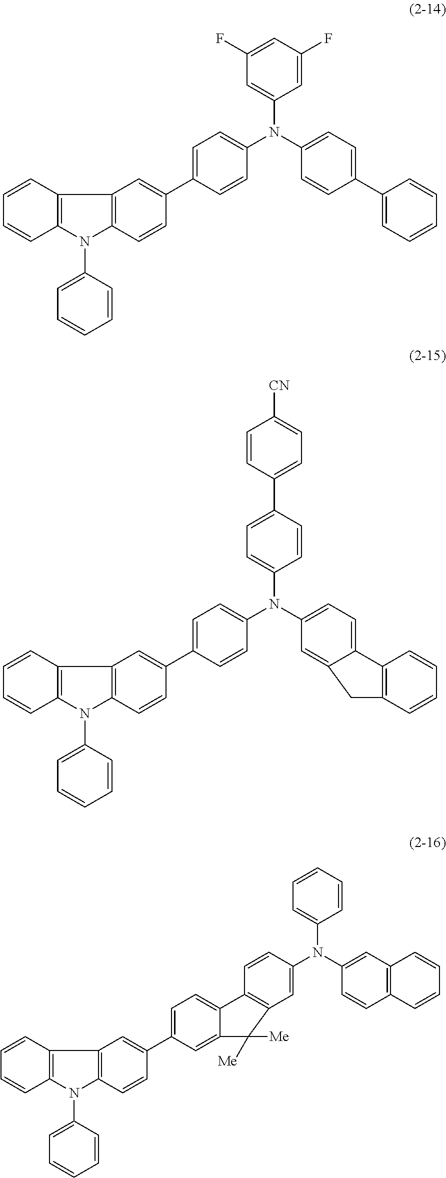 [SMILES: Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1 ; CC1(C)c2cc(-c3ccc4c(c3)c3ccccc3n4-c3ccccc3)ccc2-c2ccc(N(c3ccccc3)c3ccc4ccccc4c3)cc21]

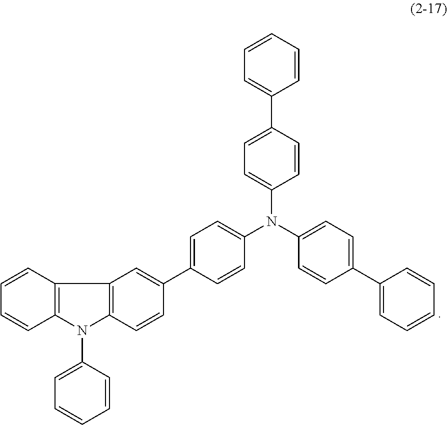 [SMILES: c1ccc(-c2ccc(N(c3ccc(-c4ccccc4)cc3)c3ccc(-c4ccc5c(c4)c4ccccc4n5-c4ccccc4)cc3)cc2)cc1]

14. The organic electroluminescent device of claim 9, wherein the electron accepting material has a lowest unoccupied molecular orbital (LUMO) level from about −9.0 eV to about −4.0 eV.

15. The organic electroluminescent device of claim 9, wherein the anode-side hole transport layer is adjacent to the anode.

16. The organic electroluminescent device of claim 9, wherein the emission layer comprises a compound represented by the following Formula 4: 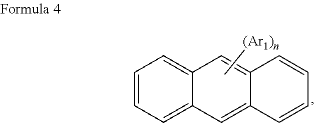
wherein, in Formula 4, Ar₁ is selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group, and a hydroxyl group, and
n is an integer selected from 1 to 10.
